(19) United States
(12) Patent Application Publication
(10) Pub. No.: US 2024/0276867 A1
(43) Pub. Date: Aug. 15, 2024

(54) DINUCLEAR PLATINUM EMITTER COMPLEXES AND METHODS OF MAKING AND USING THEREOF

(71) Applicants: Versitech Limited, Hong Kong (CN); Hong Kong Quantum AI Lab Limited, Hong Kong (CN)

(72) Inventors: Chi-Ming Che, Hong Kong (CN); Kar-Wai Lo, Hong Kong (CN); Gang Cheng, Hong Kong (CN)

(21) Appl. No.: 18/563,314

(22) PCT Filed: May 31, 2022
(86) PCT No.: PCT/CN2022/096225

§ 371 Date: Nov. 21, 2023

Related U.S. Application Data
(60) Provisional application No. 63/195,140, filed on May 31, 2021.

(51) Int. Cl. H10K 85/30; C07F 15/00; C09K 11/06; H10K 50/12; H10K 101/10

(52) U.S. Cl. CPC H10K 85/346; C07F 15/0086; C09K 11/06; C09K 2211/1007; C09K 2211/1014; C09K 2211/1044; C09K 2211/1059; C09K 2211/185; H10K 50/12; H10K 2101/10

(57) ABSTRACT

Described herein are dinuclear platinum(II) emitter complexes and their methods of making and using thereof. The design of the dinuclear platinum(II) emitters results in short radiative lifetimes and high quantum yields. The dinuclear platinum(II) emitter complexes can be used to fabricate blue emitting OLEDs.

### CROSS-REFERENCE TO RELATED APPLICATION

This application claims benefit of and priority to U.S. Provisional Application No. 63/195,140 filed May 31, 2021, which is incorporated herein by reference in its entirety.

### FIELD OF THE INVENTION

The disclosed invention is generally in the field of dinuclear platinum (II) emitter complexes, their methods of making, and their use in organic electronics, such as organic light-emitting devices (OLEDs).

### BACKGROUND OF THE INVENTION

The search for operationally stable and high-efficiency blue emitters continues to be insurmountable. Thus, development of new emitters remains a high value target for the OLED industry. Extensive efforts in this area have been directed to the research and development of novel phosphorescent metal complexes. Recently, thermally activated delayed fluorescent (TADF) compounds have been developed due to their intrinsic advantages in achieving high device operational efficiency. These efforts, thus far, have resulted in limited success for these classes of emitter complexes where, as an example, issues concerning low quantum efficiencies, poor operational lifetime, and long radiative lifetimes of the emitters remain.

Accordingly, there remains a need to develop improved operationally stable and high-efficiency emitter complexes for organic light-emitting diode (OLED) applications. There is also a need for elongating the operational lifetime of devices containing such emitters to more practical levels by tailoring the radiative lifetime of the emitters.

Therefore, it is an object of the present invention to provide novel phosphorescent emitter complexes having improved emissive properties.

It is a further object of the present invention to provide methods of making such phosphorescent emitter complexes.

It is still a further object of the present invention to provide improved organic light-emitting diode (OLEDs) containing such phosphorescent emitter complexes.

### SUMMARY OF THE INVENTION

Dinuclear platinum emitter complexes containing platinum (II) atoms complexed by cyclometalating ligands and triazole-based and/or pyrazole-based ligands are described herein. Exemplary dinuclear platinum (II) emitter complexes can have a structure as follows:

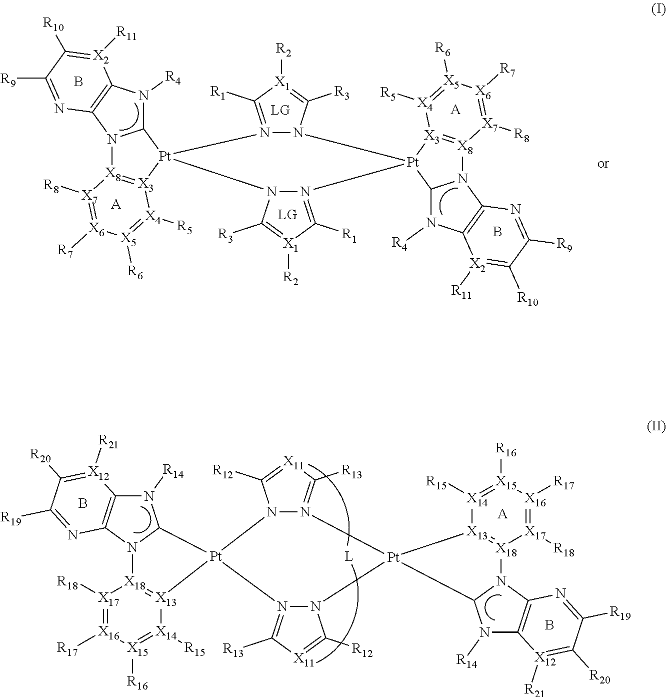

wherein each ligand is independently bonded to both platinum atoms,
wherein R₁, R₂, R₃, R₁₂, and R₁₃ for each of formulas (I) or (II) are each independently selected from the group consisting of a hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein R₄ and R₁₄ for each of formulas (I) or (II) are each independently selected from the group consisting of a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein each X₁ in formula (I) is independently selected from carbon or nitrogen with the proviso that R₂ is a free electron pair when X₁ is nitrogen,
wherein each X₂ in formula (I) is independently selected from carbon or nitrogen with the proviso that R₁ is a free electron pair when X₂ is nitrogen,
wherein each X₁₂ in formula (II) is independently selected from carbon or nitrogen with the proviso that R₂₁ is a free electron pair when X₁₂ is nitrogen,
wherein ring A in formula (I) is a 6-member carbon ring or a 6-member heterocyclic ring having at least one nitrogen atom where X₈ is a carbon and each of X₃ or X₄ or X₅ or X₆ or X₇ are independently selected from carbon or nitrogen with the proviso that when any of X₄ or X₅ or X₆ or X₇ are nitrogen that R₅, R₆, R₇, R₈ are a free electron pair. In preferred instances, only two of X₃-X₇ groups are nitrogen and the remaining X groups are carbons. In some particular instances, X₃ is a carbon,
wherein ring B in formula (I) is a 6-member ring having at least one nitrogen atom. In some instances, ring B has two nitrogen atoms when X₂ is nitrogen,
wherein ring A in formula (II) is a 6-member carbon ring or a 6-member heterocyclic ring having at least one nitrogen atom where X₁₈ is a carbon and each of X₁₃ or X₁₄ or X₁₅ or X₁₆ or X₁₇ are independently selected from carbon or nitrogen with the proviso that when any of X₁₄ or X₁₅ or X₁₆ or X₁₇ are nitrogen that R₁₅, R₁₆, R₁₇, R₁₈ are a free electron pair. In preferred instances, only two of X₃-X₁₇ groups are nitrogen and the remaining X groups are carbons. In some particular instances, X₁₃ is a carbon,
wherein ring B in formula (II) is a 6-member ring having at least one nitrogen atom. In some instances, ring B has two nitrogen atoms when X₁₂ is nitrogen,
wherein R₅, R₆, R₇, R₈, R₉, R₁₀, R₁₁, R₁₅, R₁₆, R₁₇, R₁₈, R₁₉, R₂₀, and R₂₁, of formulas (I) or (II) are each independently selected from the group consisting of a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group (such as —OMe); an amino group; a hydroxyl group; a formyl group; an acyl group; a thio group; an ester group; a carbonyl group; a carboxylate group; an amide group; a nitro group; and an SiMe₃ group,
wherein each of R₅ and R₆, R₆ and R₇, R₇ and R₈, R₉ and R₁₀, R₁₀ and R₁₁, R₁₅ and R₁₆, R₁₆ and R₁₇, R₁₇ and R₁₈, R₁₉ and R₂₀, or R₂₀ and R₂₁, can optionally form a saturated, unsaturated, or aromatic, optionally substituted ring, optionally interrupted by a heteroatom, and having a total of from 5 to 18 carbon atoms and heteroatoms, and
wherein in L in formula (II) is a linker group which is a substituted or unsubstituted linear or branched alkyl radical having from 1 to 20 carbon atoms, optionally interrupted by at least one heteroatom and/or aryl group and/or cycloalkyl and/or heteroaryl group and/or heterocycloalkyl group and optionally having at least one substituent group thereon; or a substituted or unsubstituted alkenyl radical having 2 to 20 carbon atoms, or a substituted or unsubstituted alkynyl radical having 2 to 20 carbon atoms; or is a linker group comprising two terminal phenol groups each attached to the two X₁₁ groups and the two terminal phenol groups each are linked together via a linear or branched alkyl radical, optionally interrupted by at least one heteroatom and/or aryl group and optionally having at least one substituent group thereon.

The dinuclear platinum emitter complexes described are phosphorescent and electroluminescent. The dinuclear platinum emitter complexes can be emissive at room temperature, low temperature, or both. The dinuclear platinum emitter complexes may be in a solid, liquid, glassy, film, or solution state. The dinuclear platinum emitter complexes can emit light in response to (i) the passage of an electric current or (ii) to an electric field. In some forms, the dinuclear platinum emitter complexes may emit light independent of concentration. The phosphorescent and electroluminescent properties of the dinuclear platinum emitter complexes are typically within a wavelength range of between about 380 nm and 550 nm, inclusive.

In some instances, the dinuclear platinum emitter complexes preferably emit blue to sky-blue light within a wavelength range of between about 400 nm and 550 nm, inclusive, or any sub-range within. The emissive properties of the dinuclear platinum emitter complexes can be tuned by way of the selection of substituents. The dinuclear platinum emitter complexes may emit exclusively or predominantly in the blue wavelength range of the visible spectrum and may contain one or two emission maxima within.

The dinuclear platinum(II) emitter complexes and the ligands described herein can be synthesized using methods known in the art of organic chemical synthesis. In one non-limiting exemplary method, the dinuclear platinum(II) emitter complex can be prepared by:
contacting a platinum (Pt) compound with a first ligand selected from a pyrazole ligand, a triazole ligand, or a combination thereof; and a second ligand according to formula (III)

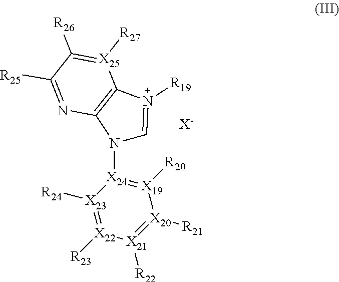

wherein R₁₉ is selected from the group consisting of a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein X₁₉ is independently selected from carbon or nitrogen with the proviso that R₂₀ is hydrogen when X₁₉ is a carbon and R₂₀ is a free electron pair when X₁₉ is nitrogen,
wherein X₂₅ is independently selected from carbon or nitrogen with the proviso that R₂₆ is a free electron pair when X₂₅ is nitrogen,
wherein X₂₄ is carbon and each of X₁₉ or X₂₀ or X₂₁ or X₂₂ or X₂₃ are independently selected from carbon or nitrogen with the proviso that when any of X₁₉ or X₂₀ or X₂₁ or X₂₂ or X₂₃ are nitrogen that R₂₀, R₂₁, R₂₂, R₂₃, R₂₄ are a free electron pair. In preferred instances, only two of X₁₉-X₂₃ are nitrogen and the remaining X groups are carbon. In other preferred instances, X₁₉ is a carbon and R₂₀ is a hydrogen.
wherein R₂₁, R₂₂, R₂₃, R₂₄, R₂₅, R₂₆, and R₂₇ are each independently selected from the group consisting of a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group,
wherein each of R₂₁ and R₂₂, R₂₂ and R₂₃, R₂₃ and R₂₄, R₂₅ and R₂₆, or R₂₆ and R₂₇ can optionally form a saturated, unsaturated, or aromatic, optionally substituted ring, optionally interrupted by a heteroatom, and having a total of from 5 to 18 carbon atoms and heteroatoms.

The dinuclear platinum(II) emitter complexes described herein are photo-stable, and are emissive at room temperatures, low temperatures, or a combination thereof. Accordingly, the complexes can be incorporated into organic light-emitting devices (OLEDs). Such OLEDs can be used in commercial applications such smart phones, televisions, monitors, digital cameras, tablet computers, lighting fixtures that usually operate at room temperatures, a fixed visual display unit, mobile visual display unit, illumination unit, keyboard, clothes, ornaments, garment accessary, wearable devices, medical monitoring devices, wallpaper, tablet PC, laptop, advertisement panel, panel display unit, household appliances, and office appliances.

### BRIEF DESCRIPTION OF THE DRAWINGS

FIG. 1 shows representative dinuclear platinum(II) emitter compounds Pt-1 to Pt-7 which were synthesized.

FIGS. 2A, 2B, 2C, and 2D each respectively show the room temperature emission spectra for thin films containing dinuclear platinum(II) emitters Pt-1 (4% in PMMA and 4% in mCP); Pt-2 (4% in PMMA); Pt-3 (4% in PMMA and 4% in mCP); and Pt-4 (4% in PMMA), respectively. FIG. 2E shows the room temperature emission spectra for thin films containing dinuclear platinum(II) emitters Pt-5 to Pt-7 (4% in PMMA each).

FIG. 3A shows the electroluminescent spectrum of Pt-1 (at 4, 8, 12, and 16 wt % in a host). FIG. 3B is a graph of the luminance (y-axis) versus voltage (x-axis) for OLED devices containing Pt-1 (at 4, 8, 12, and 16 wt % in a host). FIG. 3C is a graph of the current density (y-axis) versus voltage (x-axis) for OLED devices containing Pt-1 (at 4, 8, 12, and 16 wt % in a host). FIG. 3D is a graph of the EQE (y-axis) versus luminance (x-axis) for OLED devices containing Pt-1 (at 4, 8, 12, and 16 wt % in a host).

FIG. 4A shows the electroluminescent spectrum of Pt-2 (at 4, 8, and 12 wt % in a host mCP:B3PYMPM). FIG. 4B is a graph of the EQE (y-axis) versus luminance (x-axis) for OLED devices containing Pt-2 (at 4, 8, and 12 wt % in a host mCP:B3PYMPM). FIG. 4C is a graph of the luminance (y-axis) versus voltage (x-axis) for OLED devices containing Pt-2 (at 4, 8, and 12 wt % in a host mCP:B3PYMPM). FIG. 4D is a graph of the current density (y-axis) versus voltage (x-axis) for OLED devices containing Pt-2 (at 4, 8, and 12 wt % in a host mCP:B3PYMPM). FIG. 4E shows the electroluminescent spectrum of Pt-2 (at 4, 8, and 12 wt % in a host CzSi:BCPO). FIG. 4F is a graph of the EQE (y-axis) versus luminance (x-axis) for OLED devices containing Pt-2 (at 4, 8, and 12 wt % in a host CzSi:BCPO). FIG. 4G is a graph of the luminance (y-axis) versus voltage (x-axis) for OLED devices containing Pt-2 (at 4, 8, and 12 wt % in a host CzSi:BCPO). FIG. 4H is a graph of the current density (y-axis) versus voltage (x-axis) for OLED devices containing Pt-2 (at 4, 8, and 12 wt % in a host CzSi:BCPO).

FIG. 5A shows the electroluminescent spectrum of Pt-3 (at 8 wt % in different hosts: CzSi:TPSO1; BCPO:TSPO1; or BCPO:CzSi). FIG. 5B is a graph of the EQE (y-axis) versus luminance (x-axis) for OLED devices containing Pt-3 (at 8 wt % in different hosts: CzSi:TPSO1; BCPO:TSPO1; or BCPO:CzSi). FIG. 5C is a graph of the luminance (y-axis) versus voltage (x-axis) for OLED devices containing Pt-3 (at 8 wt % in different hosts: CzSi:TPSO1; BCPO:TSPO1; or BCPO:CzSi). FIG. 5D is a graph of the current density (y-axis) versus voltage (x-axis) for OLED devices containing Pt-3 (at 8 wt % in different hosts: CzSi:TPSO1; BCPO:TSPO1; or BCPO:CzSi). FIG. 5E shows the electroluminescent spectrum of Pt-3 (at 4, 8, and 12 wt % in a host CzSi:BCPO). FIG. 5F is a graph of the EQE (y-axis) versus luminance (x-axis) for OLED devices containing Pt-3 (at 4, 8, and 12 wt % in a host CzSi:BCPO). FIG. 5G is a graph of the luminance (y-axis) versus voltage (x-axis) for OLED devices containing Pt-3 (at 4, 8, and 12 wt % in a host CzSi:BCPO). FIG. 5H is a graph of the current density (y-axis) versus voltage (x-axis) for OLED devices containing Pt-3 (at 4, 8, and 12 wt % in a host CzSi:BCPO).

FIG. 6A shows the electroluminescent spectrum of Pt-4 (at 4, 8, 12, and 16 wt % in a host). FIG. 6B is a graph of the EQE (y-axis) versus luminance (x-axis) for OLED devices containing Pt-4 (at 4, 8, 12, and 16 wt % in a host). FIG. 6C is a graph of the luminance (y-axis) versus voltage (x-axis) for OLED devices containing Pt-4 (at 4, 8, 12, and 16 wt % in a host). FIG. 6D is a graph of the current density (y-axis) versus voltage (x-axis) for OLED devices containing Pt-4 (at 4, 8, 12, and 16 wt % in a host).

FIG. 7A shows the electroluminescent spectrum of Pt-5 (at 4, 8, and 12 wt % in a host CzSi). FIG. 7B is a graph of the EQE (y-axis) versus luminance (x-axis) for OLED devices containing Pt-5 (at 4, 8, and 12 wt % in a host CzSi). FIG. 7C is a graph of the luminance (y-axis) versus voltage (x-axis) for OLED devices containing Pt-5 (at 4, 8, and 12 wt % in a host CzSi). FIG. 7D is a graph of the current density (y-axis) versus voltage (x-axis) for OLED devices containing Pt-5 (at 4, 8, and 12 wt % in a host CzSi).

FIG. 8A shows the electroluminescent spectrum of Pt-6 (at 2 and 4 wt % in a host CzSi:BCPO). FIG. 8B is a graph of the EQE (y-axis) versus luminance (x-axis) for OLED devices containing Pt-6 (at 2 and 4 wt % in a host CzSi:BCPO). FIG. 8C is a graph of the luminance (y-axis) versus voltage (x-axis) for OLED devices containing Pt-6 (at 2 and 4 wt % in a host CzSi:BCPO). FIG. 8D is a graph of the current density (y-axis) versus voltage (x-axis) for OLED devices containing Pt-6 (at 2 and 4 wt % in a host CzSi:BCPO).

FIG. 9A shows the electroluminescent spectrum of Pt-7 (at 2, 4, 6, and 12 wt % in a host CzSi:BCPO). FIG. 9B is a graph of the EQE (y-axis) versus luminance (x-axis) for OLED devices containing Pt-7 (at 2, 4, 6, and 12 wt % in a host CzSi:BCPO).

FIG. 9C is a graph of the luminance (y-axis) versus voltage (x-axis) for OLED devices containing Pt-7 (at 2, 4, 6, and 12 wt % in a host CzSi:BCPO). FIG. 9D is a graph of the current density (y-axis) versus voltage (x-axis) for OLED devices containing Pt-7 (at 2, 4, 6, and 12 wt % in a host CzSi:BCPO).

FIG. 10A shows the electroluminescent spectrum of v-DABNA (1 wt % in mCBP), and Pt-7 (10 wt %) and v-DABNA (1 wt %) co-doped in mCBP. FIG. 10B is a graph of the EQE (y-axis) versus luminance (x-axis) for OLED devices containing v-DABNA (1 wt % in mCBP), and Pt-7 (10 wt %) and v-DABNA (1 wt %) co-doped in mCBP.

FIGS. 11A-11C show graphs of OLED lifetime measurement data for emitters Pt-2 (4 wt %), Pt-5 (4 wt %), and Pt-7 (10 wt %) in devices where the relative luminance (y-axis) versus time (x-axis), respectively, is shown.

FIG. 12A shows a graph of LT₅₀ (y-axis) versus L₀ (x-axis) for Pt-7 (10 wt % in mCBP), and Pt-7 (10 wt %) and v-DABNA (1 wt %) co-doped in mCBP. FIG. 12B shows a graph of the relative luminance (y-axis) versus time (x-axis) for Pt-7 (10 wt %) and v-DABNA (1 wt %) co-doped in mCBP. FIG. 12C shows a graph of the relative luminance (y-axis) versus time (x-axis) for Pt-7 (10 wt %) in mCBP.

FIG. 13 shows a non-limiting example of an organic light-emitting diode device, 100, having a multilayer architecture. The device contains (i) a cathode 110 including a first layer 120 and a second layer 130; (ii) an electron transporting layer 140; (iii) an optional carrier confinement layer 150; (iv) a light-emitting layer 160; (v) a hole-transporting layer 170; and (vi) an anode 180.

FIG. 14 shows a representation of an x-ray crystal structure of two molecular forms (left and right) of dinuclear platinum(II) emitter Pt-3 in crystal.

FIG. 15 shows a representation of an x-ray crystal structure of a molecular form of dinuclear platinum(II) emitter Pt-4 in crystal.

FIG. 16 shows a representation of an x-ray crystal structure of a molecular form of dinuclear platinum(II) emitter Pt-5 in crystal.

FIG. 17 shows a representation of an x-ray crystal structure of a molecular form of dinuclear platinum(II) emitter Pt-7 in crystal.

### DETAILED DESCRIPTION OF THE INVENTION

### I. Definitions

An “aryl radical” or “aryl group” is understood to mean a radical containing a structure made up of 6 to 30 carbon atoms, 6 to 18 carbon atoms, which is formed from one aromatic ring or a plurality of fused aromatic rings. Exemplary aryl radicals are, without limitation, phenyl, benzyl, naphthyl, anthracenyl, or phenanthrenyl. Aryl radicals may be unsubstituted, where all carbon atoms which are substitutable bear hydrogen atoms. Alternatively, they may be substituted at one, greater than one, or at all substitutable positions therein. Suitable exemplary substituents include, without limitation, alkyl radicals, such as alkyl radicals having 1 to 8 carbon atoms, which may be selected from methyl, ethyl, i-propyl or t-butyl, aryl radicals (such as C₆-aryl radicals, which may be substituted or unsubstituted), heteroaryl radicals (which may comprise at least one nitrogen atom, such as pyridyl radicals), alkenyl radicals (which may comprise one double bond and 1 to 8 carbon atoms), or groups with electron donating or electron accepting ability. Groups with electron donating ability are understood to mean groups which have a positive inductive (+I) and/or positive mesomeric (+M) effect, and groups with electron accepting ability are understood to mean groups which have a negative inductive (−1) and/or negative mesomeric (-M) effect. Suitable groups with donor or acceptor action are halogen radicals, such as F, Cl, Br, alkoxy radicals, aryloxy radicals, carbonyl radicals, ester radicals, amine radicals, amide radicals, CH₂F groups, CHF₂ groups, CF₃ groups, CN groups, thio groups, or SCN groups.

A “heteroaryl radical” or “heteroaryl group” is understood to mean radicals which differ from the aryl radicals described above in that at least one carbon atom in the structure making up the aryl radical is otherwise replaced by at least one heteroatom. Heteroatoms may have hydrogen substituents and/or any permissible substituents of organic compounds in order to satisfy the valences of the heteroatoms. Exemplary heteroatoms include N, O, and S. In most instances, one or two carbon atoms of the structure of the aryl radicals are replaced by heteroatoms. Exemplary heteroaryls include, without limitation, pyridyl, pyrimidyl, pyrazyl, triazyl, and five-membered heteroaromatics, such as pyrrole, furan, thiophene, pyrazole, imidazole, triazole, oxazole, thiazole. Heteroaryls may be substituted at none (unsubstituted), one, more than one, or at all substitutable positions. Suitable substituents are as defined above for the aryl radicals.

An “alkyl radical” or “alkyl group” is understood to mean a radical having 1 to 20 carbon atoms, 1 to 10 carbon atoms, or 1 to 8 carbon atoms. The alkyl radical may be branched or unbranched and the carbon chain may optionally be interrupted by one or more heteroatoms, such as N, O, or S. Heteroatoms may have hydrogen substituents and/or any permissible substituents of organic compounds in order ti satisfy the valences of the heteroatoms. The alkyl radical may optionally be substituted by one or more of the substituents mentioned for the aryl radicals above. It is also possible that the alkyl radical contain one or more aryl groups thereon, where suitable aryl groups are described above. Exemplary alkyl radicals include, without limitation, methyl, ethyl, i-propyl, n-propyl, i-butyl, n-butyl, t-butyl, sec-butyl, i-pentyl, n-pentyl, sec-pentyl, neopentyl, n-hexyl, i-hexyl and sec-hexyl. It is further understood that the term alkyl, as defined herein, can also refer to and encompasses radicals having degrees of unsaturation, where the alkyl radical may contain at least one carbon-carbon double bond (this can be referred to as an “alkenyl radical” or “alkenyl group” having 2 to 20 carbon atoms, 2 to 10 carbon atoms, or 2 to 8 carbon atoms, which may be optionally substituted) and/or at least one carbon-carbon triple bond (this can be referred to as an “alkynyl radical” or “alkynyl group” having 2 to 20 carbon atoms, 2 to 10 carbon atoms, or 2 to 8 carbon atoms, which may be optionally substituted). It is understood that the terms “alkenyl radical,” “alkenyl group,” “alkynyl radical,” and “alkynyl group” are each disclosed, as defined above, and may be used independently in the disclosure, as understood by the skilled person, where reference to alkyl radical or group is made. References to alkyl radical or alkyl group can be understood to refer to or encompass any combination of alkyl, alkenyl, and/or alkynyl groups or alkyl, alkenyl, and/or alkynyl radicals, where the alkenyl and alkynyl groups contain one or more degrees of unsaturation, as described above. In certain instances, references herein to alkyl radicals or alkyl groups specifically can be limited, as needed, to refer to alkyl groups or alkyl radicals having no degrees of unsaturation.

A “cycloalkyl radical” or “cycloalkyl group” is understood to mean a cyclic radical having 3 to 20 carbon atoms, 3 to 10 carbon atoms, or 3 to 8 carbon atoms. The carbon chain of the cycloalkyl radical may optionally be interrupted by one or more heteroatoms, such as N, O, or S. Heteroatoms may have hydrogen substituents and/or any permissible substituents of organic compounds in order to satisfy the valences of the heteroatoms. The cycloalkyl radical may be unsubstituted or substituted, i.e. substituted by one or more of the substituents mentioned herein. It is further understood that the term cycloalkyl, as defined herein, encompasses radicals having degrees of unsaturation where the cycloalkyl radical may contain at least one carbon-carbon double bond (this can be referred to as an “cycloalkenyl radical” or “alkenyl group” having 4 to 20 carbon atoms, 4 to 10 carbon atoms, or 4 to 8 carbon atoms, which may be optionally substituted) and/or at least one carbon-carbon triple bond (this can be referred to as an “cycloalkynyl radical” or “cycloalkynyl group” having 6 to 20 carbon atoms, 6 to 10 carbon atoms, or 6 to 8 carbon atoms, which may be optionally substituted).

“Carbonyl group,” as used herein, is understood to mean moieties which can be represented by the general formula:

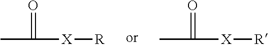

wherein X is a bond, or represents an oxygen or a sulfur, and R represents a hydrogen, a substituted or unsubstituted alkyl, substituted or unsubstituted alkenyl, substituted or unsubstituted alkynyl, substituted or unsubstituted cycloalkyl, substituted or unsubstituted aryl, or substituted or unsubstituted heteroaryl, —(CH₂)ₘ—R″; wherein R′ represents a hydrogen, substituted or unsubstituted alkyl, substituted or unsubstituted alkenyl, substituted or unsubstituted alkynyl, substituted or unsubstituted cycloalkyl, substituted or unsubstituted aryl, or substituted or unsubstituted heteroaryl or —(CH₂)ₘ—R″; wherein R″ represents a hydroxy group, substituted or unsubstituted carbonyl group, an aryl, a cycloalkyl, a heterocycle, or a polycycle; and m is zero or an integer ranging from 1 to 8. Where X is oxygen and R is defined as above, the moiety can be referred to as a “carboxyl group.” When X is oxygen and R is hydrogen, the formula represents a “carboxylic acid group.” Where X is oxygen and R′ is hydrogen, the formula represents a “formate group.” Where X is oxygen and R or R′ is not hydrogen, the formula represents an “ester group.” In general, where the oxygen atom of the above formula is replaced by a sulfur atom, the formula represents a “thiocarbonyl group.” Where X is sulfur and R or R′ is not hydrogen, the formula represents a “thioester group.” Where X is sulfur and R is hydrogen, the formula represents a “thiocarboxylic acid group.” Where X is sulfur and R′ is hydrogen, the formula represents a “thioformate group.” Where X is a bond and R is not hydrogen, the above formula represents a “ketone group.” Where X is a bond and R is hydrogen, the above formula represents an “aldehyde group.” The term “substituted carbonyl” refers to a carbonyl, as defined above, wherein one or more hydrogen atoms in R, R′ or a group to which the moiety is attached, are independently substituted with suitable substituents, as defined below.

An “amide group” or “amido” is understood to mean a moiety represented by the general formula:

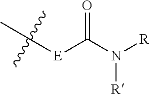

wherein, E is absent, or E is substituted or unsubstituted alkyl, substituted or unsubstituted alkenyl, substituted or unsubstituted alkynyl substituted or unsubstituted cycloalkyl, substituted or unsubstituted aryl, substituted or unsubstituted heteroaryl, wherein independently of E, R and R′ each independently represent a hydrogen, substituted or unsubstituted alkyl, substituted or unsubstituted alkenyl, substituted or unsubstituted alkynyl, substituted or unsubstituted carbonyl, substituted or unsubstituted cycloalkyl, substituted or unsubstituted aryl, or substituted or unsubstituted heteroaryl, —(CH₂)ₘ—R″′, or R and R′ taken together with the N atom to which they are attached complete a heterocycle having from 3 to 14 atoms in the ring structure; R″′ can represent a hydroxy group, substituted or unsubstituted carbonyl group, an aryl group, a cycloalkyl group, a heterocycle, or a polycycle; and m is zero or an integer ranging from 1 to 8. When E is oxygen, a “carbamate group” is formed. The carbamate cannot be attached to another chemical species, such as to form an oxygen-oxygen bond, or other unstable bonds, as understood by one of ordinary skill in the art.

The term “substituted,” as used herein, refers to all permissible substituents of the compounds or functional groups described above. Exemplary substituents include, but are not limited to, halogens, hydroxyl groups, or any other organic groupings containing any number of carbon atoms, preferably 1-14 carbon atoms, and optionally include one or more heteroatoms, such as oxygen, sulfur, or nitrogen grouping in linear, branched, or cyclic structural formats. Representative substituents can include alkyl, substituted alkyl (such as —CF₃ and —CD₃), alkenyl, substituted alkenyl, alkynyl, substituted alkynyl, phenyl, substituted phenyl, aryl, substituted aryl, heteroaryl, substituted heteroaryl, halo, hydroxyl, alkoxy, formyl, substituted alkoxy, phenoxy, substituted phenoxy, aroxy, substituted aroxy, thio (—SH), substituted thio, arylthio, substituted arylthio, cyano, isocyano, substituted isocyano, carbonyl, substituted carbonyl, carboxyl, substituted carboxyl, carboxylates, amino, substituted amino, amide, substituted amide, sulfonyl, substituted sulfonyl, sulfonic acid, phosphoryl, substituted phosphoryl, phosphonyl, substituted phosphonyl, polyaryl, substituted polyaryl, cyclic (such as C₃-C₂₀ cyclic), substituted cyclic (such as substituted C₃-C₂₀ cyclic), heterocyclic, substituted heterocyclic, deuterium, trihaloalkyl (trifluoromethyl), unsubstituted diarylamino, substituted diarylamino, unsubstituted dialkylamino, substituted dialkylamino, azo, carbonate ester, nitro, nitroso, phosphino, pyridyl, NRR′, SR, C(O)R, COOR, C(O)NR, SOR, and SOR groups, wherein R and R′ are independently selected from hydrogen atom, deuterium atom, or any of the substituents named above.

Numerical ranges disclosed in the present application include, but are not limited to, ranges of carbon atoms, ranges of temperatures, ranges of times, ranges of bias voltages, ranges of wavelengths, ranges of radiative lifetimes, ranges of quantum yields, ranges of integers, and ranges of luminances, ranges of current densities, ranges of current efficiencies, ranges of power efficiences, ranges of external quantum efficiencies, amongst others. The disclosed ranges, disclose individually each possible number that such a range could reasonably encompass, as well as any sub-ranges and combinations of sub-ranges encompassed therein. For example, disclosure of a range of carbon atoms is intended to disclose individually every possible value that such a range could encompass, consistent with the disclosure herein. For example, a carbon range of 1 to 10 carbons also discloses each number of carbons within the range individually (1, 2, 3, 4, 5, 6, 7, 8, 9, 10 carbons), as well as any sub-range contained therein (2 to 4 carbons or 5 to 9 carbons).

Use of the term “about” is intended to describe values either above or below the stated value, which the term “about” modifies, in a range of approx. +/−10%; in other instances the values may range in value either above or below the stated value in a range of approx. +/−5%. When the term “about” is used before a range of numbers (i.e., about 1-5) or before a series of numbers (i.e., about 1, 2, 3, 4, etc.) it is intended to modify both ends of the range of numbers and/or each of the numbers recited in the entire series, unless specified otherwise.

### II. Phosphorescent Emitter Complexes

Described herein are dinuclear platinum emitter complexes which contain platinum (II) which is complexed by cyclometalating ligand (i.e., capable of forming a metal-carbon σ-bond) and triazole-based and/or pyrazole-based ligands in a double-decker coordination geometry while maintaining a short intramolecular Pt-Pt distance. “Short intramolecular Pt-Pt distance,” as used herein, refers to a platinum-platinum distance in the disclosed complexes of less than about 3.5 Å, 3.4 Å, 3.3 Å, 3.2 Å, 3.1 Å, or 3.3 Å; or a platinum-platinum distance in the complexes of between about 3 to 3.5 A and sub-ranges within.

It is generally believed that the open double-decker coordination geometry and short intramolecular Pt-Pt distances provide a high-energy³MMLCT excited state that can provide for a combination of high emission quantum yield and short radiative lifetimes for the dinuclear platinum emitter complexes described below.

### A. Dinuclear Platinum (II) Emitter Complexes

The dinuclear platinum emitter complexes can have a structure according to formulas (I) or (II), as follows:

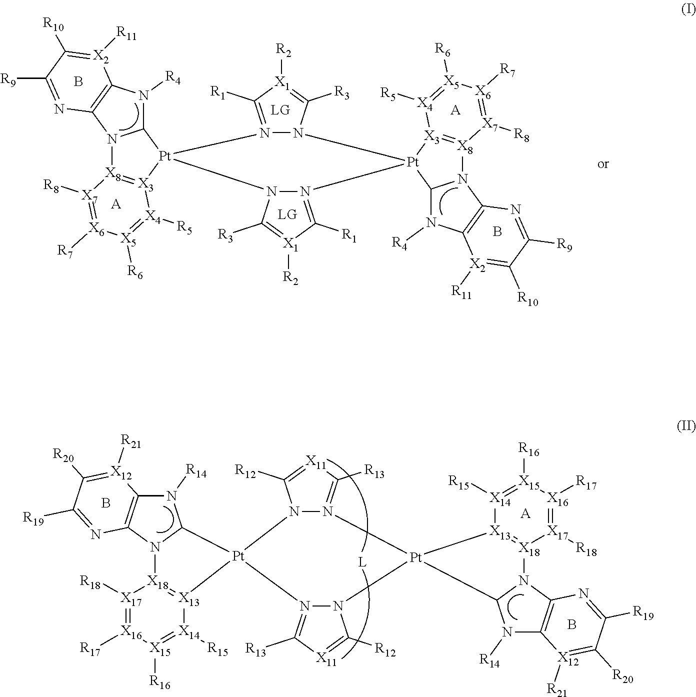

wherein each ligand, such as denoted LG in formula (I), is independently bonded to both platinum atoms,
wherein R₁, R₂, R₃, R₁₂, and R₁₃ for each of formulas (I) or (II) are each independently selected from the group consisting of a hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein R₄ and R₁₄ for each of formulas (I) or (II) are each independently selected from the group consisting of a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein each X₁ in formula (I) is independently selected from carbon or nitrogen with the proviso that R₂ is a free electron pair when X₁ is nitrogen,
wherein each X₂ in formula (I) is independently selected from carbon or nitrogen with the proviso that R₁₁ is a free electron pair when X₂ is nitrogen,
wherein each X₁₂ in formula (II) is independently selected from carbon or nitrogen with the proviso that R₂₁ is a free electron pair when X₁₂ is nitrogen,
wherein ring A in formula (I) is a 6-member carbon ring or a 6-member heterocyclic ring having at least one nitrogen atom where X₈ is a carbon and each of X₃ or X₄ or X₅ or X₆ or X₇ are independently selected from carbon or nitrogen with the proviso that when any of X₄ or X₅ or X₆ or X₇ are nitrogen that R₅, R₆, R₇, R₈ are a free electron pair. In preferred instances, only two of X₃-X₇ groups are nitrogen and the remaining X groups are carbons. In some particular instances, X₃ is a carbon,
wherein ring B in formula (I) is a 6-member ring having at least one nitrogen atom. In some instances, ring B has two nitrogen atoms when X₂ is nitrogen,
wherein ring A in formula (II) is a 6-member carbon ring or a 6-member heterocyclic ring having at least one nitrogen atom where X₁₈ is a carbon and each of X₁₃ or X₁₄ or X₁₅ or X₁₆ or X₁₇ are independently selected from carbon or nitrogen with the proviso that when any of X₁₄ or X₁₅ or X₁₆ or X₁₇ are nitrogen that R₁₅, R₁₆, R₁₇, R₁₈ are a free electron pair. In preferred instances, only two of X₁₃-X₁₇ groups are nitrogen and the remaining X groups are carbons. In some particular instances, X₁₃ is a carbon,
wherein ring B in formula (II) is a 6-member ring having at least one nitrogen atom. In some instances, ring B has two nitrogen atoms when X₁₂ is nitrogen,
wherein R₅, R₆, R₇, R₈, R₉, R₁₀, R₁₁, R₁₅, R₁₆, R₁₇, R₁₈, R₁₉, R₂₀, and R₂₁, of formulas (I) or (II) are each independently selected from the group consisting of a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group (such as —OMe); an amino group; a hydroxyl group; a formyl group; an acyl group; a thio group; an ester group; a carbonyl group; a carboxylate group; an amide group; a nitro group; and an SiMe₃ group,
wherein each of R₅ and R₆, R₆ and R₇, R₇ and R₈, R₉ and R₁₀, R₁₀ and R₁₁, R₁₅ and R₁₆, R₁₆ and R₁₇, R₁₇ and R₁₈, R₁₉ and R₂₀, or R₂₀ and R₂₁, can optionally form a saturated, unsaturated, or aromatic, optionally substituted ring, optionally interrupted by a heteroatom, and having a total of from 5 to 18 carbon atoms and heteroatoms,
wherein in L in formula (II) is a linker group which is a substituted or unsubstituted linear or branched alkyl radical having from 1 to 20 carbon atoms, optionally interrupted by at least one heteroatom and/or aryl group and/or cycloalkyl and/or heteroaryl group and/or heterocycloalkyl group and optionally having at least one substituent group thereon; or a substituted or unsubstituted alkenyl radical having 2 to 20 carbon atoms, or a substituted or unsubstituted alkynyl radical having 2 to 20 carbon atoms; or is a linker group comprising two terminal phenol groups each attached to the two X₁₁ groups and the two terminal phenol groups each are linked together via a linear or branched alkyl radical, optionally interrupted by at least one heteroatom and/or aryl group and optionally having at least one substituent group thereon.

It is believed that the presence of a linker L, as shown in genus formula (II) can help to rigidify the molecular structure of dinuclear platinum(II) emitter complex and slow down the non-radiative decay process related or due to structural distortion.

Further, the linker could also improve the stability of dinuclear platinum(II) emitter complexes, as the metal-ligand bond lengths of complex with a linker L were observed to be shortened by 0.01-0.03 Å in the crystal structure, which implies stronger metal-ligand bond strength. The presence of a linker could allow refinement on the coordination geometry and photophysical properties of emitter without perturbing its emission energy.

In certain instances, R₁, R₂, R₃, R₅, R₆, R₇, R₈, R₉, R₁₀, R₁₁, R₁₂, R₁₃, R₁₅, R₁₆, R₁₇, R₁₈, R₁₉, R₂₀, and R₂₁ of formulas (I) or (II) can each independently be halogen or deuterium substituted alkyl radicals, such as —CF₃ and —CD₃.

The dinuclear platinum(II) emitter complex may of the above formulae can exist as individual compounds or as mixtures of any two or more possible isomers. In some instances, the dinuclear platinum(II) emitter complex is of formula (I) where X₁ is nitrogen and X₂is a carbon; each R₁ and R₃ is an aryl radical, such as an optionally substituted phenyl ring; each R₄ is a linear or branched alkyl radical, such as a methyl group; and R₅, R₆, R₇, R₈, R₉, R₁₀, and R₁₁ are selected from hydrogen, linear or branched alkyl radical, halogen, alkoxyl radical, or Si(R_{q})₃, where R_{q} is a linear or branched alkyl radical, alkoxyl radical or aryl; and X₃ to X₈ are carbon.

In some other instances, the dinuclear Platinum(II) emitter complex is of formula (I) where X₁ is nitrogen and X₂ is a nitrogen; each R₁ and R₃ is a linear or branched alkyl radical, such as a methyl group; each R₄ is a linear or branched alkyl radical, such as a methyl group; R₈, R₉, R₁₀, and R₁₁ are selected from hydrogen, linear or branched alkyl radical, halogen, alkoxyl radical, or Si(R_{q})₃, where R_{q} is a linear or branched alkyl radical, alkoxyl radical or aryl; and R₅, R₆, and R₇ are each a halogen, where the halogen may be fluorine; and X₃ to X₈ are carbon.

In some other instances, the dinuclear Platinum(II) emitter complex is of formula (I) where X₁ is nitrogen and X₂ is a carbon; each R₁ and R₃ is a linear or branched alkyl radical, such as a methyl group; each R₄ is a linear or branched alkyl radical, such as a methyl group; R₈, R₉, R₁₀, and R₁ are selected from hydrogen, linear or branched alkyl radical, halogen, alkoxyl radical, or Si(R_{q})₃, where R_{q} is a linear or branched alkyl radical, alkoxyl radical or aryl; and R₅, R₆, and R₇ are each a halogen, where the halogen may be fluorine; and X₃ to X₈ are carbon.

In some other instances, the dinuclear Platinum(II) emitter complex is of formula (I) where X₁ is nitrogen and X₂ is a nitrogen; each R₁ and R₃ is a linear or branched alkyl radical, such as a methyl group; each R₄ is a linear or branched alkyl radical, such as a methyl group; R₈, R₉, R₁₀, and R₁ are selected from hydrogen, linear or branched alkyl radical, halogen, alkoxyl radical, or Si(R_{q})₃, where R_{q} is a linear or branched alkyl radical, alkoxyl radical or aryl; and R₅, R₆, and R₇ are each a halogen, where the halogen may be fluorine; and X₃ to X₈ are carbon. In still some other instances, the dinuclear platinum(II) emitter complex is of formula (I) where X₁ is carbon and X₂is a carbon; each R₂ is a hydrogen; each R₁ and R₃ is a linear or branched alkyl radical, such as a methyl group; each R₄ is a linear or branched alkyl radical, such as a methyl group; R₈, R₉, R₁₀, and R₁ are selected from hydrogen, linear or branched alkyl radical, halogen, alkoxyl radical, or Si(R_{q})₃, where R_{q} is a linear or branched alkyl radical, alkoxyl radical or aryl; and R₅, R₆, and R₇ are each a halogen, where the halogen may be fluorine.

In some other instances, the dinuclear Platinum(II) emitter complex is of formula (I) where X₁ is carbon and X₂ is a nitrogen; each R₁ and R₃ is a linear or branched alkyl radical, such as a methyl group; each R₄ is a linear or branched alkyl radical, such as a methyl group; R₈, R₉, R₁₀, and R₁₁ are selected from hydrogen, linear or branched alkyl radical, halogen, alkoxyl radical, or Si(R_{q})₃, where R_{q} is a linear or branched alkyl radical, alkoxyl radical or aryl; and R₅, R₆, and R₇ are each a halogen, where the halogen may be fluorine; and X₃ to X₈ are carbon.

In some other cases, the dinuclear platinum(II) emitter complex is of formula (II) where X₁₁ is a carbon and X₁₂is a carbon; each R₁₂ and R₁₃ is a linear or branched alkyl radical, such as a methyl group; each R₁₄ is a linear or branched alkyl radical, such as a methyl group; R₁₈, R₁₉, R₂₀, and R₂₁ are each hydrogen R₁₅, R₁₆, and R₁₇ are each a halogen, where the halogen may be fluorine; and the linker group L is a linear or branched alkyl radical.

In some instances, the linker group L of formula (II) can be a linear alkyl radical, such as *—(CRₐR_{b})ₙ—*, where n is an integer value from 5 to 20, and Rₐ and R_{b} can be a hydrogen; a halogen; a substituted or unsubstituted linear or branched alkyl radical having from 1 to 20 carbon atoms, optionally interrupted by at least one heteroatom and/or aryl group and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group.

In some cases, the linker L is *—(CRₐR_{b})ₙ—* where Rₐ and R_{b} are each hydrogen and n is 10. In yet other instances, the linker L can have a formula selected from:

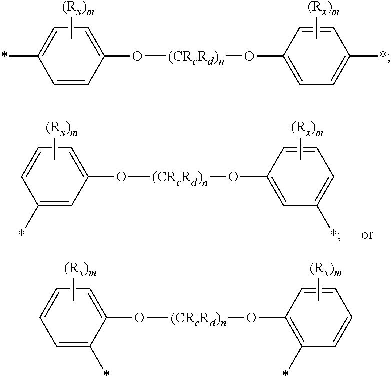

where each n can have an integer value from 3 to 20, and each R_{c} and R_{d} can independently be a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group; where each Rₓ is typically hydrogen and m is 4 but alternatively each Rₓ can represent one or more optional substituents, which may independently be present, when m is 1, 2, 3, or 4 and each Rₓ can be selected from a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group.

In still other instances, the linker L can be a group having a formula selected from:

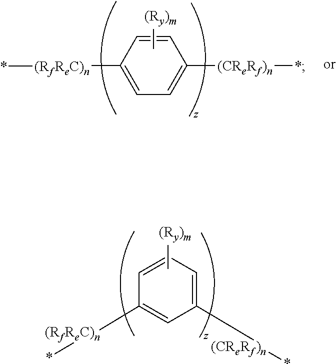

where each n and z are independently an integer value from 1 to 20, and each Rₑ and R_{f} can each independently be a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group; where Ry is typically hydrogen and m is 4 but alternatively Ry can represent one or more optional substituents, which may independently be present, when m is 1, 2, 3, or 4, where any remaining unsubstituted positions are hydrogen, and each Ry can be selected from a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group.

Exemplary dinuclear platinum(II) emitter complexes can have a structure selected from:

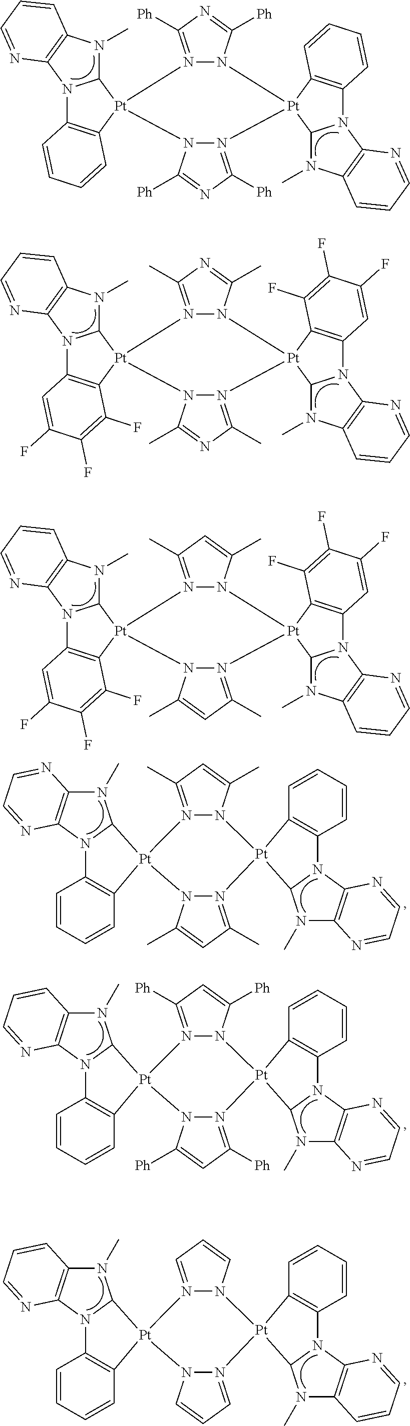

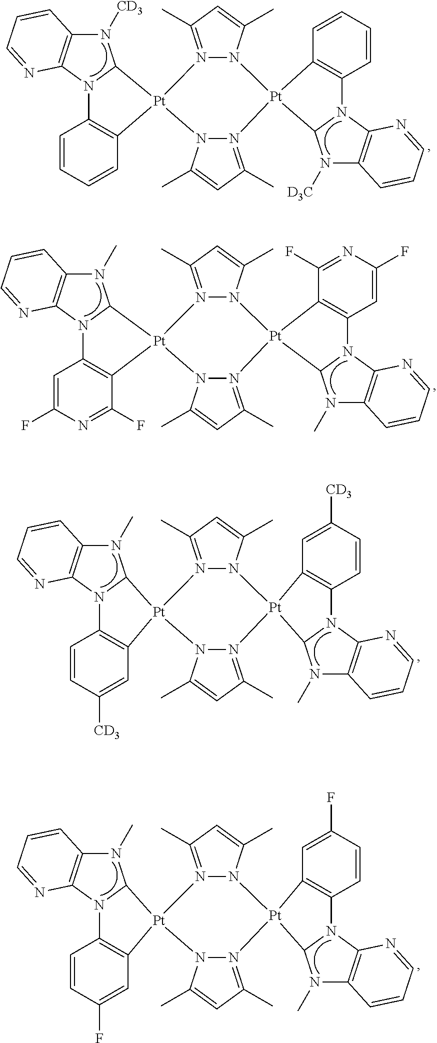

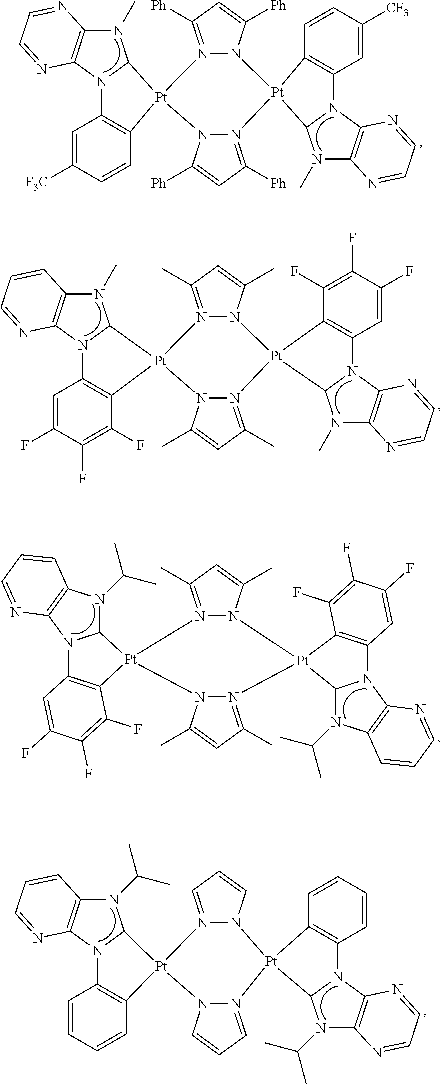

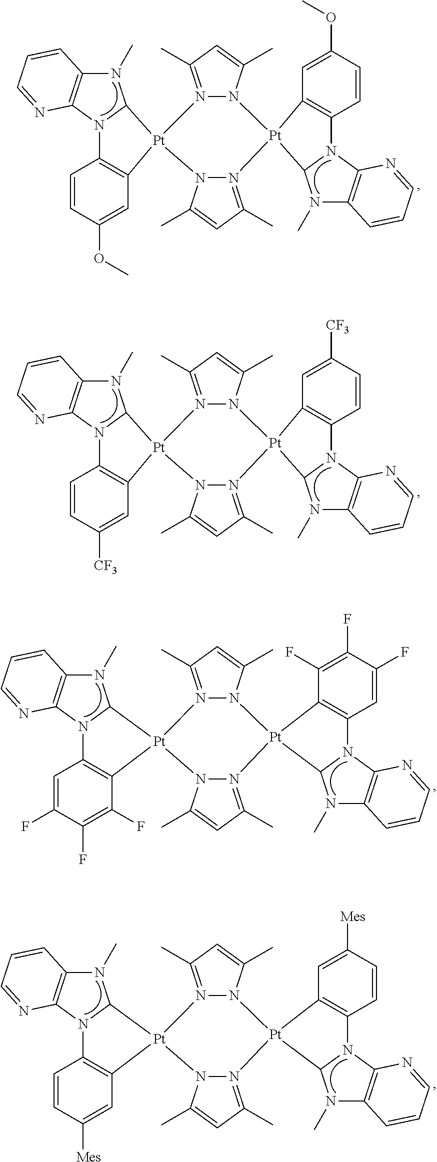

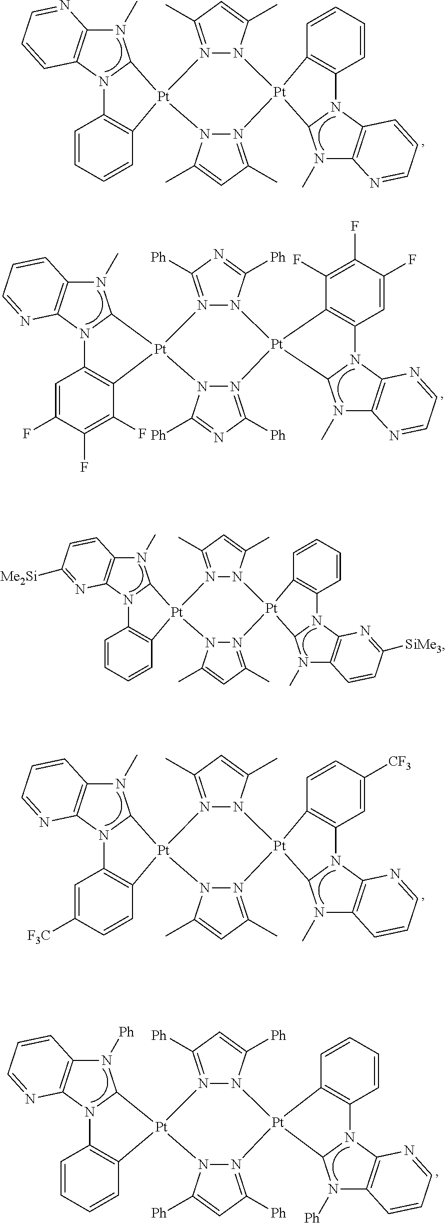

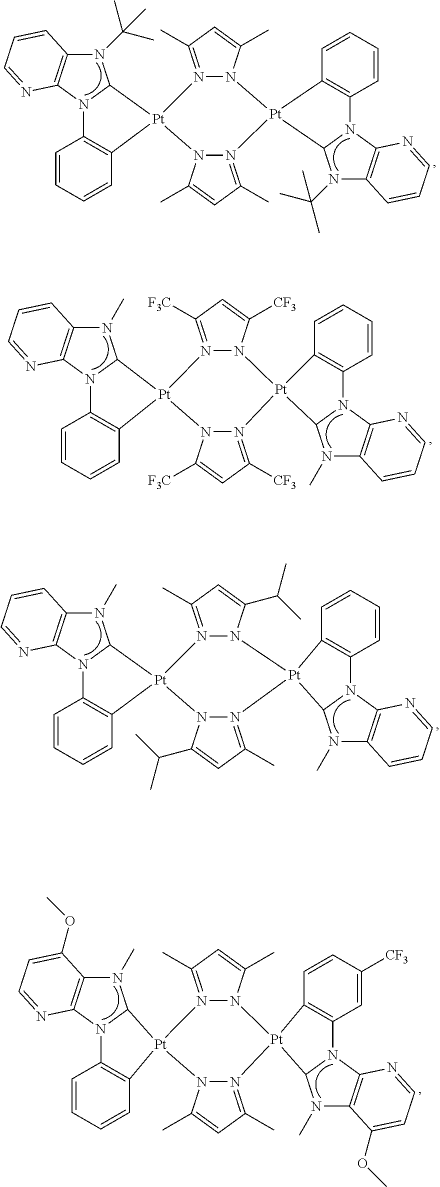

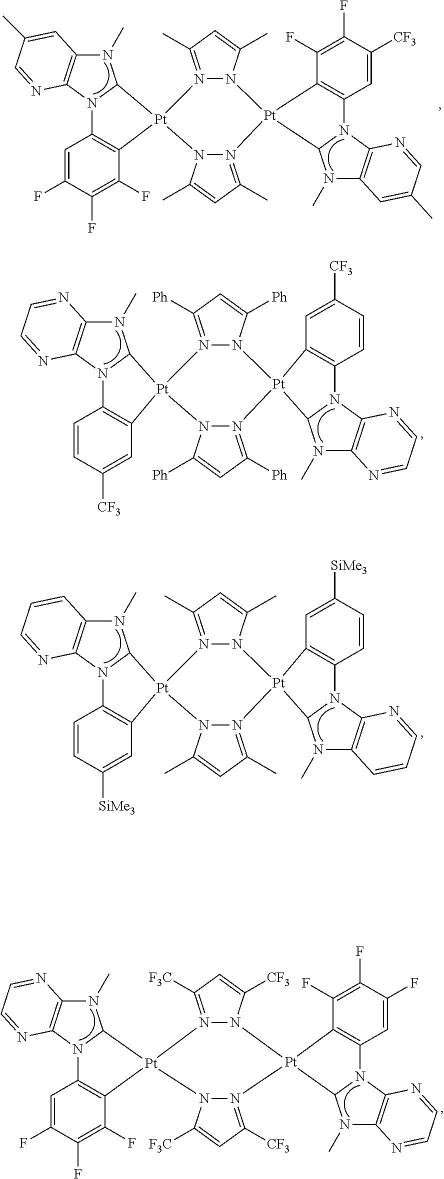

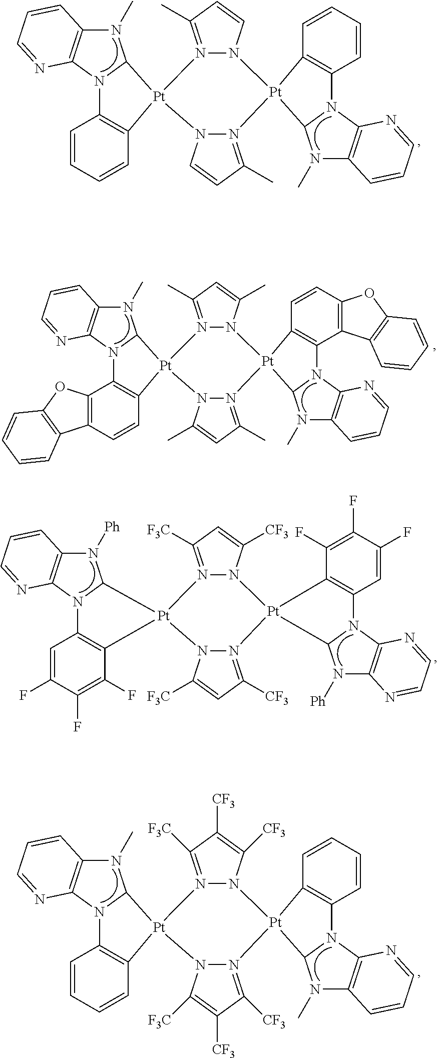

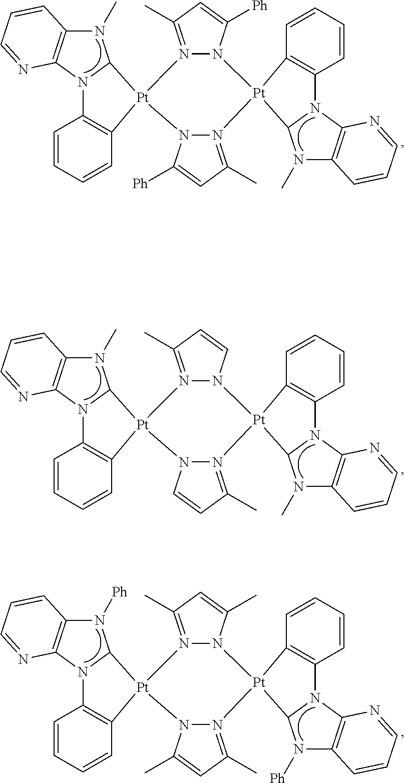

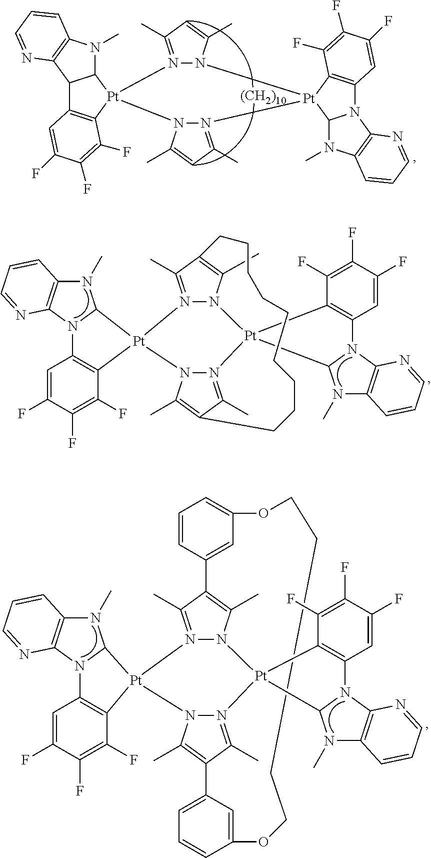

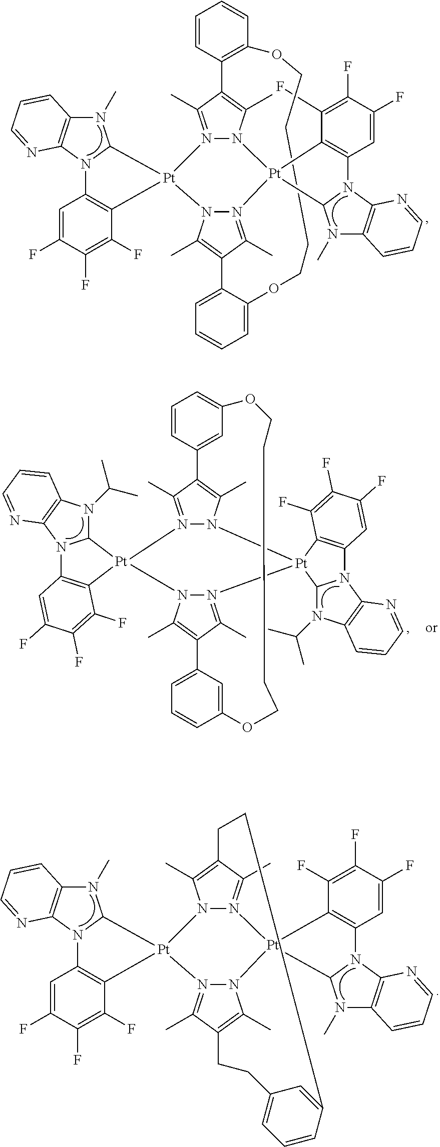

The dinuclear platinum emitter complexes are phosphorescent and electroluminescent. The dinuclear platinum emitter complexes can be emissive at room temperature, low temperature, or both. The dinuclear platinum emitter complexes may be in a solid, liquid, glassy, film, or solution state.

The dinuclear platinum emitter complexes can emit light in response to (i) the passage of an electric current or (ii) to an electric field. In some forms, the dinuclear platinum emitter complexes may emit light independent of concentration.

The phosphorescent and electroluminescent properties of the dinuclear platinum emitter complexes are typically within a wavelength range of between about 380 nm and 550 nm, inclusive. In some instances, the dinuclear platinum emitter complexes preferably emit blue to sky-blue light within a wavelength range of between about 400 nm and 550 nm, inclusive, or any sub-range within. The emissive properties of the dinuclear platinum emitter complexes can be tuned by way of the selection of substituents. The dinuclear platinum emitter complexes may emit exclusively or predominantly in the blue wavelength range of the visible spectrum and may contain one or two emission maxima within.

The dinuclear platinum emitter complexes can produce blue electroluminescence, when present in an OLED device, with CIE(x, y) coordinates of 0.14-0.15, 0.20-0.24 and 0.13-15, 0.11-0.19, respectively, at different doping concentrations ranging from 5 to 20 wt % in a host. In OLED devices, the blue index (current efficiency/CIE-y) may be in a range of between about 125 to 230, 130 to 200, or 130-170.

In some instances, the dinuclear platinum emitter complexes demonstrate high emission quantum yields of at least about 0.5, 0.55, 0.6, 0.65, 0.7, 0.75, 0.8, 0.85, 0.9, or 0.95; or the emission quantum yield is within a range of about 0.5 to 0.95, or any sub-range within. In some instances, the dinuclear platinum emitter complexes demonstrate an emission lifetime within a range of about 0.7 to 3.5 μs or 0.8 to 2.0 μs, as well as sub-ranges or individual values within these ranges. The dinuclear platinum emitter complexes can have an emission lifetime of about 0.8, 0.9, 1.0, 1.1, 1.2, 1.3, 1.4, 1.5, 1.6, 1.7, 1.8, 1.9, or 2.0 μs.

In some instances, the dinuclear platinum emitter complexes demonstrate short radiative rate constants in a range of about 4.5×10⁵ to 10×10⁵ s⁻¹, or any sub-range or value disclosed within. In some instances, the dinuclear platinum emitter complexes demonstrate a short radiative lifetime within a range of about 1.0 to 4.0 μs or 1.0 to 2.0 μs. as well as sub-ranges or individual values within these ranges. The dinuclear platinum emitter complexes can have a radiative lifetime of about 1.0, 1.1, 1.2, 1.3, 1.4, 1.5, 1.6, 1.7, 1.8, 1.9, or 2.0 μs. In some cases, the dinuclear platinum emitter complexes demonstrate a high radiative decay rate constant of at least 10⁶ s⁻¹.

Every compound within the above genus definitions is intended to be and should be considered to be specifically disclosed herein. Further, every subgroup that can be identified within the above definition is intended to be and should be considered to be specifically disclosed herein. As a result, it is specifically contemplated that any compound or subgroup of compounds can be either specifically included for or excluded from use or included in or excluded from a list of compounds. For example, any one or more of the compounds described herein, with a structure depicted herein, or referred to in the Tables or the Examples herein can be specifically included, excluded, or combined in any combination, in a set or subgroup of such compounds. Such specific sets, subgroups, inclusions, and exclusions can be applied to any aspect of the compositions and methods described here. For example, a set of compounds that specifically excludes one or more particular compounds can be used or applied in the context of compounds per se (for example, a list or set of compounds), compositions including the compound, any one or more of the disclosed methods, or combinations of these. Different sets and subgroups of compounds with such specific inclusions and exclusions can be used or applied in the context of compounds per se, compositions including one or more of the compounds, or any of the disclosed methods. All of these different sets and subgroups of compounds—and the different sets of compounds, compositions, and methods using or applying the compounds—are specifically and individual contemplated and should be considered as specifically and individually described. For example, the following can be specifically included or excluded, as a group or individually, from any compounds per se (for example, a list or set of compounds), compositions including the compound, or any one or more of the disclosed methods, or combinations of these. For example, the compounds of formula I or formula II can exclude any of the complexes containing tetradentate ligands described in U.S. Pat. No. 9,108,998 by Molt, et al.

### III. Methods of Making

### A. Dinuclear Platinum (II) Emitter Complexes

The dinuclear platinum(II) emitter complexes and the ligands described herein can be synthesized using methods known in the art of organic chemical synthesis. For instance, ligands can be purchased from commercial chemical manufacturers or may be prepared according to procedures reported and/or adapted from the literature. The selection of appropriate synthetic conditions, reagents, reaction workup conditions, purification techniques (as needed) are known to those in the field of synthesis. Exemplary and non-limiting syntheses of ligands and dinuclear platinum(II) emitter complexes are discussed in the Examples below.

In one non-limiting exemplary method, the dinuclear platinum(II) emitter complex can be prepared by:
contacting a platinum (Pt) compound with a first ligand selected from a pyrazole ligand, a triazole ligand, or a combination thereof, and a second ligand according to formula (III)

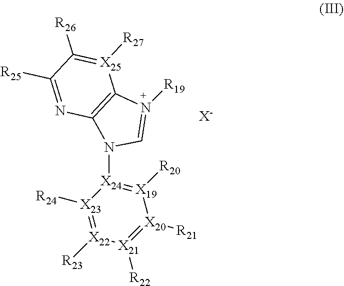

wherein R₁₉ is selected from the group consisting of a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein X₁₉ is independently selected from carbon or nitrogen with the proviso that R₂₀ is hydrogen when X₁₉ is a carbon and R₂₀ is a free electron pair when X₁₉ is nitrogen,
wherein X₂₅ is independently selected from carbon or nitrogen with the proviso that R₂₆ is a free electron pair when X₂₅ is nitrogen,
wherein X₂₄ is carbon and each of X₁₉ or X₂₀ or X₂₁ or X₂₂ or X₂₃ are independently selected from carbon or nitrogen with the proviso that when any of X₁₉ or X₂₀ or X₂₁ or X₂₂ or X₂₃ are nitrogen that R₂₀, R₂₁, R₂₂, R₂₃, R₂₄ are a free electron pair. In preferred instances, only two of X₁₉-X₂₃ are nitrogen and the remaining X groups are carbon. In other preferred instances, X₁₉ is a carbon and R₂₀ is a hydrogen.
wherein R₂₁, R₂₂, R₂₃, R₂₄, R₂₅, R₂₆, and R₂₇ are each independently selected from the group consisting of a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group,
wherein each of R₂₁ and R₂₂, R₂₂ and R₂₃, R₂₃ and R₂₄, R₂₅ and R₂₆, or R₂₆ and R₂₇ can optionally form a saturated, unsaturated, or aromatic, optionally substituted ring, optionally interrupted by a heteroatom, and having a total of from 5 to 18 carbon atoms and heteroatoms.

In some instances the halide is the halide is an iodide, a chloride, or a bromide.

The platinum(II) compound above can be any suitable platinum(II) salt. An exemplary platinum(II) salt includes, but is not limited to, dichloro(1,5-cyclooctadiene) platinum(II), sodium or potassium tetrachloroplatinate, platinum(II) acetate, platinum(II) acetylacetonate, or bis(benzonitrile)dichloroplatinum(II). Various platinum(II) salts which can be used to form the complexes described are known in the art and commercially available.

In some instances, for the ligand of formula (III) R₁₉ is a linear or branched alkyl radical, such as a methyl group; and R₂₀, R₂₁, R₂₂ are each a halogen, such as fluorine.

In some instances, the first ligand is a pyrazole ligand having a structure according to formula (IV)

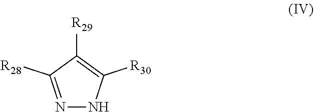

wherein R₂₈, R₂₉, and R₃₀ are each independently selected from the group consisting of a hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms. In some cases, the pyrazole ligand of formula (IV) has a structure:

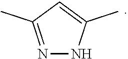

In some other instances, the first ligand is a pyrazole ligand having a structure according to formula (V)

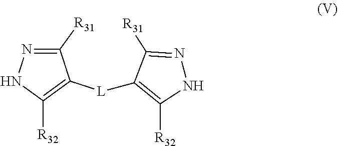

wherein L is a linker group which is a substituted or unsubstituted linear or branched alkyl radical having from 1 to 20 carbon atoms, optionally interrupted by at least one heteroatom and/or aryl group and/or cycloalkyl and/or heteroaryl group and/or heterocycloalkyl group, optionally having at least one substituent group thereon; or a substituted or unsubstituted alkenyl radical having 2 to 20 carbon atoms, or a substituted or unsubstituted alkynyl radical having 2 to 20 carbon atoms. In some other instances, L is a linker group having two phenol groups linked with linear or branched alkyl radical, optionally interrupted by at least one heteroatom and/or aryl group and optionally having at least one substituent group thereon, and
wherein R₃₁ and R₃₂ are each independently selected from the group consisting of a hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms.

In some cases, the linker L in formula (V) is *—(CRₐR_{b})ₙ—* where Rₐ and R_{b} are each hydrogen and n is 10. In yet other instances, the linker L can have a formula selected from:

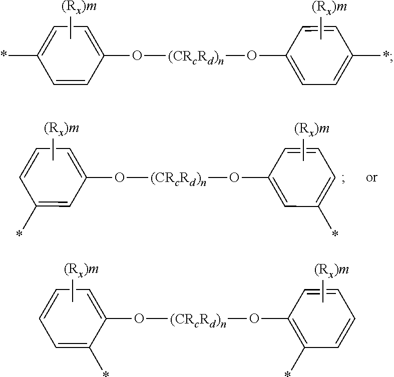

where each n can have an integer value from 3 to 20, and each R_{c} and R_{d} can independently be a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group; where each Rₓ is typically hydrogen and m is 4 but alternatively each Rₓ can represent one or more optional substituents, which may independently be present, when m is 1, 2, 3, or 4 and each Rₓ can be selected from a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group.

In still other instances, the linker L can be a group having a formula selected from:

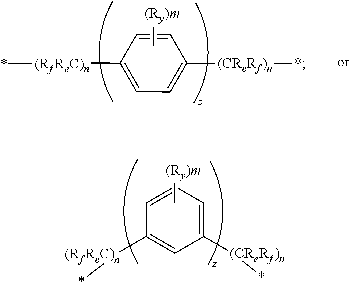

where each n and z are independently an integer value from 1 to 20, and each Rₑ and R_{f} can each independently be a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group; where Ry is typically hydrogen and m is 4 but alternatively Ry can represent one or more optional substituents, which may independently be present, when m is 1, 2, 3, or 4, where any remaining unsubstituted positions are hydrogen, and each Ry can be selected from a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group.

In some cases, the pyrazole ligand of formula (V) has a structure:

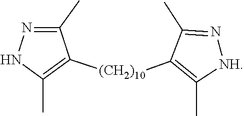

In yet other instances, the first ligand is a triazole ligand having a structure according to formula (VI)

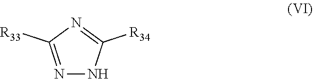

wherein R₃₃ and R₃₄ are each independently selected from the group consisting of a hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms. In some cases, the triazole ligand of formula (VI) has a structure:

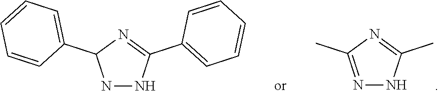

### B. Ligands

Synthetic methods for preparing ligands of formulas (III)-(VI) described above are known or may be adapted from the literature. In some instances, pyrazole and triazole ligands described herein and used in the examples below can be readily obtained from commercial chemical manufacturers. Example syntheses of an NHC ligands and a bridging ligands are described in the Examples below.

### IV. Uses for the Dinuclear Platinum (II) Emitter Complexes

The dinuclear platinum(II) emitter complexes described herein are photo-stable, and are emissive at room temperatures, low temperatures, or a combination thereof. Accordingly, the complexes can be incorporated into organic light-emitting devices (OLEDs). Such OLEDs can be used in commercial applications such smart phones, televisions, monitors, digital cameras, tablet computers, lighting fixtures that usually operate at room temperatures, a fixed visual display unit, mobile visual display unit, illumination unit, keyboard, clothes, ornaments, garment accessary, wearable devices, medical monitoring devices, wall paper, tablet PC, laptop, advertisement panel, panel display unit, household appliances, and office appliances.

Methods of preparing OLEDs containing one or more dinuclear platinum(II) emitter complexes, as described above, are well-known in the art of organic electronics. Such method of making OLEDs can involve vacuum deposition or solution processing techniques, such as spin-coating and ink-jet printing. The selection of suitable materials (anode, cathode, hole transport layer, electron transport layer, etc.) and fabrication parameters (such as deposition conditions or solvent selections) needed to fabricate OLEDs containing the dinuclear platinum(II) emitter complexes described herein are known in the art.

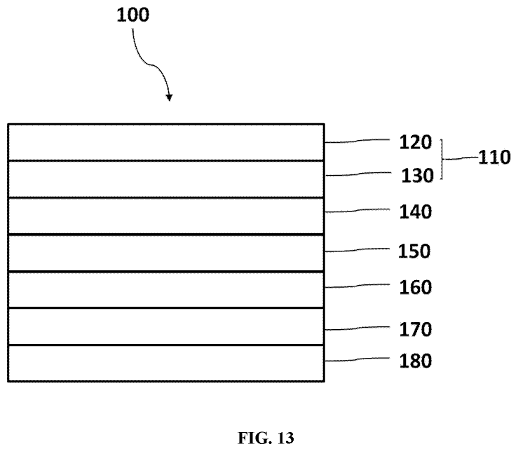

In one non-limiting example, organic light-emitting devices can have an ordered structure containing at least an anode, a hole-transporting layer, a light-emitting layer, an electron-transporting layer, and a cathode, wherein the light-emitting layer contains a dinuclear platinum(II) emitter complex, as described above. Referring to FIG. 13, an organic light-emitting device OLED 100 can include (i) a cathode 110 preferably including an aluminum layer 120 and a lithium layer 130; (ii) optionally, an electron transporting layer 140; (iii) optionally, a carrier confinement layer 150; (iv) a light-emitting layer 160 containing a dinuclear platinum(II) emitter complex described herein; (v) optionally, a hole-transporting layer 170; and (vi) an anode 180, such as indium tin oxide-coated glass. Flexible substrates other than glass, such as on plastic are also known in the art. The above is a non-limiting illustration of an OLED device which may be fabricated. It is understood that various other OLED architectures are possible.

The light-emitting layer is formed by doping the dinuclear platinum(II) emitter complex, as a dopant, into a host compound and the luminescent compound has a percent composition between about 5 wt % and 20 wt %, such as about 5 to 15 wt %, of the light-emitting layer. In some forms, the light-emitting layer has a thickness between about 10 nm and 60 nm, such as 30 nm.

In some forms, the light-emitting layer contains a host compound selected from, but is not limited to, 1,3-bis(N-carbazolyl)benzene (mCP), 4,4′-bis(carbazol-9-yl)biphenyl (CBP), 4,4′,4″-tris(carbazol-9-yl)- triphenylamine (TCTA), 3-(4-biphenylyl)-4-phenyl-5-tert-butylphenyl-1,2,butylphenyl-1,2,4-triazole (TAZ), p-bis(triphenylsilyl)benzene (UGH2), 9-(4-tert-Butylphenyl)-3,6-bis(triphenylsilyl)-9H-carbazole (CzSi), Bis-4-(N-carbazolyl)phenyl )phenylphosphine oxide (BCPO), diphenyl-4-triphenylsilylphenyl-phosphine oxide (TSPO1), and suitable combinations thereof. For example, two hosts, such as CzSi:TSPO1, BCPO:TSPO1, and BCPO:CzSi may be used in some cases at suitable relative ratios. Exemplary relative molar ratios of two respective hosts can range from between about 0.5:1 to 2:1.

In some forms, the hole-transporting layer contains an organic compound that can be, but is not limited to, 4,4′-bis[N-(1-naphthyl)-N-phenylamino]biphenyl (NPB), 4,4′-bis[N-(3-methylphenyl)-N-phenylamino]biphenyl (TPD), 4,4′,4″-tris[(3-methylphenyl)phenylamino] triphenylamine (MTDATA), and di-[4-(N,N-ditolyl-amino)phenyl]cyclohexane (TAPC). In addition, polymeric hole-transporting materials can be used including poly(N-vinylcarbazole) (PVK), polythiophene, polypyrrole, polyaniline, and copolymers including PEDOT:PSS. In some forms, the hole-transporting layer has a thickness between about 10 nm and 70 nm, such as 40 nm.

In some forms, the electron-transporting layer contains an organic compound that can be, but is not limited to, 1,3,5-tris(phenyl-2-benzimidazolyl)-benzene (TPBI), 1,3,5-tri[(3-pyridyl)-phen-3-yl] benzene (TmPyPB), bathocuproine (BCP), bathophenanthroline (BPhen) and bis(2-methyl-8-quinolinolate)-4-(phenylphenolate)-aluminum (BAlq), 1,3,5-tri[(3-pyridyl)-phen-3-yl]benzene (TmPyPB),1,3-bis[3,5-di(pyridin-3-yl)- phenyl]benzene (BmPyPhB) and 1,3,5-tris(6-(3-(pyridin-3-yl)phenyl)pyridin-2-yl)benzene (Tm3PyP26PyB). In some forms, the electron-transporting layer has a thickness between about 10 nm and 60 nm, such as 40 nm.

In some forms, the light-emitting device can contain a carrier confinement layer inserted between the hole-transporting layer and the light-emitting layer, or between the light-emitting layer and the electron-transporting layer. Preferably, the carrier confinement layer improves the performance of the light-emitting device. In some forms, the carrier confinement layer contains an organic compound that can be, but is not limited to, CBP, TCTA, 3TPYMB, BmPyPhB, and Tm3PyP26PyB. In some forms, the carrier confinement layer has a thickness between about 5 nm and about 50 nm, such as 10 nm.

Preferably, the anode of the light-emitting device contains indium tin oxide-coated glass. Preferably, the cathode of the light-emitting device can contain lithium fluoride, aluminium, or a combination thereof. In some forms, the lithium fluoride forms a layer having a thickness between about 0.05 nm and 5 nm, such as 1 nm. In some forms, the aluminium forms a layer having a thickness between about 50 nm and about 250 nm, such as 150 nm.

OLEDs containing the dinuclear platinum(II) emitter complexes can demonstrate maximum current efficiencies (CE) of up to 45 cd/A. In some cases, the CE can include, but is not limited to values of about 5 cd/A, 10 cd/A, 15 cd/A, 20 cd/A, 25 cd/A, 30 cd/A, 35, 40, or 45 cd/A. The CE values at luminances of 1000 cd/m² may be up to 30, 35, 40, or 45 cd/A. In some cases, the CE at luminances of 1000 cd/m² can include, but is not limited to values of about 5 cd/A, 10 cd/A, 15 cd/A, 20 cd/A, 25 cd/A, 30, 35, 40, or 45 cd/A.

OLEDs containing the dinuclear platinum(II) emitter complexes can demonstrate maximum power efficiencies (PE) of up to 40 lumens per watt. In some cases, the PE can include, but is not limited to values of about 5 lm/W, 10 lm/W, 15 lm/W, 20 lm/W, 25 lm/W, 30 lm/W, 35 lm/W, or 40 lm/W. The PE values at luminances of 1000 cd/m² may be up to 25 or 30 lm/W. In some cases, the PE at luminances of 1000 cd/m² can include, but is not limited to values of about 5 lm/W, 10 lm/W, 15 lm/W, 20 lm/W, 25 lm/W, or 30 lm/W.

OLEDs containing the dinuclear platinum(II) emitter complexes can demonstrate maximum external quantum efficiencies (EQE) of up to about 30%. In some cases, the EQE can include, but is not limited to values of about 10 to 30%. The EQE values at luminances of 1000 cd/m² may be up to 20% or 25%. In some cases, the EQE at luminances of 1000 cd/m² can include, but is not limited to values of about 10 to 20% or 10 to 25%.

The disclosed compositions and methods can be further understood through the following numbered paragraphs.

Paragraph 1. A dinuclear platinum(II) emitter complex, or an isomer thereof, according to formula (I):

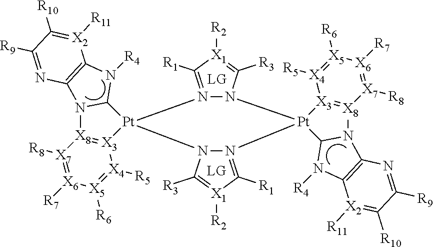

wherein each ligand, LG, is independently bonded to both platinum atoms,
wherein R₁, R₂, and R₃are each independently selected from the group consisting of hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein each R₄ is independently selected from the group consisting of a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein each X₁ is independently selected from carbon or nitrogen with the proviso that R₂ is a free electron pair when X₁ is nitrogen,
wherein each X₂ is independently selected from carbon or nitrogen with the proviso that R₁₁ is a free electron pair when X₂ is nitrogen,
wherein X₈ is carbon and each of X₃ or X₄ or X₅ or X₆ or X₇ are independently selected from carbon or nitrogen with the proviso that when any of X₄ or X₅ or X₆ or X₇ are nitrogen that R₅, R₆, R₇, R₈ are a free electron pair,
wherein R₅, R₆, R₇, R₈, R₉, R₁₀, and R₁₁ are each independently selected from the group consisting of a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; a nitro group; and an SiMe₃ group,
wherein each of R₅ and R₆, R₆ and R₇, R₇ and R₈, R₉ and R₁₀, or R₁₀ and Riican optionally form a saturated, unsaturated, or aromatic, optionally substituted ring, optionally interrupted by a heteroatom, and having a total of from 5 to 18 carbon atoms and heteroatoms.

Paragraph 2. The dinuclear platinum(II) emitter complex of paragraph 1, wherein each X₁ is nitrogen; each R₁ and R₃ is an aryl radical; each X₂ is carbon; each R₄ is a linear or branched alkyl radical; R₅, R₆, R₇, R₈, R₉, R₁₀, and R₁₁ are each hydrogen; and X₃-X₈ are each carbon.

Paragraph 3. The dinuclear platinum(II) emitter complex of paragraph 1, wherein each X₁ is nitrogen; each R₁ and R₃ is an aryl radical; each X₂ is nitrogen; each R₄ is a linear or branched alkyl radical; R₅, R₆, R₇, R₈, R₉, and R₁₀ are each hydrogen; and X₃-X₈ are each carbon.

Paragraph 4. The dinuclear platinum(II) emitter complex of paragraph 1, wherein each X₁ is nitrogen; each R₁ and R₃ is a linear or branched alkyl radical; each X₂ is carbon; each R₄ is a linear or branched alkyl radical; R₈-R₁₁ is selected from hydrogen, linear or branched alkyl radical, halogen, alkoxyl radical, or Si(R_{q})₃, wherein R_{q} is a linear or branched alkyl radical, alkoxyl radical or aryl; R₅, R₆, and R₇ are each a halogen; and X₃-X₈ are each carbon.

Paragraph 5. The dinuclear platinum(II) emitter complex of paragraph 1, wherein each X₁ is nitrogen; each R₁ and R₃ is a linear or branched alkyl radical; each X₂ is nitrogen; each R₄ is a linear or branched alkyl radical; R₈-R₁₀ are selected from hydrogen, linear or branched alkyl radical, halogen, alkoxyl radical, or Si(R_{q})₃, wherein R_{q} is a linear or branched alkyl radical, alkoxyl radical or aryl; R₅, R₆, and R₇ are each a halogen; and X₃-X₈ are each carbon.

Paragraph 6. The dinuclear platinum(II) emitter complex of any one of paragraphs 4-5, wherein the halogen is fluorine.

Paragraph 7. The dinuclear platinum(II) emitter complex of paragraph 1, wherein each X₁ is carbon; each R₂ is a hydrogen; each R₁ and R₃ is a linear or branched alkyl radical; each X₂ is carbon; each R₄ is a linear or branched alkyl radical; R₈-R₁₁ are selected from hydrogen, linear or branched alkyl radical, halogen, alkoxyl radical, or Si(R_{q})₃, wherein R_{q} is a linear or branched alkyl radical, alkoxyl radical or aryl; and R₅, R₆, and R₇ are each a halogen; and X₃-X₈ are each carbon.

Paragraph 8. The dinuclear platinum(II) emitter complex of paragraph 1, wherein each X₁ is carbon; each R₂ is a hydrogen; each R₁ and R₃ is a linear or branched alkyl radical; each X₂ is nitrogen; each R₄ is a linear or branched alkyl radical; R₈-R₁₀ are selected from hydrogen, linear or branched alkyl radical, halogen, alkoxyl radical, or Si(R_{q})₃, wherein R_{q} is a linear or branched alkyl radical, alkoxyl radical or aryl; and R₅, R₆, and R₇ are each a halogen; and X₃-X₈ are each carbon.

Paragraph 9. The dinuclear platinum(II) emitter complex of any one of paragraphs 7-8, wherein the halogen is fluorine.

Paragraph 10. The dinuclear platinum(II) emitter complex of paragraph 1, wherein each ligand LG independently has a chemical structure selected from:

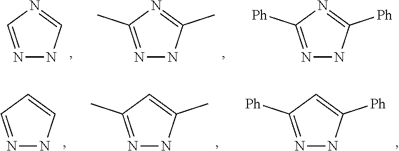

and substituted forms thereof.

Paragraph 11. The dinuclear platinum(II) emitter complex of any one of paragraphs 1-10 having a structure selected from:

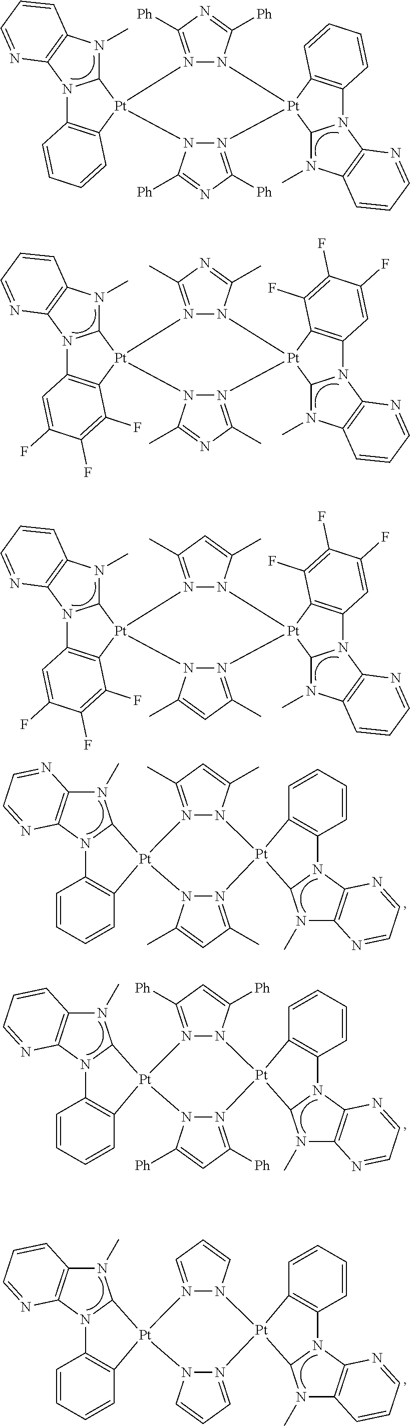

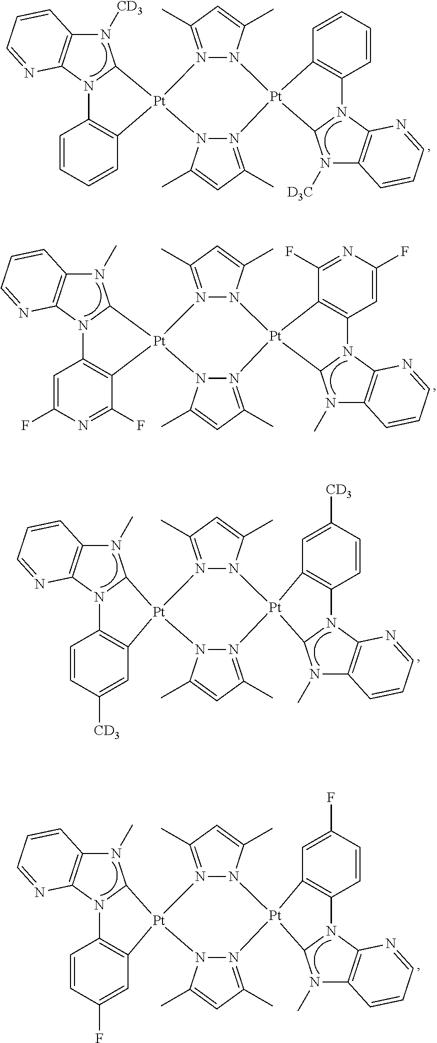

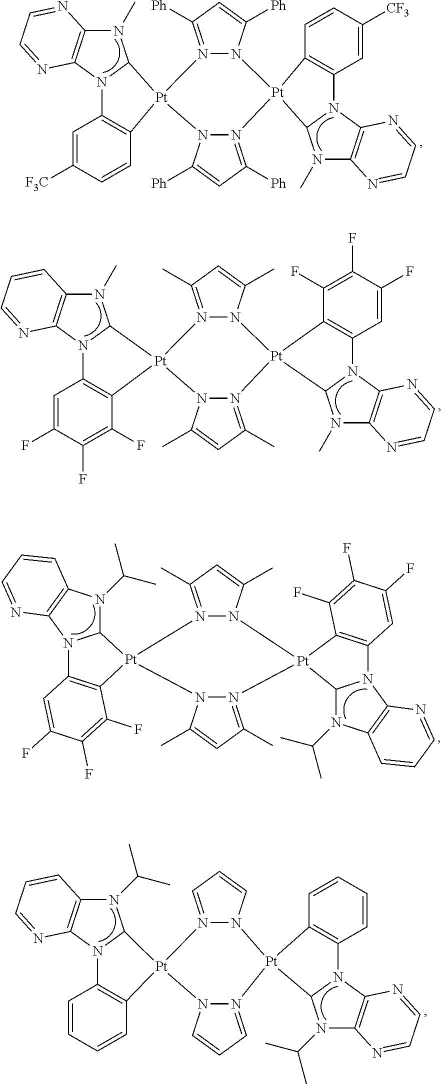

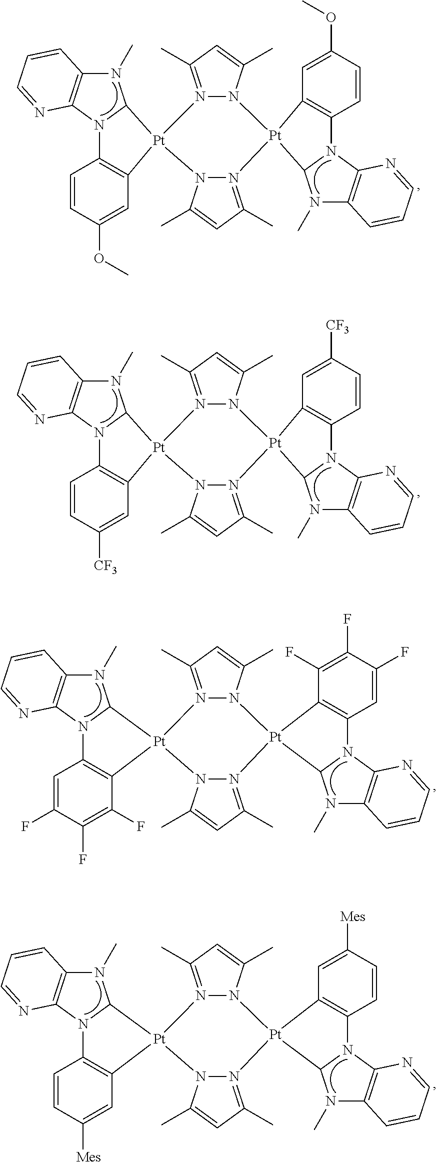

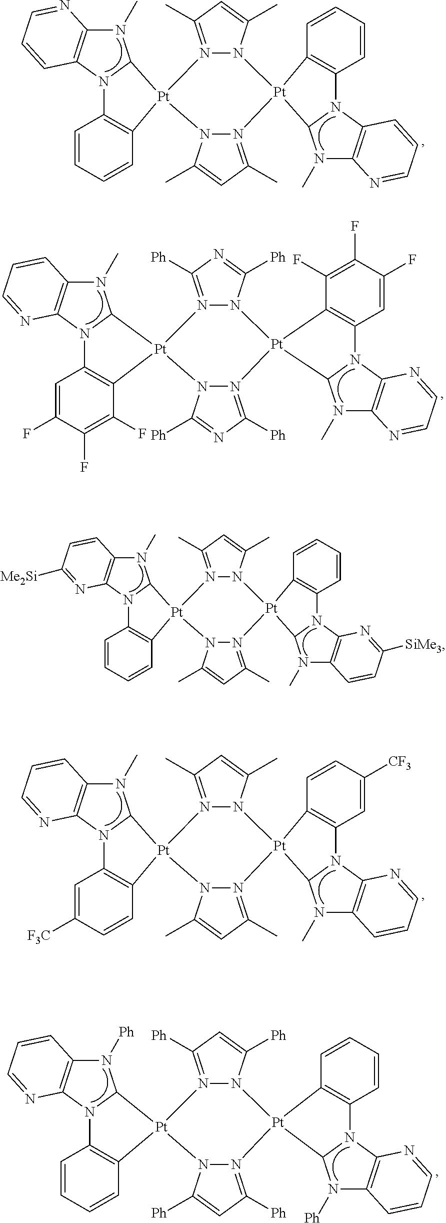

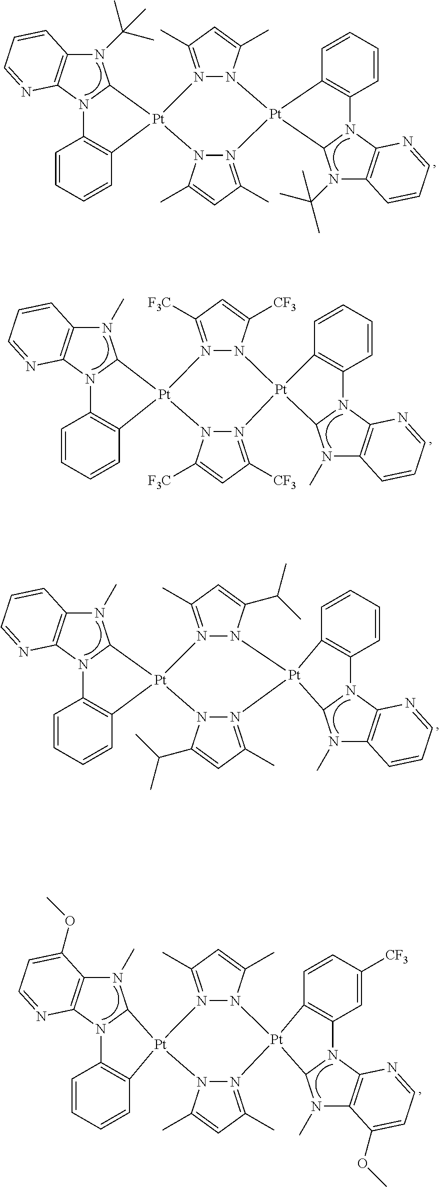

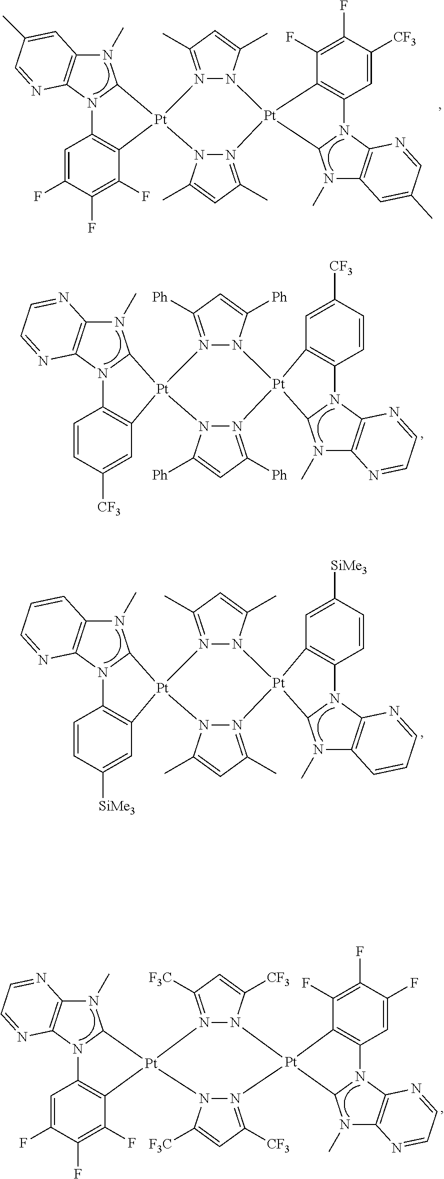

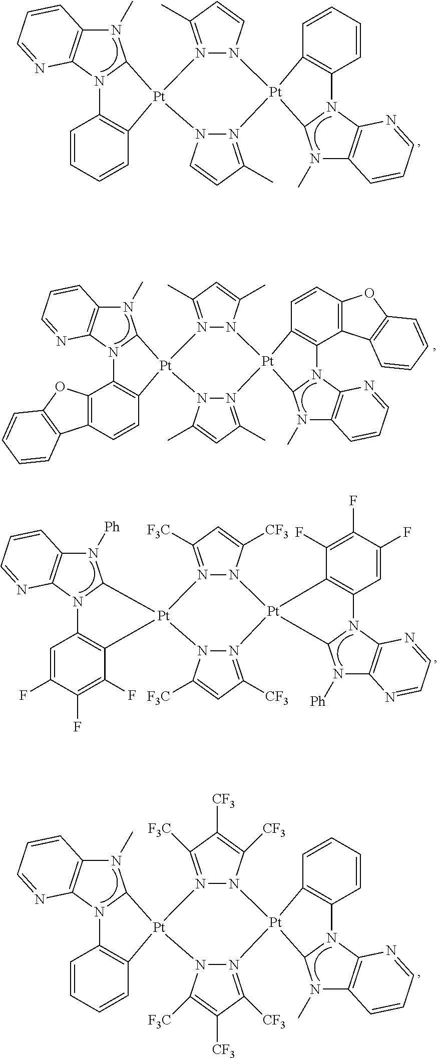

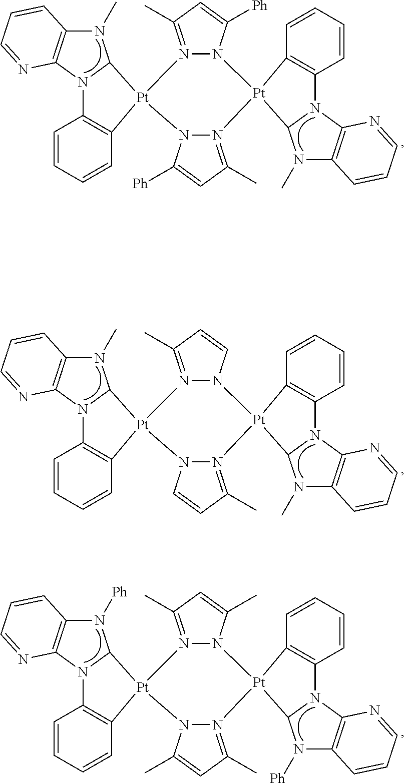

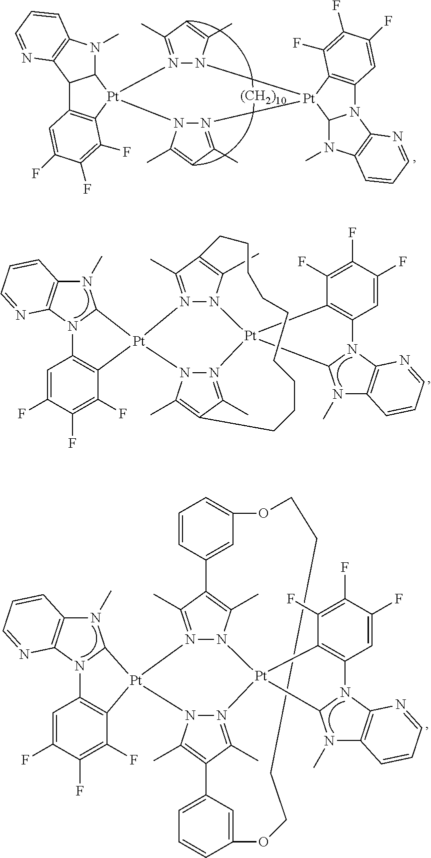

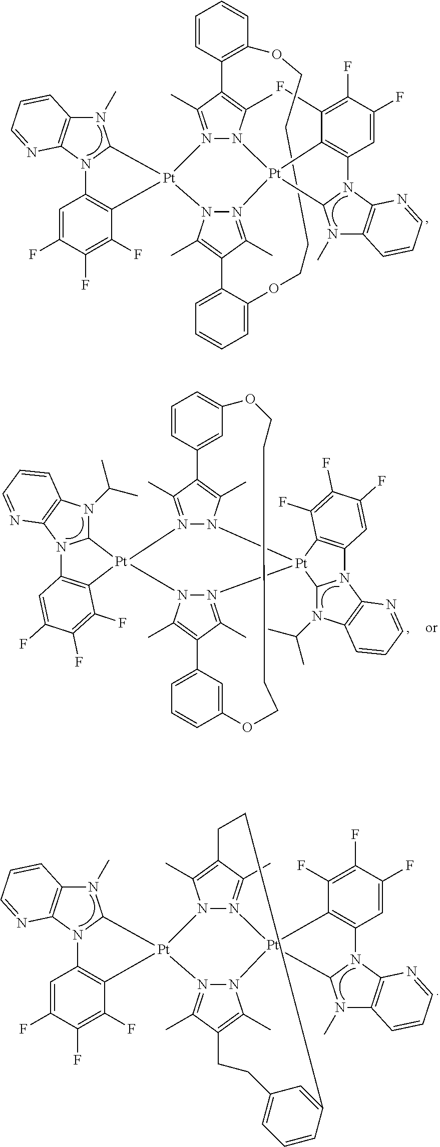

Paragraph 12. A dinuclear platinum(II) emitter complex, or an isomer thereof, according to formula (II):

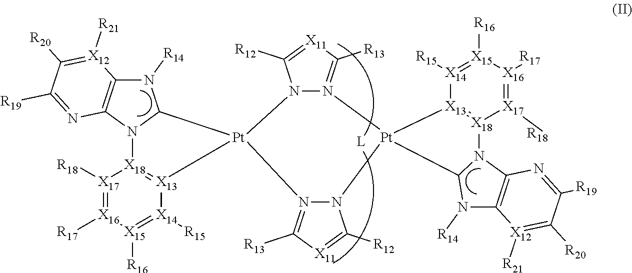

wherein R₁₂ and R₁₃ are each independently selected from the group consisting of a hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein each R₁₄ is independently selected from the group consisting of a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein each X₁₁ in formula (II) is a carbon linked to one another via a linker group L,
wherein each X₁₂ is independently selected from carbon or nitrogen with the proviso that R₂₁ is a free electron pair when X₁₂ is nitrogen,
wherein each X₁₃ or X₁₄ or X₁₅ or X₁₆ or X₁₇ or X₁₈ are independently selected from carbon or nitrogen with the proviso that when any of X₁₄ or X₁₅ or X₁₆ or X₁₇ are nitrogen that R₁₅, R₁₆, R₁₇, R₁₈ are a free electron pair,
wherein R₁₅, R₁₆, R₁₇, R₁₈, R₁₉, R₂₀, and R₂₁ are each independently selected from the group consisting of a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; a nitro group, and an SiMe₃ group,
wherein each of R₁₅ and R₁₆, R₁₆ and R₁₇, R₁₇ and R₁₈, R₁₉ and R₂₀, or R₂₀ and R₂₁ can optionally form a saturated, unsaturated, or aromatic, optionally substituted ring, optionally interrupted by a heteroatom, and having a total of from 5 to 18 carbon atoms and heteroatoms,
wherein the linker group L is a linker group which is a substituted or unsubstituted linear or branched alkyl radical having from 1 to 20 carbon atoms, optionally interrupted by at least one heteroatom and/or aryl group and/or cycloalkyl and/or heteroaryl group and/or heterocycloalkyl group and optionally having at least one substituent group thereon; or includes two phenol groups linked with linear or branched alkyl radical, optionally interrupted by at least one heteroatom and optionally having at least one substituent group thereon.

Paragraph 13. The dinuclear platinum(II) emitter complex of paragraph 12, wherein the linker group L has a formula selected from:

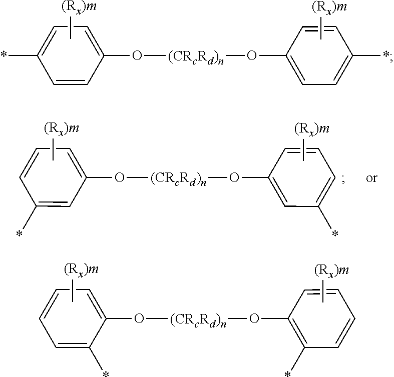

where each n can have an integer value from 3 to 20, and each R_{c} and R_{d} can independently be a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group; where each Rₓ is typically hydrogen and m is 4 but alternatively each Rₓ can represent one or more optional substituents, which may independently be present, when m is 1, 2, 3, or 4 and each Rₓ can be selected from a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group.

Paragraph 14. The dinuclear platinum(II) emitter complex of paragraph 12, wherein the linker group L has a formula selected from:

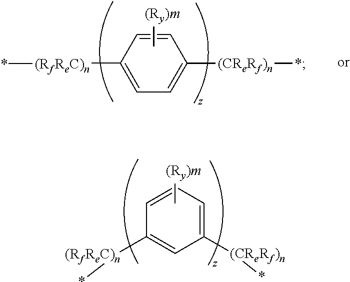

where each n and z are independently an integer value from 1 to 20, and each Rₑ and R_{f} can each independently be a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group; where Ry is typically hydrogen and m is 4 but alternatively Ry can represent one or more optional substituents, which may independently be present, when m is 1, 2, 3, or 4, where any remaining unsubstituted positions are hydrogen, and each Ry can be selected from a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group.

Paragraph 15. The dinuclear platinum(II) emitter complex of paragraph 12, wherein each R₁₂ and R₁₃ is a linear or branched alkyl radical, or a substituted or unsubstituted aryl radical; each R₁₄ is a linear or branched alkyl radical, or a substituted or unsubstituted aryl radical; each X₁₂ is selected from carbon or nitrogen with the proviso that R₂₁ is absent when X₁₂ is nitrogen; R₁₈-R₂₀ selected from hydrogen, linear or branched alkyl radical, halogen, alkoxyl radical, or Si(R_{q})₃, wherein R_{q} is a linear or branched alkyl radical, alkoxyl radical or aryl; R₁₅, R₁₆, and R₁₇ are each a halogen; and L is a linker group which is a substituted or unsubstituted linear or branched alkyl radical having from 1 to 20 carbon atoms, optionally interrupted by at least one heteroatom and/or aryl group and/or cycloalkyl and/or heteroaryl group and/or heterocycloalkyl group and optionally having at least one substituent group thereon; or a substituted or unsubstituted alkenyl radical having 2 to 20 carbon atoms, or a substituted or unsubstituted alkynyl radical having 2 to 20 carbon atoms; or includes two phenol groups linked with linear or branched alkyl radical, optionally interrupted by at least one heteroatom and optionally having at least one substituent group thereon.

Paragraph 16. The dinuclear platinum(II) emitter complex of paragraph 12, wherein each X₁₁ is carbon; each R₁₂ and R₁₃ is a linear or branched alkyl radical, or a substituted or unsubstituted aryl radical; each R₁₄ is a linear or branched alkyl radical, or a substituted or unsubstituted aryl radical; each X₁₂ is carbon; R₁₈-R₂₁ selected from hydrogen, linear or branched alkyl radical, halogen, alkoxyl radical, or Si(R_{q})₃, wherein R_{q} is a linear or branched alkyl radical, alkoxyl radical or aryl; R₁₅, R₁₆, and R₁₇ are each a halogen; and the linker group L is a linear or branched alkyl radical, or a substituted or unsubstituted aryl radical, or a combination thereof, optionally interrupted by at least one heteroatom.

Paragraph 17. The dinuclear platinum(II) emitter complex of paragraph 12, wherein each X₁₁ is carbon; each R₁₂ and R₁₃ is a linear or branched alkyl radical, or a substituted or unsubstituted aryl radical; each R₁₄ is a linear or branched alkyl radical, or a substituted or unsubstituted aryl radical; each X₁₂ is nitrogen; R₁₈-R₂₀ selected from hydrogen, linear or branched alkyl radical, halogen, alkoxyl radical, or Si(R_{q})₃, wherein R_{q} is a linear or branched alkyl radical, alkoxyl radical or aryl; R₁₅, R₁₆, and R₁₇ are each a halogen; and the linker group L is a linear or branched alkyl radical, or a substituted or unsubstituted aryl radical, or a combination thereof, optionally interrupted by at least one heteroatom.

Paragraph 18. The dinuclear platinum(II) emitter complex of any one of paragraphs 16-17, wherein the halogen is fluorine.

Paragraph 19. The dinuclear platinum(II) emitter complex of any one of paragraphs 12-18 having a structure selected from:

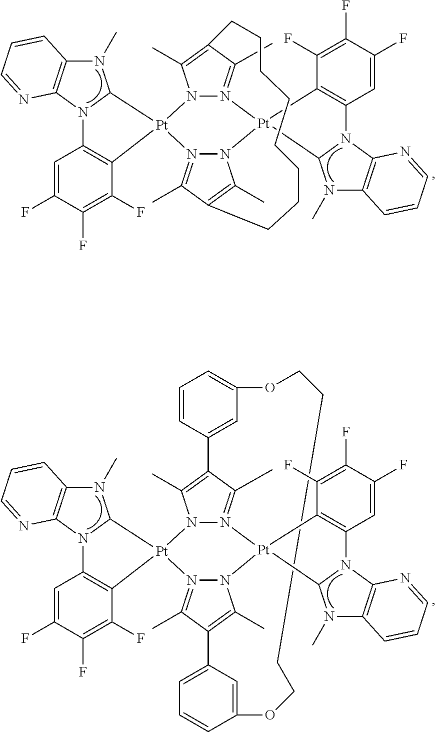

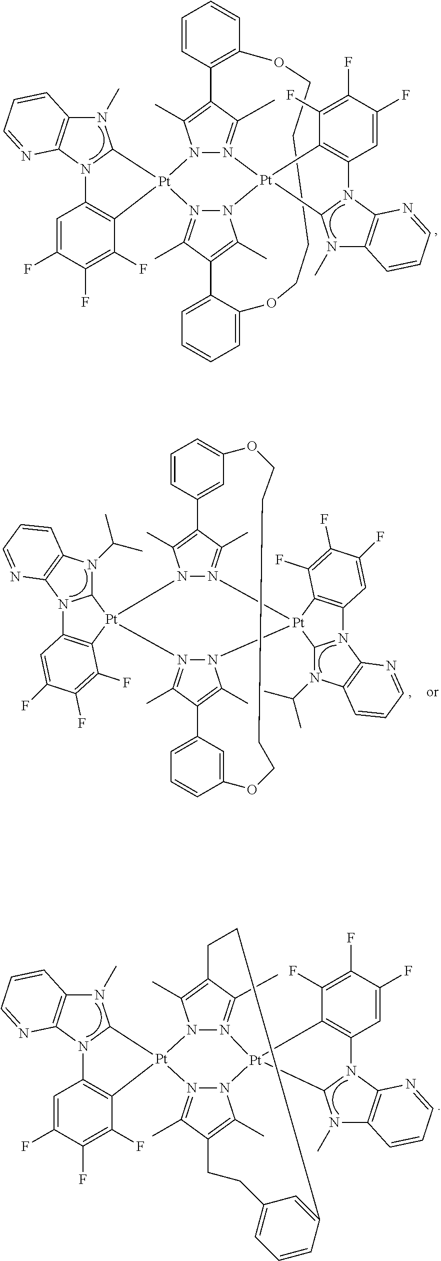

Paragraph 20. A method for preparing a dinuclear platinum(II) emitter complex, the method comprising:
contacting a platinum (Pt) compound with a first ligand selected from a pyrazole ligand, a triazole ligand, or a combination thereof, and a second ligand according to formula (III)

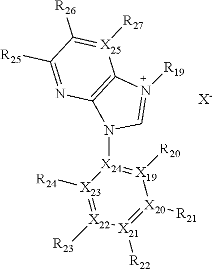

wherein R₁₉ is selected from the group consisting of a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein X₁₉ is independently selected from carbon or nitrogen with the proviso that R₂₀ is hydrogen when X₁₉ is a carbon and R₂₀ is a free electron pair when X₁₉ is nitrogen,
wherein X₂₅ is independently selected from carbon or nitrogen with the proviso that R₂₆ is a free electron pair when X₂₅ is nitrogen,
wherein X₂₄is carbon and each of X₁₉ or X₂₀ or X₂₁ or X₂₂ or X₂₃ independently selected from carbon or nitrogen with the proviso that when any of X₁₉ or X₂₀ or X₂₁ or X₂₂ or X₂₃ are nitrogen that R₂₀, R₂₁, R₂₂, R₂₃, R₂₄ are a free electron pair,
wherein R₂₁, R₂₂, R₂₃, R₂₄, R₂₅, R₂₆, and R₂₇ are each independently selected from the group consisting of a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group,
wherein each of R₂₁ and R₂₂, R₂₂ and R₂₃, R₂₃ and R₂₄, R₂₅ and R₂₆, or R₂₆ and R₂₇ can optionally form a saturated, unsaturated, or aromatic, optionally substituted ring, optionally interrupted by a heteroatom, and having a total of from 5 to 18 carbon atoms and heteroatoms, and
wherein X⁻ is a halide, BF₄⁻, PF₆⁻, CF₃SO₃⁻, SbF₆⁻, ClO₄⁻, or 1/2 SO₄²⁻.

Paragraph 21. The method of paragraph 20, wherein the halide is an iodide, a chloride, or a bromide.

Paragraph 22. The method of any one of paragraphs 20-21, wherein R₁₉ is a linear or branched alkyl radical; X₁₉-X₂₅ are carbon; R₂₀-R₂₁ and R₂₅-R₂₇ are hydrogen; and R₂₂, R₂₃, R₂₄ are each a halogen.

Paragraph 23. The method of any one of paragraphs 20-22, wherein the first ligand is the pyrazole ligand having a structure according to formula (IV)

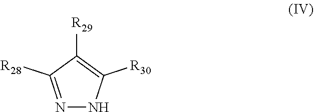

wherein R₂₈, R₂₉, and R₃₀ are each independently selected from the group consisting of a hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms.

Paragraph 24. The method of paragraph 23, wherein the pyrazole ligand of formula (IV) has a structure:

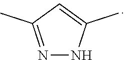

Paragraph 25. The method of any one of claims 20-22, wherein the first ligand is the pyrazole ligand having a structure according to formula (V)

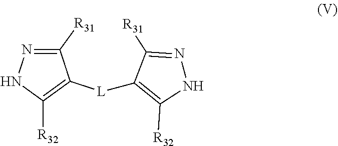

wherein in linker L is a linker group which is a substituted or unsubstituted linear or branched alkyl radical having from 1 to 20 carbon atoms, optionally interrupted by at least one heteroatom and/or aryl group and optionally having at least one substituent group thereon; or includes two phenol groups linked with linear or branched alkyl radical, optionally interrupted by at least one heteroatom and optionally having at least one substituent group thereon; and
wherein R₃₁ and R₃₂ are each independently selected from the group consisting of a hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms.

Paragraph 26. The method of paragraph 25, wherein the pyrazole ligand of formula (V) has a structure:

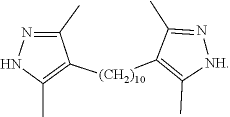

Paragraph 27. The method of any one of paragraphs 20-22, wherein the first ligand is the triazole ligand having a structure according to formula (VI)

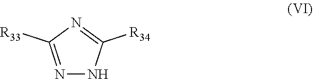

wherein R₃₃ and R₃₄ are each independently selected from the group consisting of a hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms.

Paragraph 28. The method of paragraph 27, wherein the triazole ligand of formula (VI) has a structure:

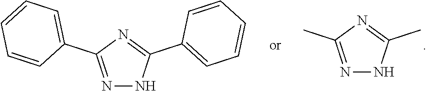

Paragraph 29. An organic electronic component comprising a first electrode, a second electrode, and an organic layer disposed between the first electrode and the second electrode, the organic layer comprising an emission layer and at least one dinuclear platinum(II) emitter complex of any one of paragraphs 1-19.

Paragraph 30. The organic electronic component of paragraph 29, wherein the organic electronic component is an organic light-emitting diode (OLED).

Paragraph 31. The organic electronic component of paragraph 30, wherein the organic light-emitting diode (OLED):
the first electrode is an anode,
the second electrode is a cathode, and
the organic layer comprises a hole transport region disposed between the first electrode and the emission layer and an electron transport region disposed between the emission layer and the second electrode, wherein the hole transport region comprises a hole injection layer, a hole transport layer, an electron blocking layer, or any combination thereof, and the electron transport region comprises a hole blocking layer, an electron transport layer, an electron injection layer, or any combination thereof.

Paragraph 32. The organic electronic component of paragraph 31, wherein the emission layer comprises the at least one organometallic compound.

Paragraph 33. The organic electronic component of paragraph 32, wherein the emission layer comprises one host or two host materials in an amount of greater than an amount of the dinuclear platinum(II) emitter complex.

Paragraph 34. The organic electronic component of paragraphs 29-33, wherein any one of the organic layer, the emission layer, the hole injection layer, the hole transport layer, the electron blocking layer, the hole blocking layer, the electron transport layer, the electron injection layer are fabricated by vacuum-evaporation deposition method or spin-coating method or ink-printing method or roll-to-roll printing method.

Paragraph 35. A device comprising the organic light-emitting diode (OLED) of any one of paragraphs 30-34.

Paragraph 36. The device according to paragraph 35, wherein the device is selected from a fixed visual display unit, mobile visual display unit, illumination unit, keyboard, clothes, ornaments, garment accessary, wearable devices, medical monitoring devices, wall paper, tablet PC, laptop, advertisement panel, panel display unit, household appliance, or office appliance.

The methods, compounds, and compositions herein described are further illustrated in the following examples, which are provided by way of illustration and are not intended to be limiting. It will be appreciated that variations in proportions and alternatives in elements of the components shown will be apparent to those skilled in the art and are within the scope of disclosed forms. Theoretical aspects are presented with the understanding that Applicants do not seek to be bound by the theory presented. All parts or amounts, unless otherwise specified, are by weight.

### EXAMPLES

### Example 1: Synthesis and Characterization of Dinuclear Platinum (II)

### Emitter Complexes

### Materials and Methods:

The chemical reagents used for synthesis were purchased from commercial sources such as Dieckmann, J & K Scientific, BLDpharm, Bidepharm, Strem Chemicals. They are directly used without further process. The solvents used for synthesis are purchased from Duksan, RCI Labscan, Scharlau. They are directly used without further process. Ligands 3,5-dimethyl-1H-pyrazole, 3,5-diphenyl-1H-1,2,4-triazole, and 3,5-dimethyl-1H-1,2,4-triazole were obtained from BLDpharm and used without further purification.

¹H, ¹³C and ¹⁹F NMR spectra were recorded on DPX-400 or DPX-500 Bruker FT-NMR spectrometer. The chemical shift of proton or carbon signals are calibrated by the corresponding solvent residual signals. High resolution mass spectra were measured with Bruker Impact II mass spectrometer.

### Synthesis of Cyclometalating N-heterocyclic Carbene (NHC) Ligands

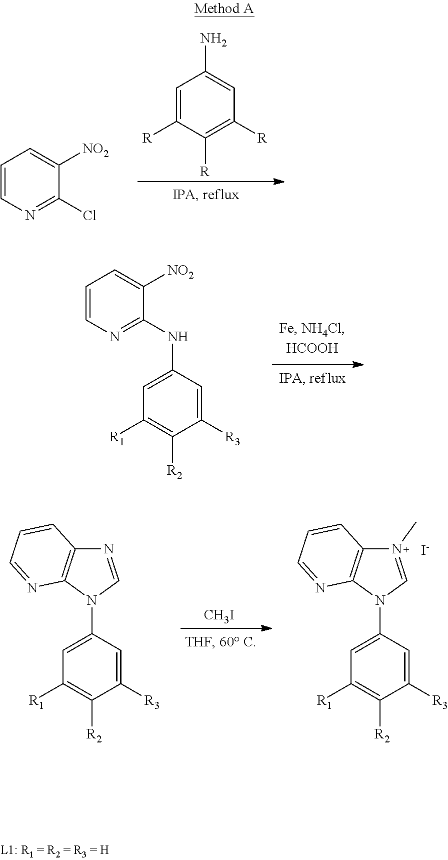

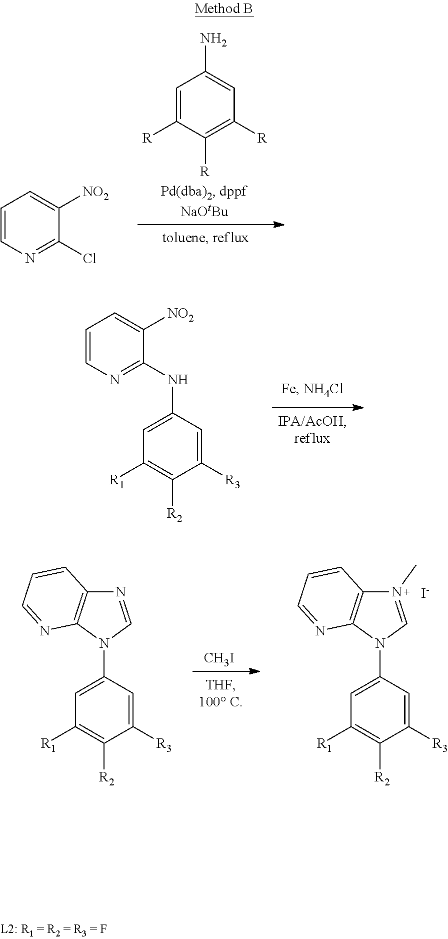

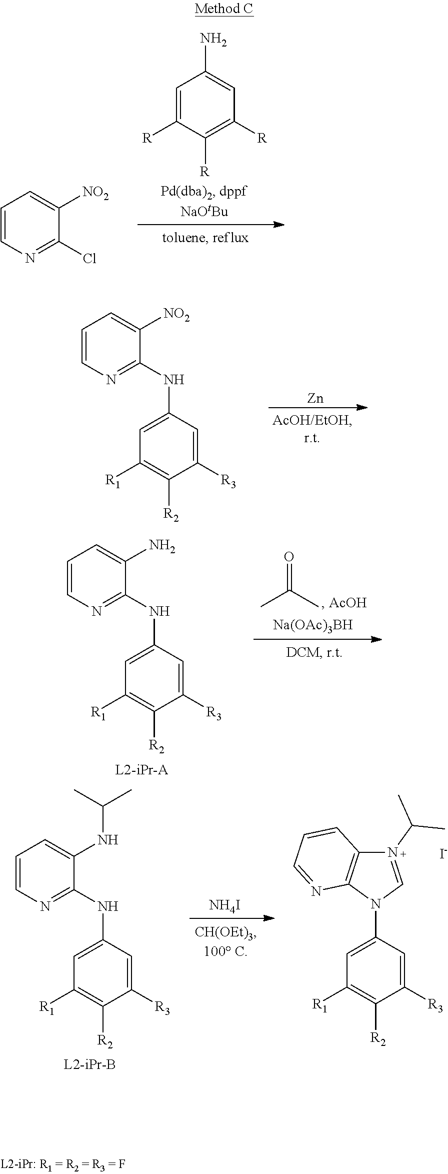

NHC ligand L1 (R₁═R₂=R₃═H) was prepared via Method A according to the literature (Organometallics 2016, 35, 673-680).

NHC ligand L2 was prepared via Method B, as follows: 2-Chloro-3-nitropyridine (1 eq.), corresponding aniline (R₁═R₂=R₃═F) (1.2 eq.), Pd(dba)₂ (0.05 eq.), DPPF (0.05 eq.) and t-BuONa (1.5 eq.) was refluxed overnight in toluene. Afterward, the reaction mixture was filtered through a short pad of silica gel and concentrated under reduced pressure. The crude product was used in next step without further purification. Next, the N-substituted nitropyridine (1 eq.), iron powder (10 eq.), ammonium chloride (10 eq.) was refluxed in IPA/AcOH (4:3) for 48 h. Volatiles were removed and acid was neutralized with aqueous NaHCO₃ and extracted with ethyl acetate. The organic phase was dried with MgSO₄, filtered, and concentrated under reduced pressure. The resulting residue was filtered through a short pad of silica gel, concentrated and used in next step without further purification. The obtained imidazole (1 eq.) and methyl iodide (5 eq.) were mixed in tetrahydrofuran (THF) and heated to 100° C. in sealed tube for 48 h. The precipitate was collected by filtration and washed with THF to give the product NHC ligand L2.

NHC ligand L2-iPr-Intermediate A was prepared via Method C, as follows: 3,4,5-Trifluoroaniline (3.50 g, 23.79 mmol), 2-chloro-3-nitropyridine (3.70 g, 23.33 mmol), ′ BuONa (3.36 g, 34.99 mmol), Pd(dba)₂ (0.67 g, 1.17 mmol) and dppf (0.65 g, 1.17 mmol) were refluxed in 30 mL dry toluene for 24 h. The reaction mixture was filtered through a short pad of silica and celite. The pad was washed with EA and the filtrate was concentrated. The residue was used in next step without further purification. 3-Nitro-N-(3,4,5-trifluorophenyl)pyridine-2-amine (16.67 mmol) and Zn powder (15.25 g, 23.33 mmol) was stirred in AcOH/EtOH (24:20 v/v) for 2 h. The excess Zn was filtered and the volatile was removed under reduced pressure. The residue was purified with silica gel column chromatography using EA/hexane as eluent to obtain the product as a dark purple solid.

NHC ligand L2-iPr-Intermediate B was prepared via Method C, as follows: L2-iPr-A (2.04 g, 8.54 mmol), acetone (0.74 g, 12.81 mmol), acetic acid (1.03 g, 17.08 mmol) and Na(OAc)₃BH (2.71 g, 12.81 mmol) were stirred overnight at room temperature in 50 mL DCM. The solvent was removed under reduced pressure and the residue was purified with silica gel column chromatography using EA/hexane as eluent to obtain the product as a dark purple solid. Further, the iodide salt of L2-iPr-B was formed by reacting L2-iPr-B (1.80 g, 6.42 mmol) and ammonium iodide (1.12 g, 7.70 mmol) and stirring overnight in 10 mL triethyl orthoformate at 100° C. The solid formed was collected by filtration and washed with THF and hexane to give the product as a white solid.

### Characterization:

L1: Yield of 69%. NMR characterization was performed and was consistent with the characterization reported in the literature (Organometallics 2016, 35, 673-680).

L2: Yield of 24%. ¹H NMR (400 MHz, DMSO): δ 10.45 (s, 1H), 8.85 (dd, J=4.8, 1.3 Hz, 1H), 8.71 (dt, J=8.4, 1.4 Hz, 1H), 8.14-8.02 (m, 2H), 7.95-7.88 (m, 1H), 4.22 (s, 3H). ¹³C NMR (126 MHz, DMSO): δ 150.36 (ddd, J=249.3, 10.3, 4.5 Hz), 148.99, 144.57, 142.55, 139.98 (dt, J=253.4, 15.0 Hz), 127.91 (td, J=12.0, 4.5 Hz), 125.13, 124.18, 122.90, 111.48-110.70 (m), 34.35. ¹⁹F NMR (471 MHz, DMSO): δ-132.05 (dd, J=21.4, 7.6 Hz, 2H), −157.60 (t, J=22.0 Hz, 1H). HIRMS (ESI) for C₁₃H₉F₃N₃[M]⁺: calcd 264.0749, found 264.0742.

L2-iPr-Intermediate A: Yield: 37%. ¹H NMR (500 MHz, CDCl₃): δ 7.82 (d, J=4.9 Hz, 1H), 7.06 (d, J=7.7 Hz, 1H), 6.95-6.88 (m, 2H), 6.87-6.81 (m, 1H), 6.64 (br s, 1H), 3.68 (br s, 2H). ¹³C NMR (126 MHz, CDCl₃): δ 151.45 (ddd, J=246.1, 10.3, 5.7 Hz), 144.67, 138.92, 137.55 (td, J=11.5, 3.2 Hz), 134.56 (dt, J=243.8, 15.7 Hz), 131.52, 124.73, 118.55, 102.15-101.73 (m). ¹⁹F NMR (471 MHz, CDCl₃): δ −134.61-−134.80 (m, 2F), −170.70-−170.97 (m, 1F). HRMS (ESI) for C₁₁H₇F₃N3 [M+H]⁺: m/z calcd 240.0749, found 240.0746.

L2-iPr-Intermediate B: Yield: 54%. ¹H NMR (500 MHz, CDCl₃): δ 7.71 (d, J=4.4 Hz, 1H), 7.01 (d, J=7.7 Hz, 1H), 6.98-6.92 (m, 1H), 6.77-6.69 (m, 2H), 3.62-3.51 (m, 1H), 1.20 (d, J=6.3 Hz, 6H). ¹³C NMR (126 MHz, CDCl₃): δ 151.43 (ddd, J=246.0, 10.2, 5.6 Hz), 143.84, 138.10 (t, J=10.2 Hz), 135.98, 134.50, 134.36 (dt, J=242.8, 15.4 Hz), 120.50, 119.49, 102.06-100.93 (m), 44.55, 22.75. ¹⁹F NMR (471 MHz, CDCl₃): δ −134.69-−135.00 (m, J=10.3 Hz, 2F), −170.95-−171.78 (m, 1F). HRMS (ESI) for C₁₄H₁₅F₃N₃[M+H]⁺: m/z calcd 282.1218, found 282.1213.

L2-iPr: Yield: 82%. ¹fH NMR (500 MHz, DMSO): δ 10.45 (s, 1H), 8.90-8.79 (m, 2H), 8.15-8.06 (m, 2H), 7.93-7.87 (m, 1H), 5.26-5.14 (m, 1H), 1.70 (d, J=6.7 Hz, 6H). ¹³C NMR (151 MHz, DMSO): δ 150.23 (ddd, J=248.8, 10.2, 4.5 Hz), 148.99, 142.80, 142.64, 139.86 (dt, J=253.2, 15.1 Hz), 128.01 (td, J=11.9, 4.3 Hz), 124.43, 123.79, 122.81, 111.54-111.12 (m), 52.22, 21.40. ¹⁹F NMR (471 MHz, DMSO): δ −132.28-−132.53 (m, 2F), −157.60-−157.95 (m, 1F). HRMS (ESI) for C₁₅H₁₃F₃N₃ [M]⁺: calcd 292.1062, found 292.1055.

### Synthesis of Bridged Pyrazole Ligands:

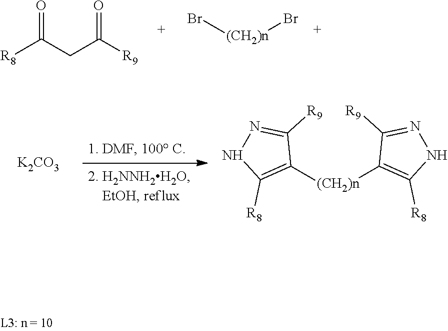

L3: Substituted (R₈ and R₉=methyl) acetylacetone (2 eq.), dibromoalkane (n=10, 1 eq.) and K₂CO₃ (2 eq.) were stirred at 100° C. in 10 mL N-dimethylformamide (DMF) for 2 days. Volatiles were removed under reduced pressure and the resulting residue was neutralized with HCl and extracted with ethyl acetate. The organic fraction was dried with MgSO₄, filtered and concentrated under reduced pressure. Hydrazine hydrate (2 eq.) and EtOH was added and the reaction mixture was refluxed overnight. The ligand product, L3, was purified either by column chromatography using ethyl acetate then ethyl acetate/MeOH as eluent to obtain the product as white solid.

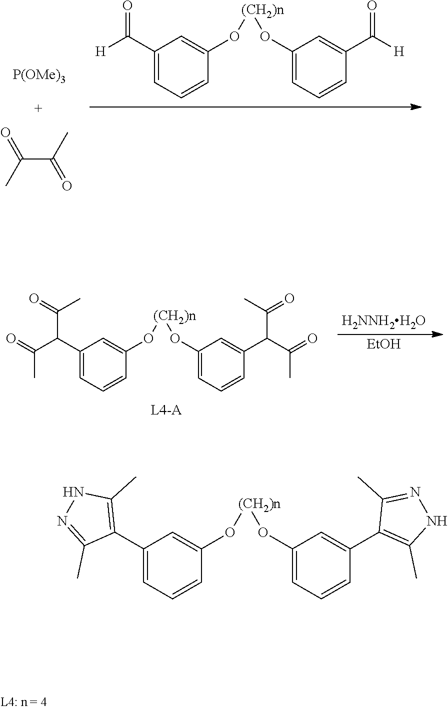

L4-Intermediate A: 2,3-Butandione (7.25 g, 84.30 mmol) was added to trimethylphosphite (10.71 g, 86.31 mmol) at 0° C. under N₂. The reaction mixture was stirred overnight at room temperature. 3,3′-(Butane-1,4 diylbis(oxy))dibenzaldehyde (5.00 g, 16.76 mmol) was added and the reaction mixture was stirred overnight at room temperature. 20 mL MeOH was added and the reaction mixture was stirred at 60° C. for 4 h. The precipitate was filtered and washed thoroughly with MeOH to give the product as a white solid.

L4: L4-A (0.60 g, 1.37 mmol) and hydrazine hydrate (0.14 g, 2.87 mmol) were refluxed overnight in 20 mL EtOH. The volatile was removed under reduced pressure to give the product as a white solid.

### Characterization:

L3: Yield of 30%. ¹H NMR (500 MHz, CDCl₃): δ 2.32 (t, J=7.5 Hz, 4H), 2.20 (s, 12H), 1.47-1.38 (m, 4H), 1.29-1.23 (m, 12H). HIRMS (EI) for C₂₀H₃₄N₄[M]⁺: calcd 330.2783, found 330.2775.

L4-Intermediate A: Yield: 45% (a mixture of keto and enol form). ¹H NMR (500 MHz, DMSO): δ 16.78 (s, 1.6H), 7.36-7.25 (m, 2H), 6.91 (m, 2H), 6.81 (m, 4H), 5.30 (s, 0.2H), 4.05 (s, 4H), 2.13 (s, 1H), 1.90-1.84 (m, 15H). HIRMS (ESI) for C₂₆H₃₁O₆[M+H]⁺: calcd 439.2121, found 439.2114.

L4: Yield: 35%. ¹H NMR (600 MHz, DMSO): δ 7.27 (t, J=7.9 Hz, 2H), 6.84-6.77 (m, 6H), 4.05 (s, 4H), 2.17 (s, 12H), 1.88 (s, 4H). ¹³C NMR (151 MHz, DMSO): δ 170.35, 158.65, 135.45, 129.38, 121.03, 116.78, 114.72, 111.80, 67.03, 25.50. HRMS (ESI) for C₂₆H₃₁N₄O₂ [M+H]⁺: calcd 431.2447, found 431.2438.

### Synthesis of Dinuclear Platinum(II) Emitter Complexes

### Pt-1 -Pt-4:

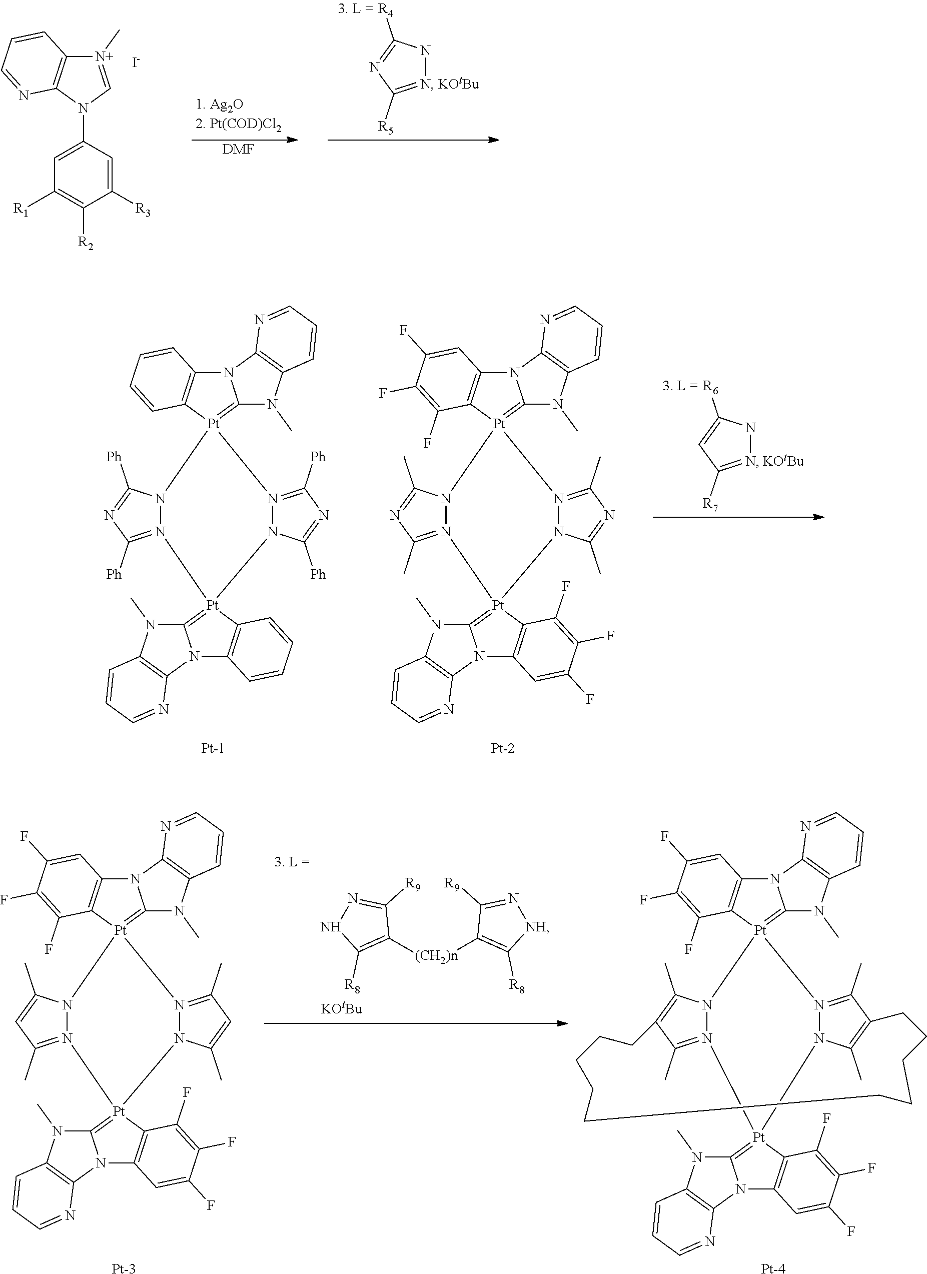

As shown in the scheme above, the corresponding imidazolium salt (L1 or L2) (1 eq.) and silver(I) oxide (0.8 eq.) was stirred under argon protected from light in anhydrous N,N′-dimethylformamide (DMF) for 24 hours at 50° C. Dichloro(1,5-cyclooctadiene)platinum(II) (1 eq.) was added, and the mixture was stirred for 2 hours at 50° C., then for 24 hours at 125° C. Afterwards potassium tert-butoxide (4 eq.) and a corresponding pyrazole (3,5-dimethyl-1H-pyrazole for Pt-3) or triazole (3,5-diphenyl-1H-1,2,4-triazole for Pt-1 or 3,5-dimethyl-1H-1,2,4-triazole for Pt-2) (4 eq) was added; when bridged pyrazole L3 was used (1.25 eq) was added. The mixture was stirred for 24 hours at room temperature and then for another 24 hours at 100° C.; all volatiles were removed in vacuo and the crude product was washed with water and isolated by flash chromatography using DCM/hexane as eluent. The product was further purified with recrystallization.

Pt-1 was prepared using L1 and diphenyl-substituted triazole 3,5-diphenyl-1H-1,2,4-triazole as ligands. Yield: 23%. ¹H NMR (500 MHz, CD₂Cl₂) δ 8.97 (d, J=6.7 Hz, 4H), 8.80-8.70 (m, 4H), 8.33-8.13 (m, 4H), 7.43-7.24 (m, 14H), 7.17-6.95 (m, 6H), 6.74 (t, J=7.5 Hz, 2H), 3.46 (s, 6H). ¹³C NMR (126 MHz, CD₂Cl₂) 6 168.16, 161.52, 160.94, 147.87, 145.16, 134.79, 131.15, 130.82, 129.53, 129.33, 128.81, 128.36, 128.28, 128.01, 127.36, 124.63, 124.59, 118.62, 118.57, 114.76, 33.16. HRMS (ESI) for C₅4H₄₁Pt₂N1₂ [M+H]⁺: calcd 1247.2873, found 1247.2889. Anal. Calcd for C₅₄H₄₀Pt₂N1₂ C₄H₁₀O: C, 52.72; H, 3.81; N, 12.72. Found: C, 52.88; H, 3.57; N, 12.93.

Pt-2 was prepared using L2 and dimethyl-substituted triazole 3,5-dimethyl-1H-1,2,4-triazole as ligands. Yield: 29%. ¹FH NMR (500 MHz, CD₂Cl₂) δ 8.48 (dd, J=4.9, 1.3 Hz, 2H), 8.44-8.32 (m, 2H), 7.73 (dd, J=8.2, 1.4 Hz, 2H), 7.38-7.31 (m, 2H), 3.59 (s, 6H), 2.37 (s, 12H). ¹³C NMR (126 MHz, CD₂Cl₂) δ 167.45, 159.10, 145.87, 145.19, 128.51, 119.62, 119.26, 110.42, 101.05, 100.84, 32.94, 14.16. ¹⁹F NMR (471 MHz, CD₂Cl₂) 6-126.10-−126.84 (m, 2F), −140.99-−141.18 (m, 2F), −165.86-−166.21 (m, 2F). HRMS (ESI) for C₃₄H₂₇Pt₂N₁₂F₆[M+H]⁺: calcd 1107.1681, found 1107.1701. Anal. Calcd for C₃₄H₂₆Pt₂F₆N₁₂ CH₃OH 0.5CH₂Cl₂: C, 36.09; H, 2.65; N, 14.23. Found: C, 35.89; H, 2.67; N, 14.07.

Pt-3 was prepared using L2 and dimethyl-substituted pyrazole 3,5-dimethyl-1H-pyrazole as ligands. Yield: 28%. ¹H NMR (500 MHz, CD₂Cl₂): δ 8.44 (dd, J=4.9, 1.3 Hz, 2H), 8.42-8.32 (m, 2H), 7.69 (dd, J=8.2, 1.3 Hz, 2H), 7.30 (dd, J=8.2, 4.9 Hz, 2H), 6.00 (s, 2H), 3.55 (s, 6H), 2.27 (s, 6H), 2.24 (s, 6H). ¹³C NMR (151 MHz, CD₂Cl₂): δ 169.43, 156.91 (ddd, J=238.8, 8.6, 3.7 Hz), 148.53, 148.53 (ddd, J=240.1, 10.9, 2.9 Hz), 146.68, 145.44, 145.36, 143.58 (ddd, J=20.6, 12.2, 4.0 Hz), 137.60 (ddd, J=248.5, 21.5, 15.0 Hz), 128.74, 119.23, 118.87, 113.66 (d, J=35.6 Hz), 104.04, 100.60 (d, J=20.9 Hz), 32.74, 32.69, 14.03. ¹⁹F NMR (471 MHz, CD₂Cl₂): δ −125.23-−125.83 (m, 2F), −141.97-142.47 (m, 2F), −166.64-−167.01 (m, 2F). HRMS (ESI) for C₃₆H₂₉Pt₂F₆N₁₀ [M+H]⁺: calcd 1105.1776, found 1105.1771. Anal. Calcd for C₃₆H₂₈Pt₂F₆N₁₀·0.25 CH₂Cl₂: C, 38.66; H, 2.55; N, 12.44. Found: C, 38.44; H, 2.53; N, 12.03.

Pt-4 was prepared using L2 and bridged pyrazole L3 as ligands. Yield: 11%. ¹H NMR (500 MHz, CD₂Cl₂): δ 8.43 (dd, J=4.9, 1.3 Hz, 2H), 8.40-8.33 (m, 2H), 7.67 (dd, J=8.2, 1.3 Hz, 2H), 7.31-7.26 (m, 2H), 3.51 (s, 6H), 2.46-2.38 (m, 4H), 2.20 (s, 6H), 2.16 (s, 6H), 1.37-1.31 (m, 4H), 1.18-1.11 (m, 8H), 1.07-0.95 (m, 4H). ¹⁹F NMR (471 MHz, CD₂Cl₂): δ −124.78-−125.32 (m, 1F), −142.60 (dd, J=18.6, 13.3 Hz, 1F), −166.89-−167.32 (m, 1F). HRMS (ESI) for C₄₆H₄₇Pt₂N₁₀F₆ [M+H]⁺: calcd 1243.3185, found 1243.3147. Anal. Calcd for C₄₆H₄₆Pt₂F₆N₁₀: C, 44.45; H, 3.73; N, 11.27. Found: C, 44.73; H, 3.80; N, 10.92.

### Pt-5 -Pt-7:

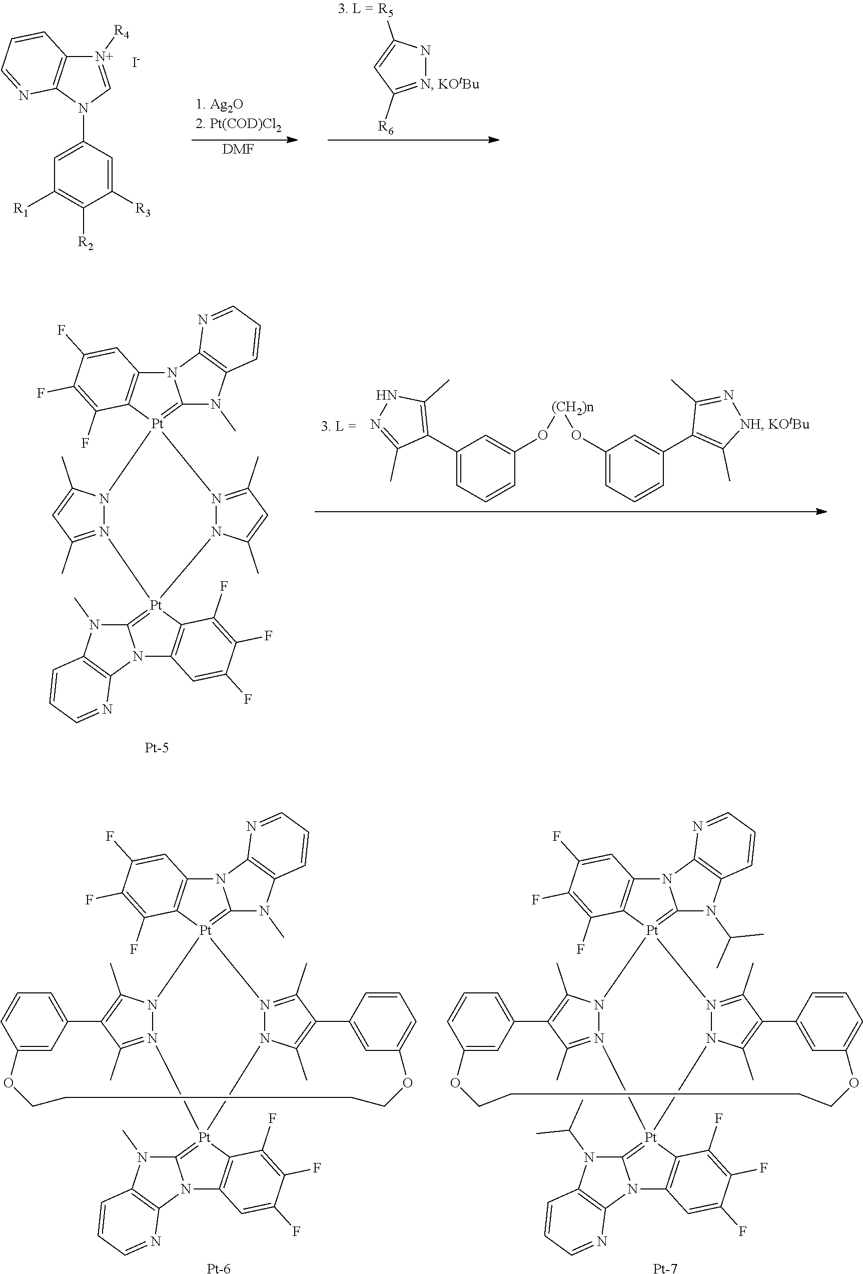

Pt-5 was prepared similar to Pt-3 using L2-iPr and dimethyl-substituted pyrazole 3,5-dimethyl-1H-pyrazole as ligands. Yield: 21%. ¹H NMR (500 MHz, CD₂Cl₂): δ 8.53-8.47 (m, 2H), 8.46 (d, J=4.9 Hz, 2H), 7.94 (d, J=8.4 Hz, 2H), 7.32-7.25 (m, 2H), 5.97 (s, 2H), 5.16-5.07 (m, 2H), 2.31 (s, 6H), 2.27 (s, 6H), 1.59 (d, J=7.0 Hz, 6H), 1.33 (d, J=6.1 Hz, 6H). ¹³C NMR (151 MHz, CD₂Cl₂): δ 168.98, 156.58 (ddd, J=240.1, 8.9, 3.8 Hz), 148.49, 148.32 (ddd, J=13.9, 11.0, 3.5 Hz), 146.63, 146.33, 144.98, 143.75 (ddd, J=16.5, 11.9, 3.8 Hz), 137.43 (ddd, J=36.5, 20.5, 13.3 Hz), 125.83, 121.51, 118.60, 113.77-113.06 (m), 103.68, 100.67 (d, J=20.9 Hz), 52.87, 21.49, 21.47, 21.44, 14.68, 14.01, 13.99. ¹⁹F NMR (471 MHz, CD₂Cl₂): δ -124.67-−125.17 (m, 2F), −142.22-−142.41 (m, 2F), −167.21-−167.44 (m, 2F). HRMS (ESI) for C₄₀H₃₇Pt₂N₁₀F₆ [M+H]⁺: calcd 1161.2402, found 1161.2379.

Pt-6 was prepared similar to Pt-5 using L2 and bridged pyrazole L4 as ligands. Yield: 5%. ¹H NMR (500 MHz, CD₂Cl₂): δ 8.44 (d, J=4.9 Hz, 2H), 8.39-8.31 (m, 2H), 7.73 (d, J=8.2 Hz, 2H), 7.34-7.30 (m, 2H), 7.27 (t, J=7.8 Hz, 2H), 6.88 (d, J=7.4 Hz, 2H), 6.74 (d, J=8.2 Hz, 2H), 6.54 (s, 2H), 4.15-4.04 (m, 4H), 3.81 (s, 6H), 2.30 (s, 6H), 2.27 (s, 6H), 2.02-1.93 (m, 4H). ¹³C NMR (151 MHz, CD₂Cl₂) δ 168.68, 159.05, 158.14-156.19 (m), 149.45-147.56 (m), 146.38, 145.38, 145.36, 145.12, 143.70-143.32 (m), 137.65, 137.07-136.79 (m), 129.48, 128.68, 122.05, 119.31, 119.19, 118.94, 116.60, 113.48 (d, J=35.2 Hz), 112.43, 100.59 (d, J=22.4 Hz), 68.89, 33.05, 33.01, 30.09, 27.82, 13.37, 13.25. ¹⁹F NMR (471 MHz, CD₂Cl₂): δ −124.79-−126.19 (m, 2F), −141.75-−142.55 (m, 2F), −166.34-−167.06 (m, 2F). HRMS (ESI) for C₅₂H₄₃Pt₂N₁₀F₆O₂[M+H]⁺: calcd 1343.2770, found 1343.2759.

Pt-7 was prepared similar to Pt-6 using L2-iPr and bridged pyrazole L4 as ligands. Yield: 3%. ¹H NMR (500 MHz, CD₂Cl₂): δ 8.55-8.41 (m, 4H), 7.97 (d, J=8.2 Hz, 2H), 7.36-7.23 (m, 4H), 6.89 (d, J=7.4 Hz, 2H), 6.77 (d, J=8.1 Hz, 2H), 6.59 (s, 2H), 5.68-5.57 (m, 2H), 4.13 (m, 4H), 2.35 (s, 6H), 2.30 (s, 6H), 2.02 (m, 4H), 1.62 (d, J=7.0 Hz, 6H), 1.46 (d, J=6.8 Hz, 6H). ¹³C NMR (151 MHz, CD₂Cl₂): δ 167.97, 159.05, 157.92-155.48 (m), 148.42 (dd, J=240.1, 10.8 Hz), 146.47, 146.21, 145.32, 145.07, 143.80-143.39 (m), 137.73, 137.55 (ddd, J=249.4, 20.4, 15.1 Hz), 129.43, 125.75, 122.12, 121.48, 119.12, 118.61, 116.47, 113.00 (d, J=35.0 Hz), 112.35, 100.70 (d, J=22.7 Hz), 68.93, 52.94, 27.86, 21.57, 21.15, 14.06, 13.33. ¹⁹F NMR (471 MHz, CD₂Cl₂): δ −123.97-−125.22 (m, 2F), −141.38-−142.63 (m, 2F), −166.24-−167.73 (m, 2F). HRMS (ESI) for C₅₆H₅₁Pt₂N₁₀F₆O₂[M+H]⁺: calcd 1399.3396, found 1399.3393.

### Characterization of Complexes Pt-1 to Pt-7

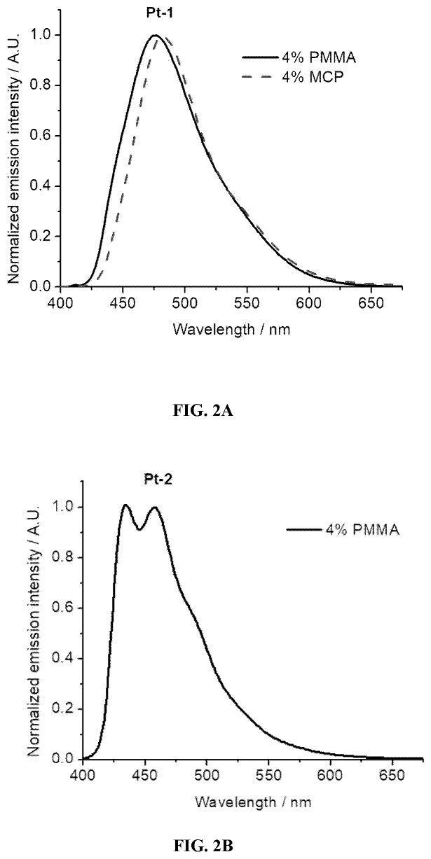

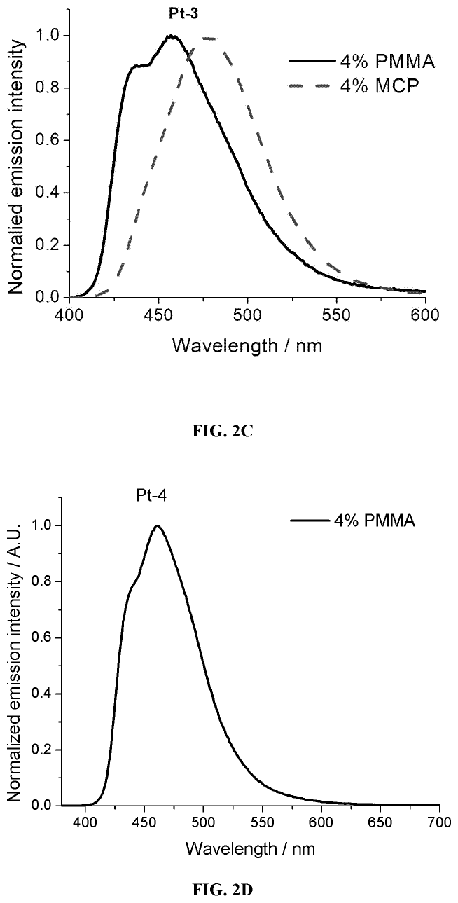

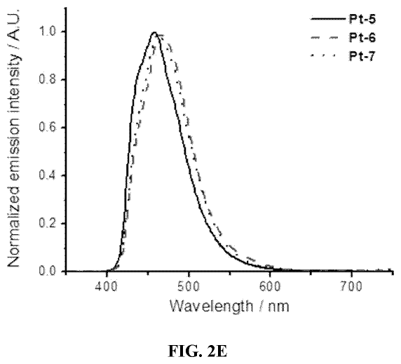

The dinuclear Pt(II) emitter complexes (Pt-1 to Pt-7) displayed strong blue photoluminescence from 457-483 nm (see FIGS. 2A-2E) with emission quantum yields ranging from 0.50-0.92 in thin-films of polymethylmethacrylate (PMMA) and 1,3-bis(N-carbazolyl)benzene (mCP) at room temperature. The emission lifetimes were for the most part within the range of 0.8-1.9 μs, giving rise to large radiative rate constants of 4.7-9.4×10⁵ s⁻¹ or short radiative lifetimes of 1.1-2.1 μs, as detailed in Table 1 below.

TABLE 1
Emission Data of Pt-1 to Pt-7 at Room Temperature.

| | | λₑₘ/ | FWHM/ | Φₑₘ; | kᵣ/×10⁵ |
|---|---|---|---|---|---|
| | medium | nm | nm | τₑₘ/μs | s⁻¹; τᵣ/μs |
| Pt-1 | 4% in PMMA | 474 | 76 | 0.92; 1.3 | 7.1; 1.4 |
| | 4% in mCP | 483 | 66 | 0.73; 0.78 | 9.4; 1.1 |
| Pt-2 | 4% in PMMA | 434, 458 | 72 | 0.78; 3.3 | 2.4; 4.2 |
| Pt-3 | 4% in PMMA | 438, 457 | 71 | 0.89; 1.9 | 4.7; 2.1 |
| | 4% in mCP | 477 | 65 | 0.50; 0.8 | 6.3; 1.6 |
| Pt-4 | 4% in PMMA | 438, 460 | 72 | 0.85; 1.6 | 5.3; 1.9 |
| Pt-5 | 4% in PMMA | 458 | 69 | 0.94; 1.8 | 5.2; 1.9 |
| Pt-6 | 4% in PMMA | 466 | 73 | 0.95; 1.3 | 7.3; 1.4 |
| Pt-7 | 4% in PMMA | 463 | 72 | 0.94; 1.5 | 6.3; 1.6 |

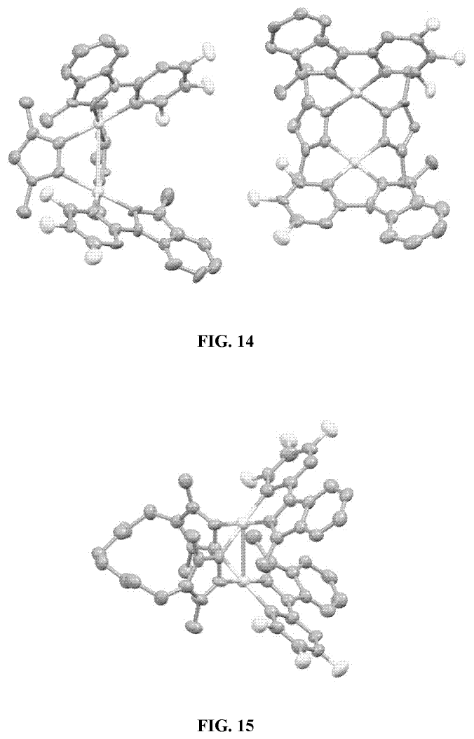

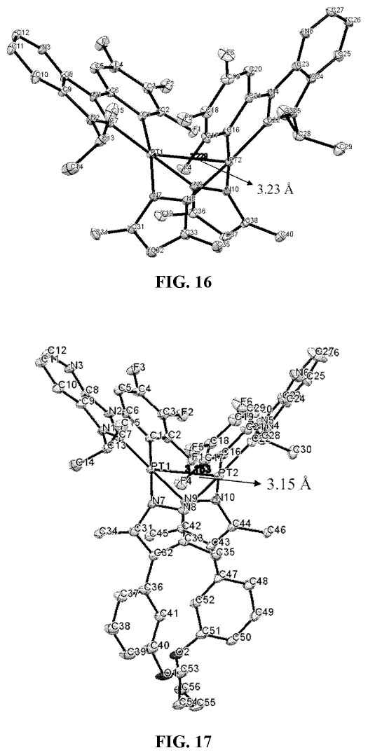

X-ray crystallography structures of dinuclear Pt(II) emitter complexes Pt-3, Pt-4, Pt-5, and Pt-7 are shown in FIGS. 14-17, respectively. The bond lengths of the Pt-3 and Pt-4 complexes are given in Table 2 below.

TABLE 2
Bond lengths of Pt-3 and Pt-4
Pt-3: Bond lengths (in Å)

| | | | |
|---|---|---|---|
| Pt1—C1 (1.952) | Pt1—C2 (2.023) | Pt2—C3 (1.945) | Pt2—C4 (2.019) |
| Pt1—N1 (2.072) | Pt1—N2 (2.055) | Pt2—N3 (2.067) | Pt2—N4 (2.043) |
| Pt1′—C1′ (1.951) | Pt1′—C2′ (2.019) | Pt2′—C3′ (1.941) | Pt2′—C4′ (2.017) |
| Pt1′—N1′ (2.073) | Pt1′—N2′ (2.051) | Pt2′—N3′ (2.054) | Pt2′—N4′ (2.049) |

Pt-4: Bond lengths (in Å)

| | | | |
|---|---|---|---|
| Pt1—C1 (1.928) | Pt1—C2 (2.016) | Pt2—C3 (1.972) | Pt2—C4 (1.997) |
| Pt1—N1 (2.059) | Pt1—N2 (2.024) | Pt2—N3 (2.064) | Pt2—N4 (2.031) |

### Example 2: Organic Light-Emitting Diodes (OLEDs) containing Dinuclear Platinum (II) Emitter Complexes Pt-1 to Pt-7

### Fabrication Process of Vacuum-deposited OLEDs:

Indium-tin-oxide (ITO) coated glass with a sheet resistance of 10 Ω/sq was used as the anode substrate. Before film deposition, patterned ITO substrates were cleaned with detergent, rinsed in de-ionized water, acetone, and isopropanol, and then dried in an oven for 1 hour in a cleanroom. The slides were then treated in an ultraviolet-ozone chamber for 5 min. The OLEDs were fabricated in a Kurt J. Lesker SPECTROS vacuum deposition system with a base pressure of 10-⁷ mbar. In the vacuum chamber, organic materials were thermally deposited in sequence at a rate of 0.5 Å s⁻¹. The emitter complex was doped into the emissive layer (host) using co-deposition technology. Afterward, LiF (1.2 nm) and Al (100 nm) were thermally deposited at rates of 0.02 and 0.2 nm s⁻¹, respectively. The film thicknesses were determined in situ with calibrated oscillating quartz-crystal sensors.

### Fabrication Process of Solution-Processed OLEDs:

An aqueous solution of PEDOT:PSS was spin-coated onto a cleaned ITO coated glass substrate (cleaning process as noted above) and baked at 120° C. for 20 min to remove the residual water solvent in a clean room. Afterwards, the mixture of PYD2 and the emitting dopant in chlorobenzene was spin-coated atop the PEDOT:PSS layer inside the glove box. After annealed at 70° C. for 30 min, all devices were subsequently transferred into a Kurt J. Lesker SPECTROS vacuum deposition system without exposing to air. In the vacuum chamber, organic materials of DPEPO and TPBi were thermally deposited in sequence at a rate of ˜0.5 nm s⁻¹. Finally, LiF (1.2 nm) and Al (100 nm) were thermally deposited at rates of 0.03 and 0.2 nm s⁻¹, respectively.

The chemical structures of organic molecules used as host and transporting materials referenced in Example 2 are as shown below.

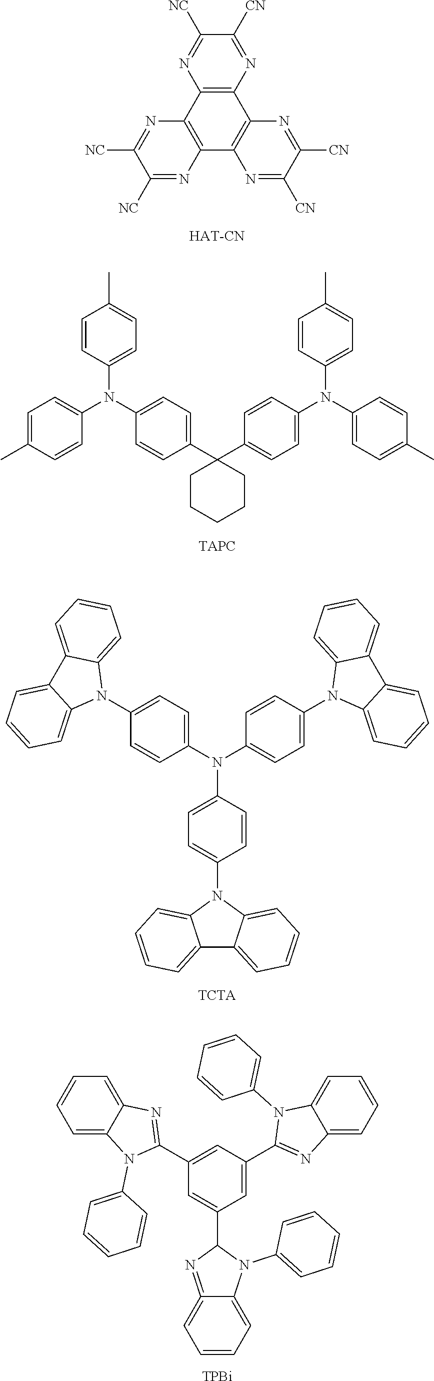

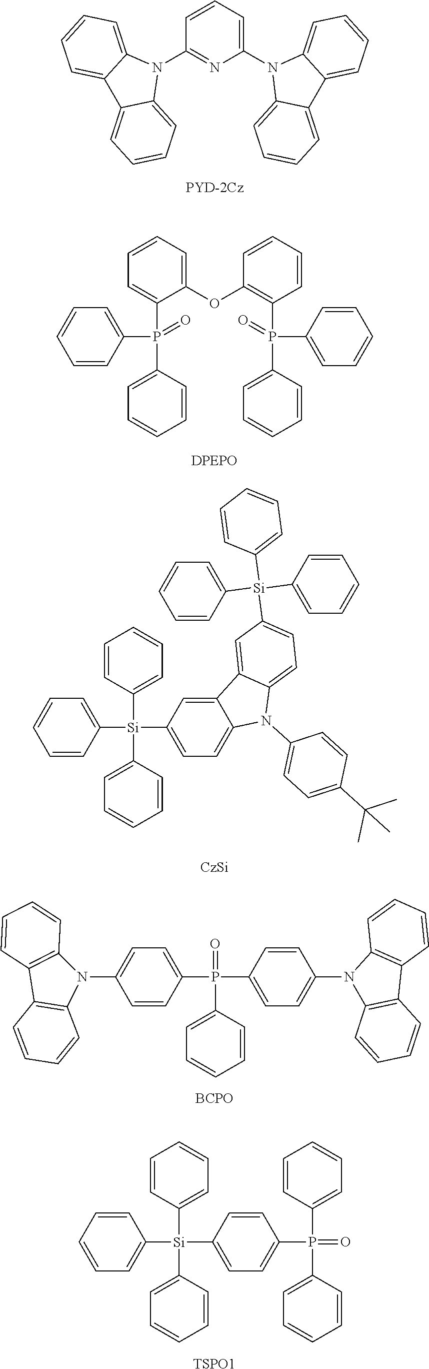

Solution-processed OLED devices were fabricated with Pt-1, where the host was PYD-2Cz. Vacuum-deposited OLED devices were fabricated with Pt-2, where the host was either mCP:B3PYMPM or CzSi:BCPO. These OLED devices each exhibited blue electroluminescence characterized with CIE(x, y) of 0.14-0.15, 0.20-0.24 and 0.15, 0.11-0.15, respectively, at different doping concentrations (4, 8, 12, and 16 wt %).

The maximum external quantum efficiency (EQE) and current efficiency (CE) of the OLED devices doped with 12 wt % of Pt-1 and Pt-2 (in mCP:B3PYMPM host) were measured to be 16.78-17.03% and 20.38-29.58 cd/A, respectively, giving a blue-index of 129-170. Pt-2 (in host) produced a maximum external quantum efficiency (EQE) and current efficiency (CE), when doped at 12% in a CzSi:BCPO host, of 18.7% and 26.0 cd/A, respectively.

Blue light-emitting OLEDs were also fabricated with Pt-3 and Pt-4 via vacuum deposition, with CIE(x, y) around 0.13-0.15, 0.13-0.19. CzSi:TPSO1, BCPO:TSPO1, and BCPO:CzSi were used as hosts for Pt-3 OLED devices. In addition, OLED devices using Pt-3 at 4, 8, and 12 wt % doping in CzSi:BCPO host were also fabricated. BCPO:CzSi was used as a host for Pt-4 OLED devices. The maximum EQE and CE of the device doped with 8 wt % of Pt-3 in BCPO:CzSi were 22.02% and 28.38 cd/A, respectively, which are the highest among these devices.

Blue light-emitting OLEDs fabricated with emitters Pt-5 to Pt-7 via vacuum deposition in various hosts (CzSi; CzSi:BCPO) were also evaluated as detailed below.

Blue light-emitting hyper-fluorescence OLED fabricated with Pt-7 and v-DABNA co-doped in mCBP as a host, and a fluorescence OLED fabricated with v-DABNA in mCBP as a host, were also evaluated as detailed below.

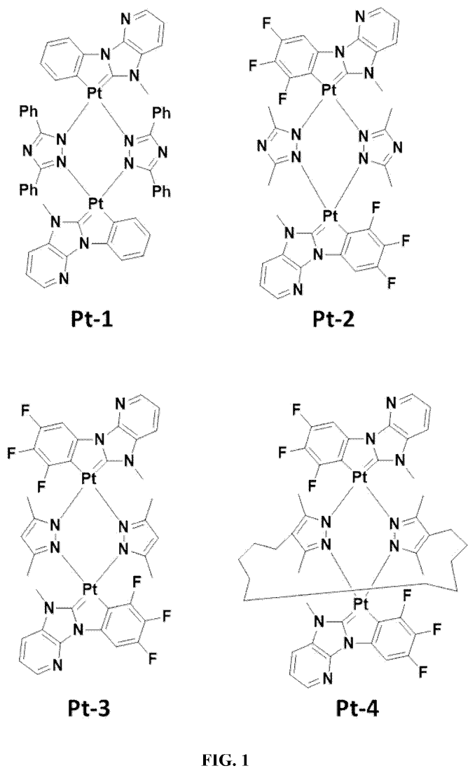

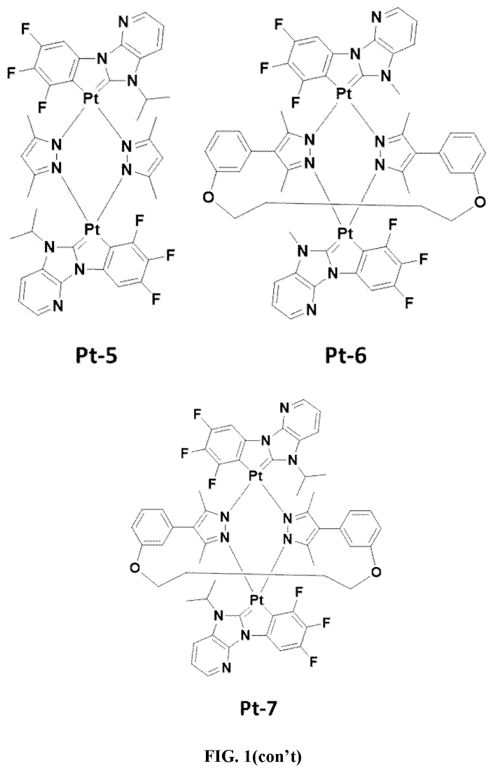

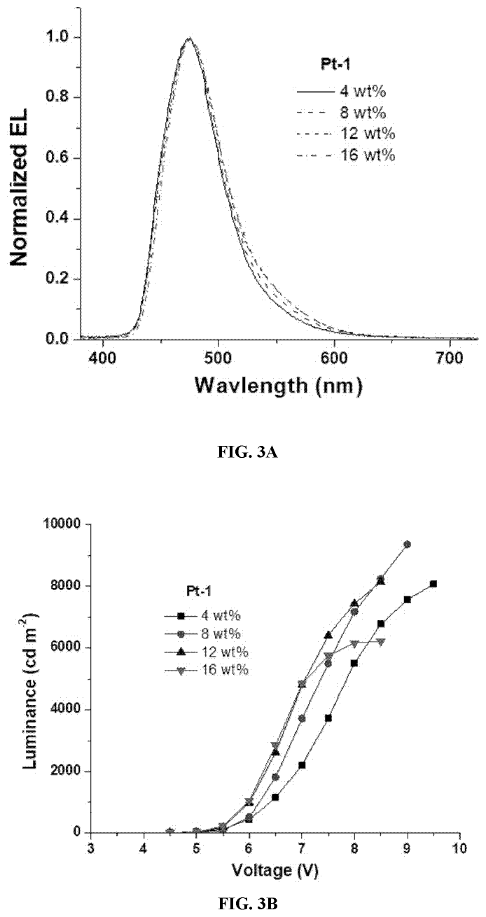

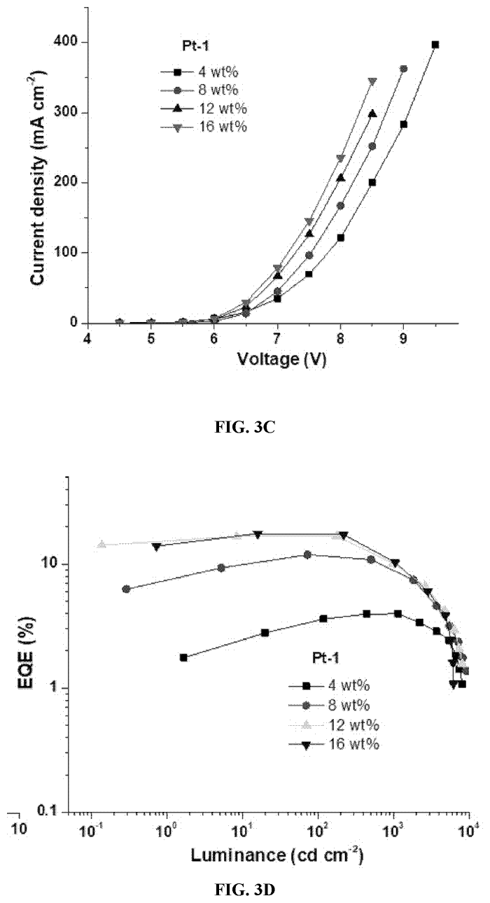

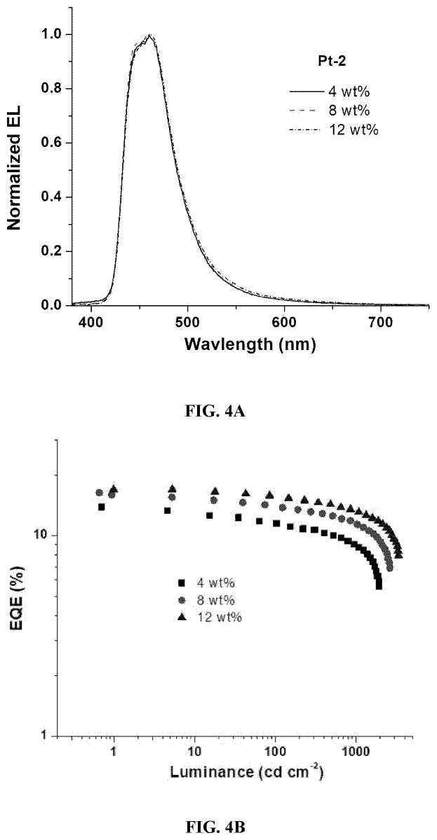

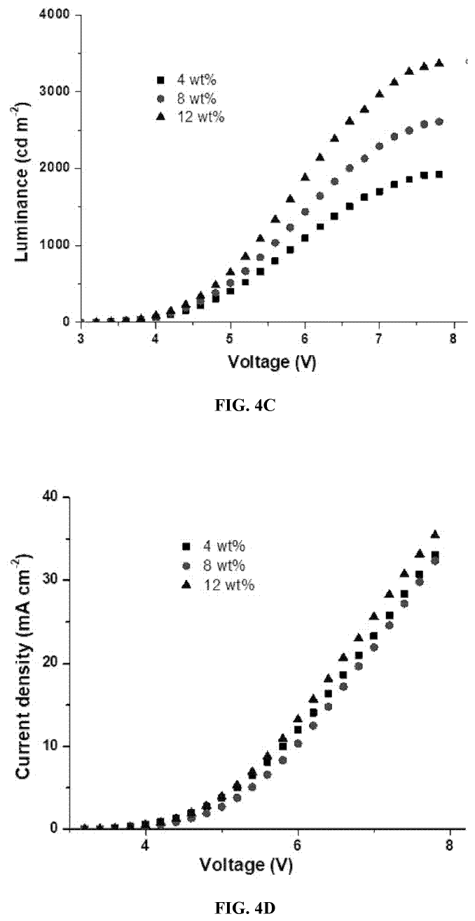

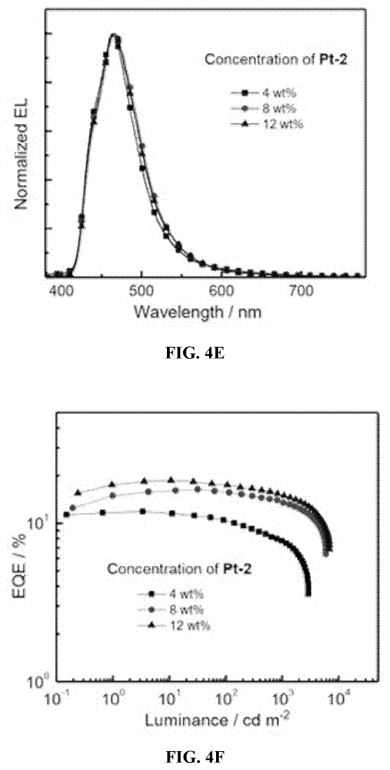

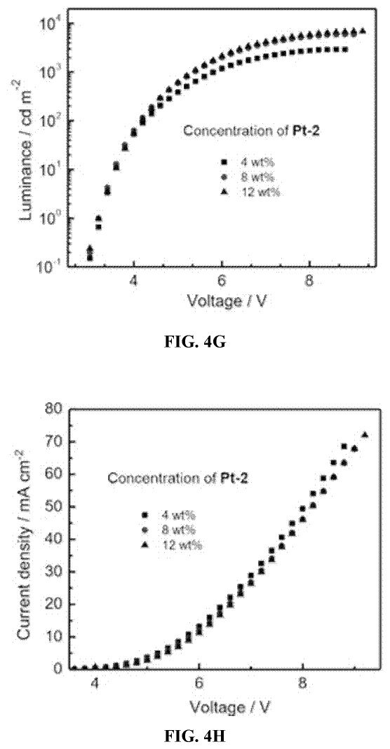

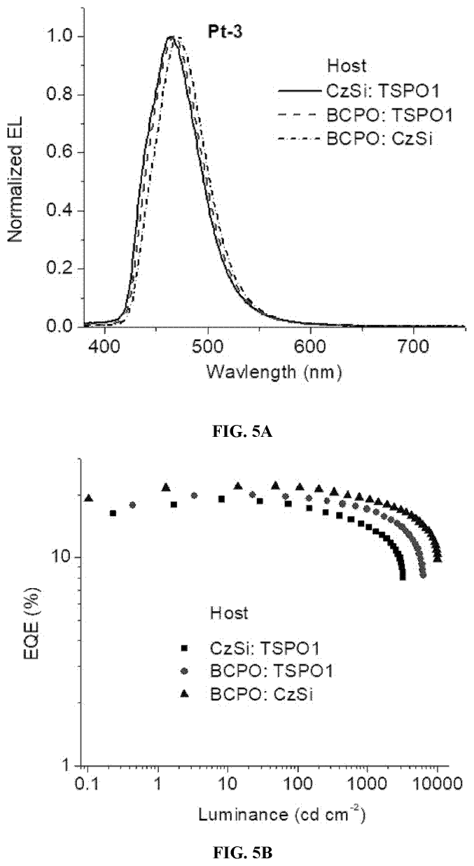

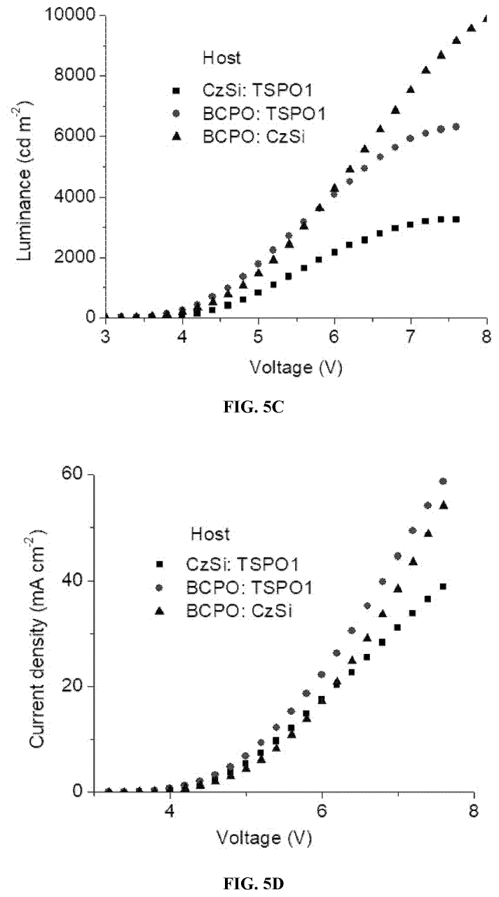

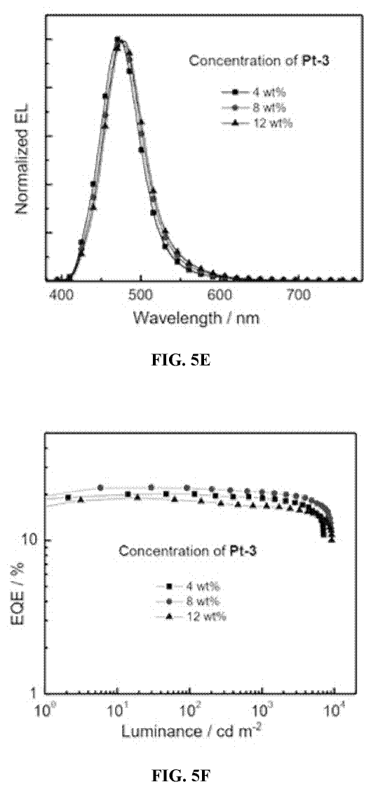

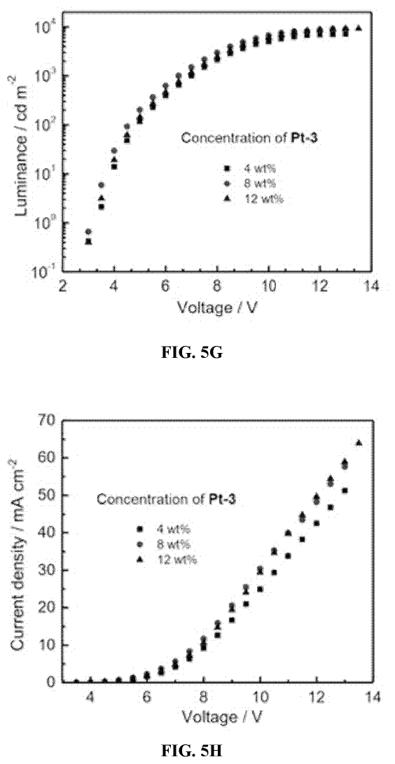

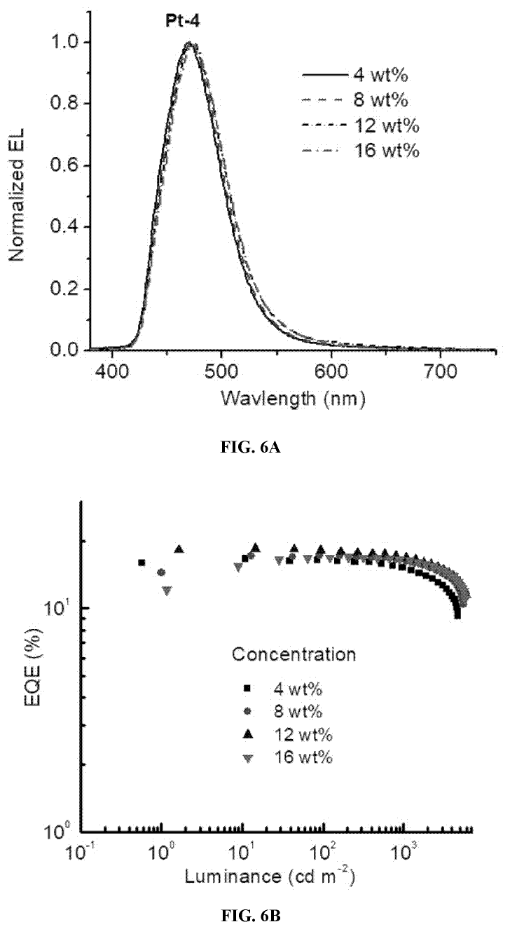

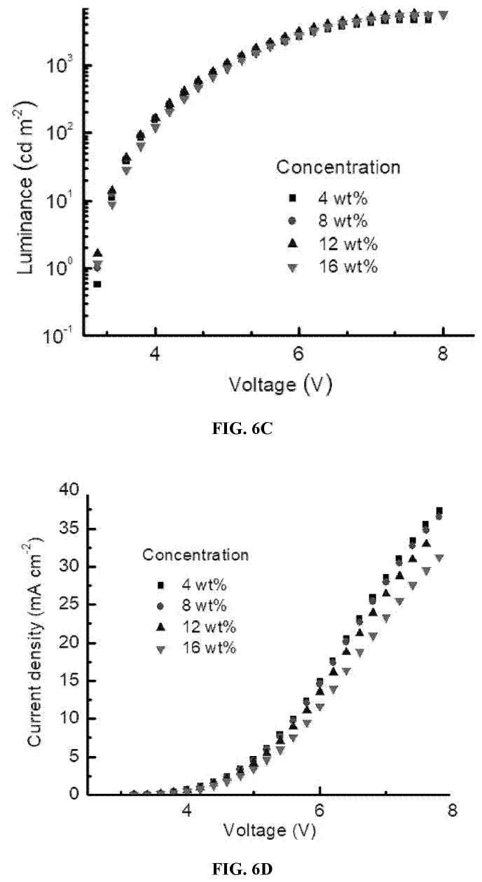

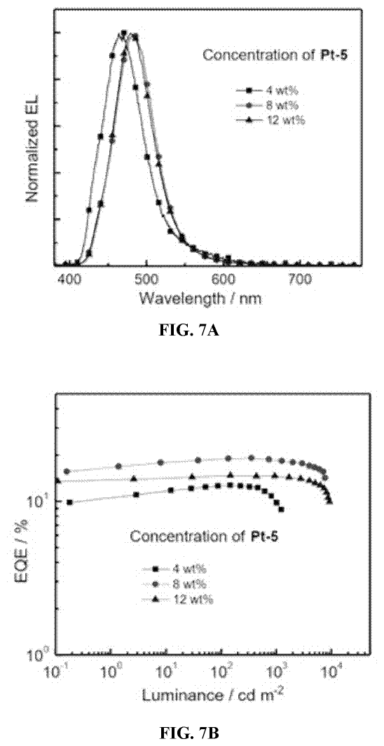

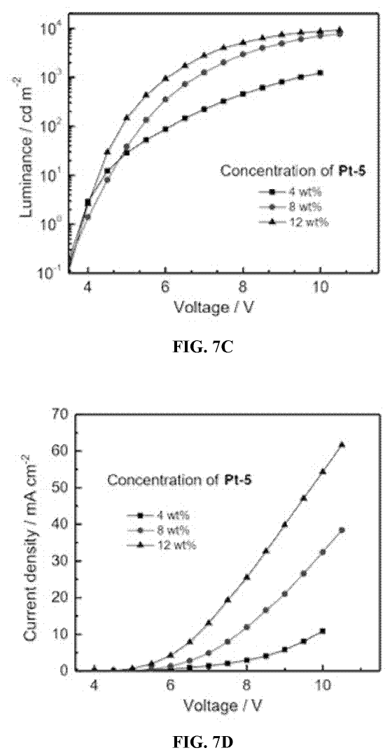

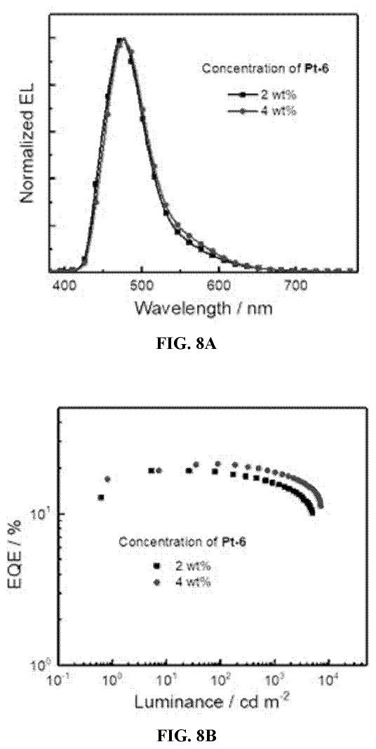

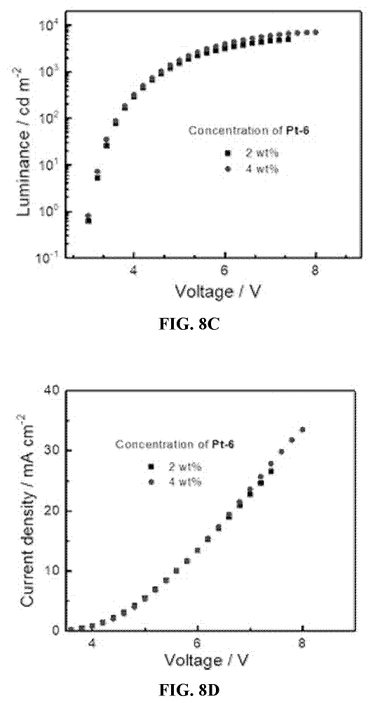

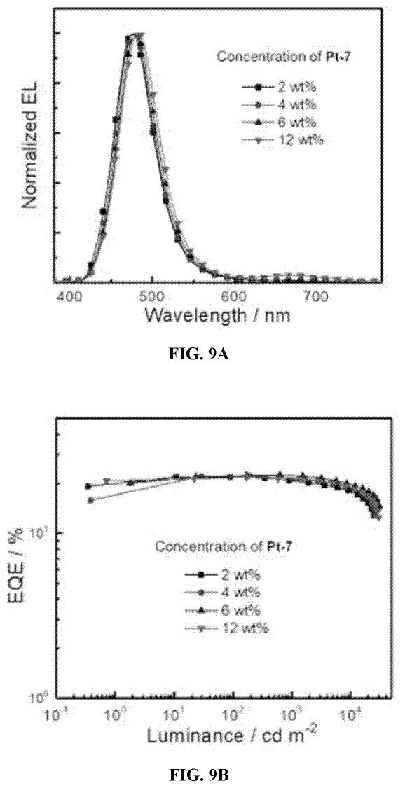

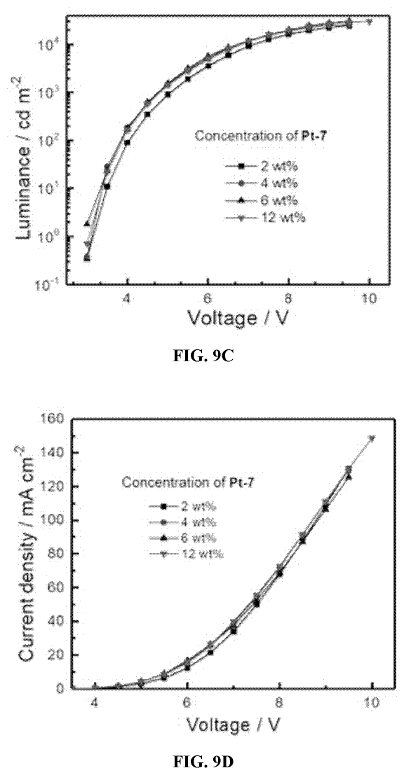

FIGS. 3A-3D, 4A-4H, 5A-5H, 6A-6D, 7A-7D, 8A-8D, 9A-9D, and 1OA-10D provide spectra and OLED performance data for devices containing dinuclear platinum (II) emitter complexes Pt-1 to Pt-7.

Detailed OLED device performance characterization data for the dinuclear platinum (II) emitter complexes Pt-1 to Pt-7 tested is provided in the Tables below.

TABLE 3
Performance data of solution-processed devices with Pt-1.

| Pt-1 | | CE [cd A⁻¹] | | PE [lm W⁻¹] | | EQE [%] | | | | |
|---|---|---|---|---|---|---|---|---|---|---|
| Concentration | L | | at 1000 | | at 1000 | | at 1000 | CIE | FWHM | λₘₐₓ |
| (wt %) | [cd m⁻²] | Max | cd m⁻² | Max | cd m⁻² | Max | cd m⁻² | [(x, y)] | [nm] | [nm] |
| 4 | 8070 | 7.53 | 7.51 | 3.94 | 3.72 | 3.97 | 3.97 | 0.14, | 56 | 474 |
| | | | | | | | | 0.20 | | |
| 8 | 9360 | 22.10 | 16.84 | 12.63 | 8.39 | 11.93 | 9.18 | 0.15, | 58 | 474 |
| | | | | | | | | 0.22 | | |
| 12 | 8200 | 29.58 | 17.46 | 17.87 | 9.15 | 16.78 | 9.15 | 0.15, | 60 | 474 |
| | | | | | | | | 0.23 | | |
| 16 | 6220 | 28.55 | 16.62 | 17.94 | 8.73 | 17.69 | 10.35 | 0.15, | 59 | 474 |
| | | | | | | | | 0.24 | | |

TABLE 4A
Performance data of vapor-deposited devices with Pt-2 using an mCP:B3PYMPM host.

| Pt-2 | | | CE [cd A⁻¹] | | PE [lm W⁻¹] | | EQE [%] | | | | |
|---|---|---|---|---|---|---|---|---|---|---|---|
| Concentration | | L | | at 1000 | | at 1000 | | at 1000 | CIE | FWHM | λₘₐₓ |
| (wt %) | | [cd m⁻²] | Max | cd m⁻² | Max | cd m⁻² | Max | cd m⁻² | [(x, y)] | [nm] | [nm] |
| 4 | wt % | 1930 | 14.53 | 9.49 | 14.27 | 5.11 | 13.88 | 9.07 | 0.15, | 56 | 458 |
| | | | | | | | | | 0.11 | | |
| 8 | wt % | 2620 | 17.84 | 12.44 | 18.68 | 6.99 | 16.38 | 11.42 | 0.15, | 56 | 458 |
| | | | | | | | | | 0.11 | | |
| 12 | wt % | 3400 | 20.38 | 15.80 | 19.96 | 9.22 | 17.03 | 13.15 | 0.15, | 56 | 458 |
| | | | | | | | | | 0.12 | | |

TABLE 4B
Performance data of vapor-deposited devices with Pt-2 using an CzSi:BCPO host.

| | | | CE [cd A⁻¹] | | PE [lm W⁻¹] | | EQE [%] | | | | |
|---|---|---|---|---|---|---|---|---|---|---|---|
| | | L | | at 1000 | | at 1000 | | at 1000 | CIE | FWHM | λₘₐₓ |
| Pt-2 | | [cd m⁻²] | Max | cd m⁻² | Max | cd m⁻² | Max | cd m⁻² | [(x, y)] | [nm] | [nm] |
| 4 | wt % | 2920 | 14.2 | 9.2 | 17.1 | 5.0 | 11.9 | 7.8 | 0.15, | 64 | 463 |
| | | | | | | | | | 0.14 | | |
| 8 | wt % | 5980 | 22.5 | 18.7 | 20.2 | 10.9 | 16.4 | 13.6 | 0.15, | 69 | 464 |
| | | | | | | | | | 0.15 | | |
| 12 | wt % | 6900 | 26.0 | 23.9 | 23.9 | 12.2 | 18.7 | 15.0 | 0.15, | 66 | 465 |
| | | | | | | | | | 0.15 | | |

TABLE 5A
Performance data of vapor-deposited devices with Pt-3
in various host with doping concentration of 8 wt %.

| Host with | | CE [cd A⁻¹] | | PE [lm W⁻¹] | | EQE [%] | | | | |
|---|---|---|---|---|---|---|---|---|---|---|
| dopant at | L | | at 1000 | | at 1000 | | at 1000 | CIE | FWHM | λₘₐₓ |
| 8 wt % | [cd m⁻²] | Max | cd m⁻² | Max | cd m⁻² | Max | cd m⁻² | [(x, y)] | [nm] | [nm] |
| CzSi:TSPO1 | 3300 | 20.04 | 14.53 | 17.49 | 8.94 | 19.06 | 13.97 | 0.14, | 61 | 464 |
| | | | | | | | | 0.12 | | |
| BCPO:TSPO1 | 6400 | 23.82 | 20.73 | 23.58 | 14.16 | 20.04 | 17.06 | 0.14, | 61 | 467 |
| | | | | | | | | 0.13 | | |
| BCPO:CzSi | 10200 | 28.38 | 24.59 | 27.32 | 16.17 | 22.02 | 19.02 | 0.13, | 58 | 470 |
| | | | | | | | | 0.16 | | |

TABLE 5B
Performance data of vapor-deposited devices with Pt-3 using an CzSi:BCPO host.

| | | | CE [cd A⁻¹] | | PE [lm W⁻¹] | | EQE [%] | | | | |
|---|---|---|---|---|---|---|---|---|---|---|---|
| | | L | | at 1000 | | at 1000 | | at 1000 | CIE | FWHM | λₘₐₓ |
| Pt-3 | | [cd m⁻²] | Max | cd m⁻² | Max | cd m⁻² | Max | cd m⁻² | [(x, y)] | [nm] | [nm] |
| 4 | wt % | 7200 | 25.9 | 24.2 | 15.3 | 10.9 | 20.1 | 18.8 | 0.13, | 57 | 467 |
| | | | | | | | | | 0.14 | | |
| 8 | wt % | 9030 | 28.4 | 24.5 | 19.3 | 11.8 | 22.0 | 19.0 | 0.13, | 58 | 470 |
| | | | | | | | | | 0.16 | | |
| 12 | wt % | 9220 | 27.3 | 24.0 | 19.5 | 11.1 | 19.0 | 16.7 | 0.14, | 58 | 472 |
| | | | | | | | | | 0.18 | | |

TABLE 6
Performance data of vapor-deposited devices with Pt-4.

| | | | CE [cd A⁻¹] | | PE [lm W⁻¹] | | EQE [%] | | | | |
|---|---|---|---|---|---|---|---|---|---|---|---|
| | | L | | at 1000 | | at 1000 | | at 1000 | CIE | FWHM | λmax |
| Pt-4 | | [cd m⁻²] | Max | cd m⁻² | Max | cd m⁻² | Max | cd m⁻² | [(x, y)] | [nm] | [nm] |
| 4 | wt % | 4750 | 22.9 | 20.8 | 21.5 | 13.1 | 16.6 | 15.2 | 0.14, | 63 | 468 |
| | | | | | | | | | 0.16 | | |
| 8 | wt % | 5520 | 24.9 | 23.7 | 22.9 | 15.0 | 17.2 | 16.3 | 0.14, | 63 | 470 |
| | | | | | | | | | 0.17 | | |
| 12 | wt % | 5900 | 28.6 | 26.1 | 27.6 | 16.5 | 18.5 | 16.9 | 0.15, | 65 | 474 |
| | | | | | | | | | 0.19 | | |
| 16 | wt % | 5700 | 26.8 | 26.0 | 22.7 | 16.8 | 17.0 | 16.7 | 0.14, | 64 | 474 |
| | | | | | | | | | 0.19 | | |

TABLE 7
Performance data of vapor-deposited devices with Pt-5 in CzSi host.

| | | | CE [cd A⁻¹] | | PE [lm W⁻¹] | | EQE [%] | | | | |
|---|---|---|---|---|---|---|---|---|---|---|---|
| | | L | | at 1000 | | at 1000 | | at 1000 | CIE | FWHM | λₘₐₓ |
| Pt-5 | | [cd m⁻²] | Max | cd m⁻² | Max | cd m⁻² | Max | cd m⁻² | [(x, y)] | [nm] | [nm] |
| 4 | wt % | 1240 | 16.3 | 12.6 | 11.3 | 4.2 | 12.8 | 9.8 | 0.16, | 67 | 464 |
| | | | | | | | | | 0.16 | | |
| 8 | wt % | 7700 | 26.9 | 26.0 | 19.4 | 12.2 | 19.2 | 18.6 | 0.14, | 63 | 477 |
| | | | | | | | | | 0.19 | | |
| 12 | wt % | 9300 | 22.3 | 22.1 | 18.4 | 11.6 | 14.7 | 14.5 | 0.14, | 64 | 477 |
| | | | | | | | | | 0.20 | | |

TABLE 8
Performance data of vapor-deposited devices with Pt-6 in CzSi:BCPO host.

| | | CE [cd A⁻¹] | | PE [lm W⁻¹] | | EQE [%] | | | | |
|---|---|---|---|---|---|---|---|---|---|---|
| | L | | at 1000 | | at 1000 | | at 1000 | CIE | FWHM | λₘₐₓ |
| Pt-6 | [cd m⁻²] | Max | cd m⁻² | Max | cd m⁻² | Max | cd m⁻² | [(x, y)] | [nm] | [nm] |
| 2 wt % | 5000 | 35.3 | 29.2 | 34.6 | 19.9 | 19.2 | 15.8 | 0.16, | 64 | 472 |
| | | | | | | | | 0.22 | | |
| 4 wt % | 7100 | 40.3 | 35.4 | 36.7 | 24.2 | 21.4 | 18.9 | 0.17, | 64 | 476 |
| | | | | | | | | 0.25 | | |

TABLE 9
Performance data of vapor-deposited devices with Pt-7 in CzSi:BCPO host.

| | | | CE [cd A⁻¹] | | PE [lm W⁻¹] | | EQE [%] | | | | |
|---|---|---|---|---|---|---|---|---|---|---|---|
| | | L | | at 1000 | | at 1000 | | at 1000 | CIE | FWHM | λₘₐₓ |
| Pt-7 | | [cd m⁻²] | Max | cd m⁻² | Max | cd m⁻² | Max | cd m⁻² | [(x, y)] | [nm] | [nm] |
| 2 | wt % | 24900 | 32.6 | 31.1 | 29.9 | 19.3 | 22.0 | 20.9 | 0.14, | 56 | 477 |
| | | | | | | | | | 0.20 | | |
| 4 | wt % | 26400 | 35.4 | 34.6 | 31.7 | 22.3 | 22.3 | 21.7 | 0.14, | 56 | 479 |
| | | | | | | | | | 0.22 | | |
| 6 | wt % | 30500 | 37.3 | 37.0 | 34.7 | 24.6 | 22.6 | 22.4 | 0.14, | 56 | 480 |
| | | | | | | | | | 0.24 | | |
| 12 | wt % | 30400 | 35.8 | 34.9 | 35.9 | 22.5 | 21.8 | 21.3 | 0.14, | 57 | 480 |
| | | | | | | | | | 0.26 | | |

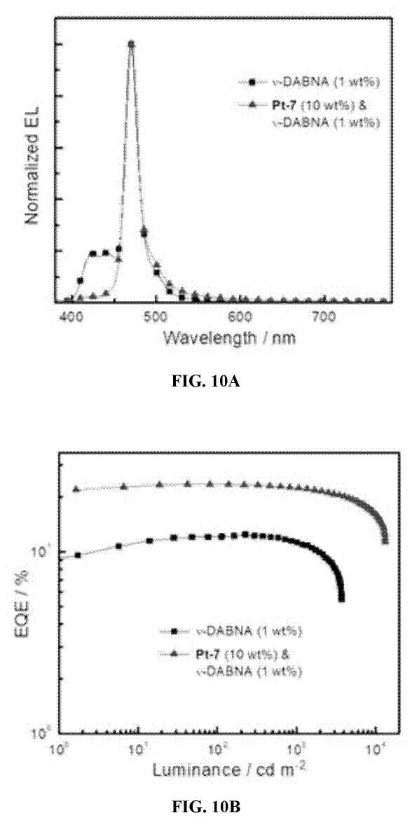

Further, device performance was evaluated for a hyper-fluorescence OLED device using Pt-7 and v-DABNA co-doped in mCBP as a host or a fluorescence OLED device using v-DABNA in mCBP as a host, as detailed in Table 10 below and in FIGS. 10A-10B, which show electroluminescence and external quantum efficiency (EQE %) data, respectively.

TABLE 10
Performance data of hyper-fluorescence OLED based on Pt-7 and v-DABNA co-doped
in mCBP host and fluorescence OLED device based on v-DABNA in mCBP host.

| Pt-7:v- | | Max | Max | EQE [%] | | | | |
|---|---|---|---|---|---|---|---|---|
| DABNA | L | CE | PE | | at 1000 | CIE | FWHM | λₘₐₓ |
| (wt %:wt %) | [cd m⁻²] | [cd A⁻¹] | [lm W⁻¹] | Max | cd m⁻² | [(x, y)] | [nm] | [nm] |
| 10:1 | 13200 | 23.0 | 21.1 | 23.4 | 22.4 | 0.13, | 18 | 469 |
| | | | | | | 0.12 | | |
| 0:1 | 3720 | 8.48 | 6.48 | 12.4 | 11.2 | 0.13, | 18 | 470 |
| | | | | | | 0.09 | | |

### OLED Lifetime Performance Evaluation:

OLED lifetime measurements were performed using emitters Pt-2 (4 wt %), Pt-5 (4 wt %), and Pt-7 (10 wt %) each doped in mCBP host. These were tested to monitor the decay of luminance over time, where LT₅₀ stands for the time at which relative luminance become 50% of the initial luminance L₀.

TABLE 11
OLED lifetime measurement data (where L₀ stands for
initial luminance at which lifetime (LT) is measured)

| Emitter | L₀ (cd m⁻²) | LT₅₀ (h) |
|---|---|---|
| Pt-2 | 1400 | 0.3 |
| Pt-5 | 580 | 0.3 |
| Pt-7 | 1000 | 85.6 |

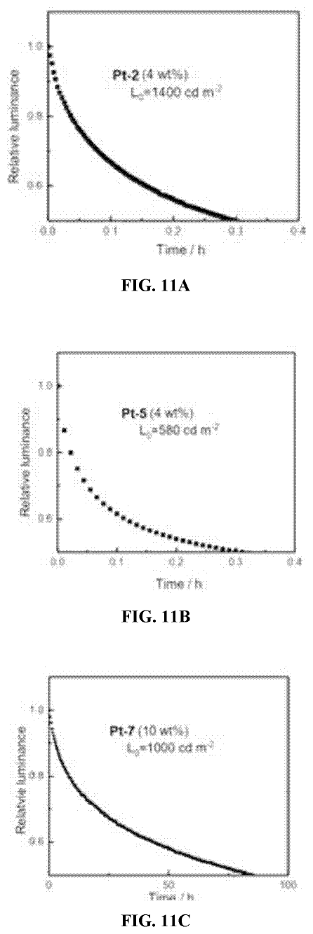

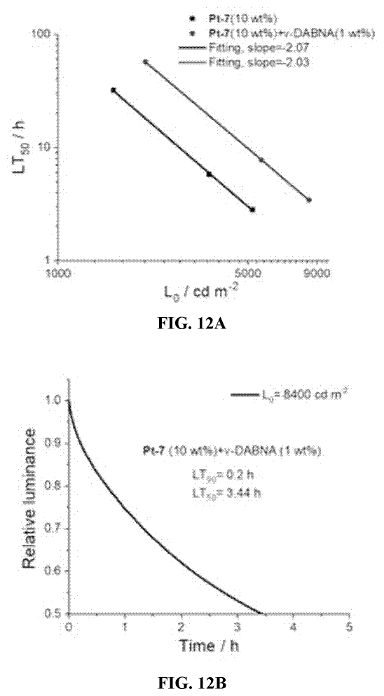

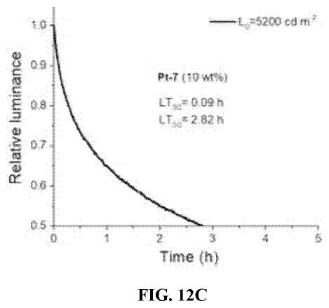

As shown in Table 11, and FIGS. 11A-C, the relative luminance of the devices drops as a function of time with Pt-7 producing the highest LT₅₀ value of 85.6 h. In view of the Pt-7 lifetime, further studies on Pt-7 and v-DABNA were conducted as detailed in the table below and as shown in the graphs in FIGS. 12A-C.

TABLE 12
Lifetime measurement data for OLED based on Pt-7 and v-DABNA
(L₀ stands for initial luminance at which LT is measured; n stands for acceleration
factor in LT(L₁) = LT(L₀) × (L₀/L₁)ⁿ)

| | | | | | | | | LT@1000 | |
|---|---|---|---|---|---|---|---|---|---|
| Pt-7:v- | 1 mA cm⁻² | | 3 mA cm⁻² | | 5 mA cm⁻² | | | cd m⁻² | |
| DABNA | L₀ | LT₅₀ | L₀ | LT₅₀ | L₀ | LT₅₀ | | LT₉₀ | LT₅₀ |
| (wt %:wt %) | (cd m⁻²) | (h) | (cd m⁻²) | (h) | (cd m⁻²) | (h) | n | (h) | (h) |
| 10:1 | 2100 | 56.9 | 5600 | 7.75 | 8400 | 3.44 | 2.03 | 15.1 | 259 |
| 10:0 | 1600 | 31.9 | 3600 | 5.78 | 5200 | 2.82 | 2.07 | 2.73 | 85.6 |

The combination of Pt-7 and v-DABNA in hyper-fluorescence OLED has exhibited longer operational lifetime (estimated LT₅₀=259 hours at L0 of 1000 cd m⁻²) than phosphorescence OLED based on Pt-7 only (estimated LT₅₀=85.6 hours at L₀ of 1000 cd m⁻²). It implies enhanced device stability and potential applications of these dinuclear platinum(II) complexes in hyper-fluorescence OLEDs.

Unless defined otherwise, all technical and scientific terms used herein have the same meanings as commonly understood by one of skill in the art to which the disclosed invention belongs. Publications cited herein and the materials for which they are cited are specifically incorporated by reference.

Those skilled in the art will recognize, or be able to ascertain using no more than routine experimentation, many equivalents to the specific embodiments of the invention described herein. Such equivalents are intended to be encompassed by the following claims.

1. A dinuclear platinum(II) emitter complex, or an isomer thereof, according to formula (I): 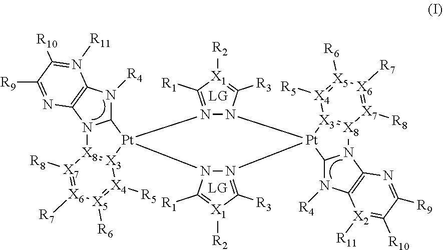
wherein each ligand, LG, is independently bonded to both platinum atoms,
wherein R₁, R₂, and R₃ are each independently selected from the group consisting of hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein each R₄ is independently selected from the group consisting of a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein each X₁ is independently selected from carbon or nitrogen with the proviso that R₂ is a free electron pair when X₁ is nitrogen,
wherein each X₂ is independently selected from carbon or nitrogen with the proviso that R₁₁ is a free electron pair when X₂ is nitrogen,
wherein X₈ is carbon and each of X₃ or X₄ or X₅ or X₆ or X₇ are independently selected from carbon or nitrogen with the proviso that when any of X₄ or X₅ or X₆ or X₇ are nitrogen that R₅, R₆, R₇, R₈ are a free electron pair,
wherein R₅, R₆, R₇, R₈, R₉, R₁₀, and R₁₁ are each independently selected from the group consisting of a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; a nitro group; and an SiMe₃ group,
wherein each of R₅ and R₆, R₆ and R₇, R₇ and R₈, R₉ and R₁₀, or R₁₀ and R₁₁ can optionally form a saturated, unsaturated, or aromatic, optionally substituted ring, optionally interrupted by a heteroatom, and having a total of from 5 to 18 carbon atoms and heteroatoms.

2. The dinuclear platinum(II) emitter complex of claim 1, wherein each X₁ is nitrogen; each R₁ and R₃ is an aryl radical; each X₂ is carbon; each R₄ is a linear or branched alkyl radical; R₅, R₆, R₇, R₈, R₉, R₁₀, and R₁₁ are each hydrogen; and X₃-X₈ are each carbon.

3. The dinuclear platinum(II) emitter complex of claim 1, wherein each X₁ is nitrogen; each R₁ and R₃ is an aryl radical; each X₂ is nitrogen; each R₄ is a linear or branched alkyl radical; R₅, R₆, R₇, R₈, R₉, and R₁₀ are each hydrogen; and X₃-X₈ are each carbon.

4. The dinuclear platinum(II) emitter complex of claim 1, wherein each X₁ is nitrogen; each R₁ and R₃ is a linear or branched alkyl radical; each X₂ is carbon; each R₄ is a linear or branched alkyl radical; R₈-R₁₁ is selected from hydrogen, linear or branched alkyl radical, halogen, alkoxyl radical, or Si(R_{q})₃, wherein R_{q} is a linear or branched alkyl radical, alkoxyl radical or aryl; R₅, R₆, and R₇ are each a halogen; and X₃-X₈ are each carbon.

5. The dinuclear platinum(II) emitter complex of claim 1, wherein each X₁ is nitrogen; each R₁ and R₃ is a linear or branched alkyl radical; each X₂ is nitrogen; each R₄ is a linear or branched alkyl radical; R₈-R₁₀ are selected from hydrogen, linear or branched alkyl radical, halogen, alkoxyl radical, or Si(R_{q})₃, wherein R_{q} is a linear or branched alkyl radical, alkoxyl radical or aryl; R₅, R₆, and R₇ are each a halogen; and X₃-X₈ are each carbon.

6. (canceled)

7. The dinuclear platinum(II) emitter complex of claim 1, wherein each X₁ is carbon; each R₂ is a hydrogen; each R₁ and R₃ is a linear or branched alkyl radical; each X₂ is carbon; each R₄ is a linear or branched alkyl radical; R₈-R₁₁ are selected from hydrogen, linear or branched alkyl radical, halogen, alkoxyl radical, or Si(R_{q})₃, wherein R_{q} is a linear or branched alkyl radical, alkoxyl radical or aryl; and R₅, R₆, and R₇ are each a halogen; and X₃-X₈ are each carbon.

8. The dinuclear platinum(II) emitter complex of claim 1, wherein each X₁ is carbon; each R₂ is a hydrogen; each R₁ and R₃ is a linear or branched alkyl radical; each X₂ is nitrogen; each R₄ is a linear or branched alkyl radical; R₈-R₁₀ are selected from hydrogen, linear or branched alkyl radical, halogen, alkoxyl radical, or Si(R_{q})₃, wherein R_{q} is a linear or branched alkyl radical, alkoxyl radical or aryl; and R₅, R₆, and R₇ are each a halogen; and X₃-X₈ are each carbon.

9-10. (canceled)

11. The dinuclear platinum(II) emitter complex of claim 1 having a structure selected from:

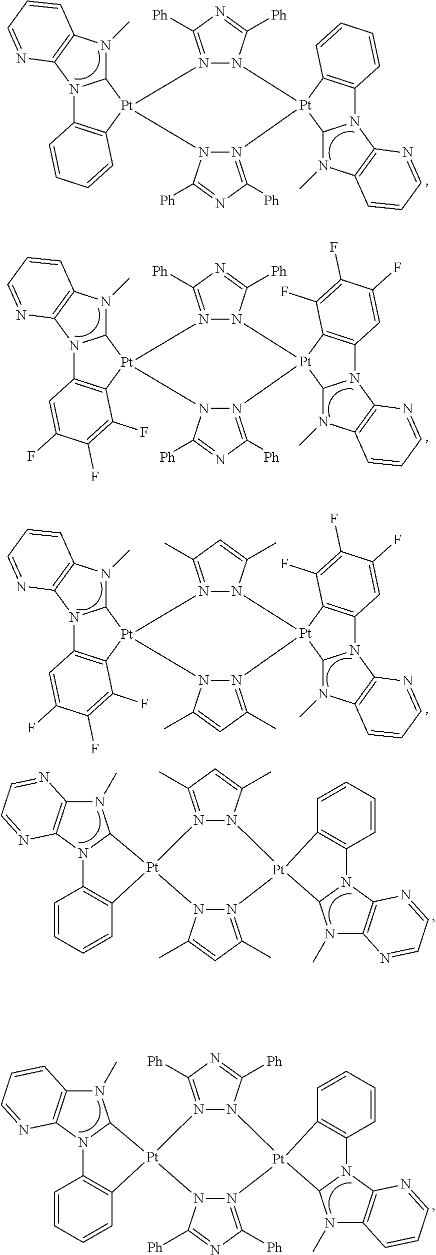

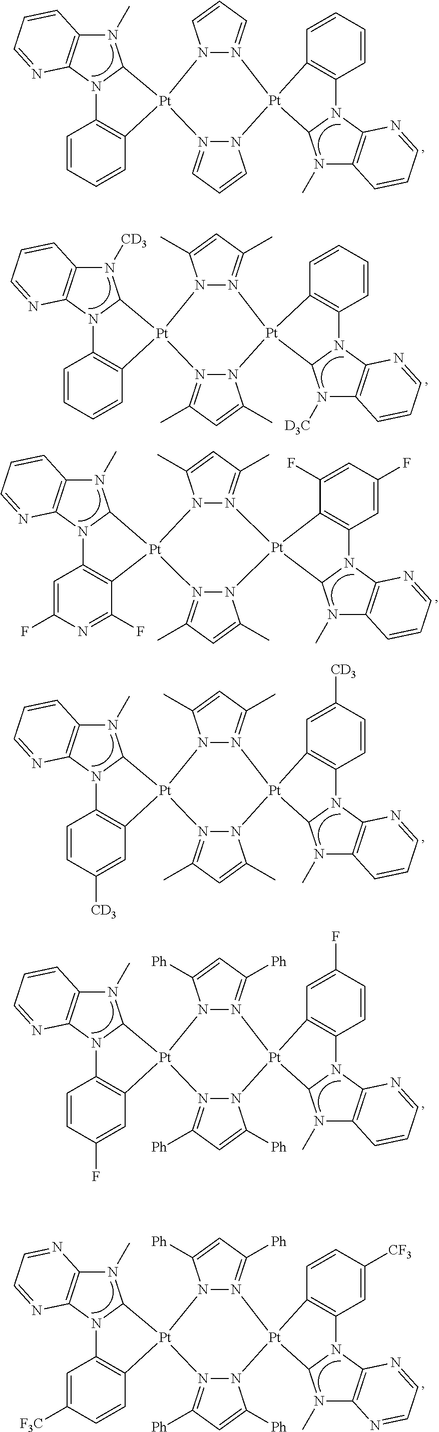

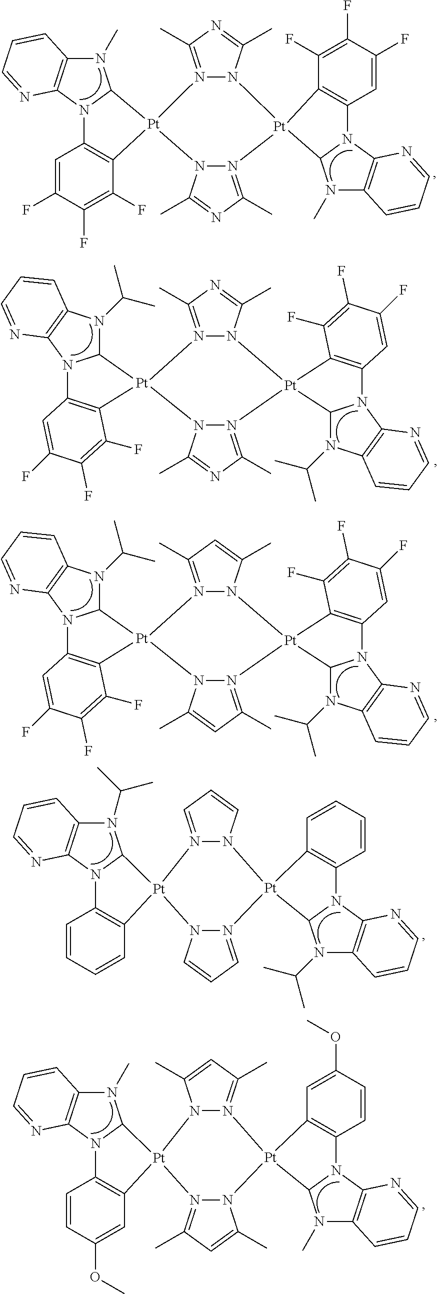

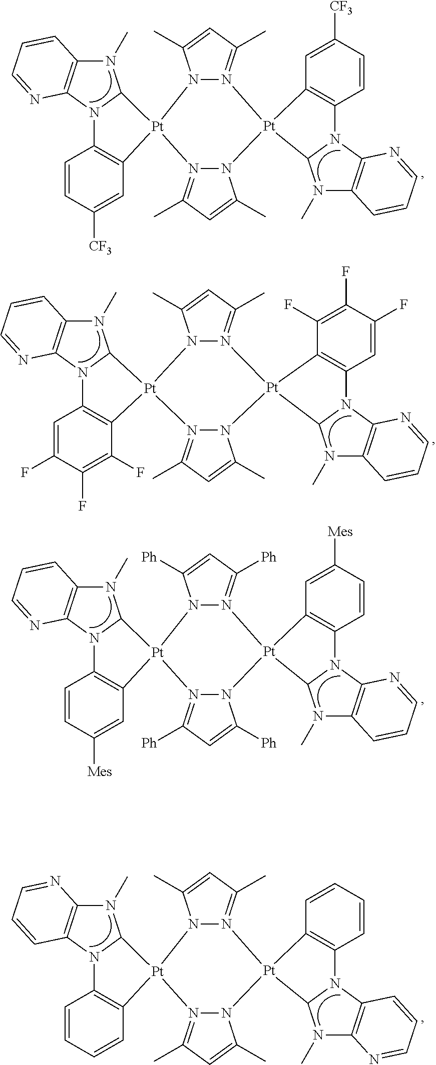

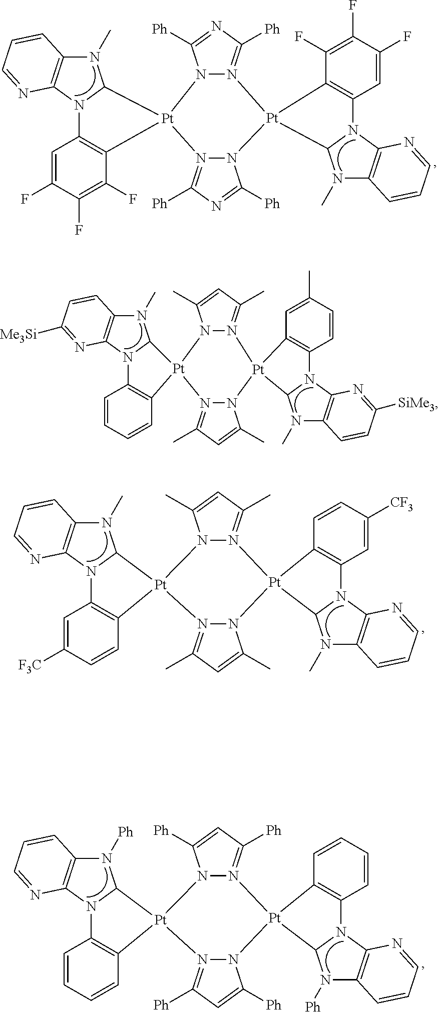

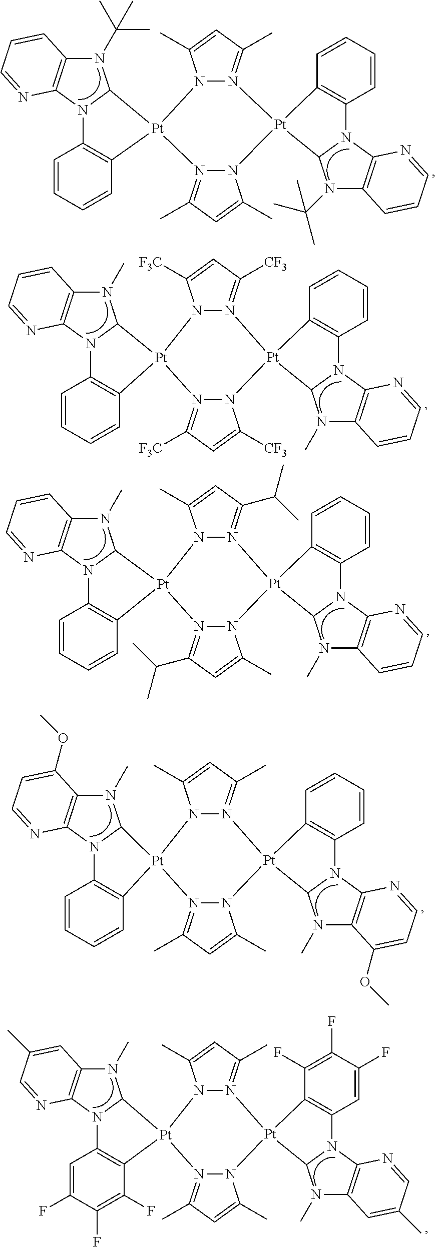

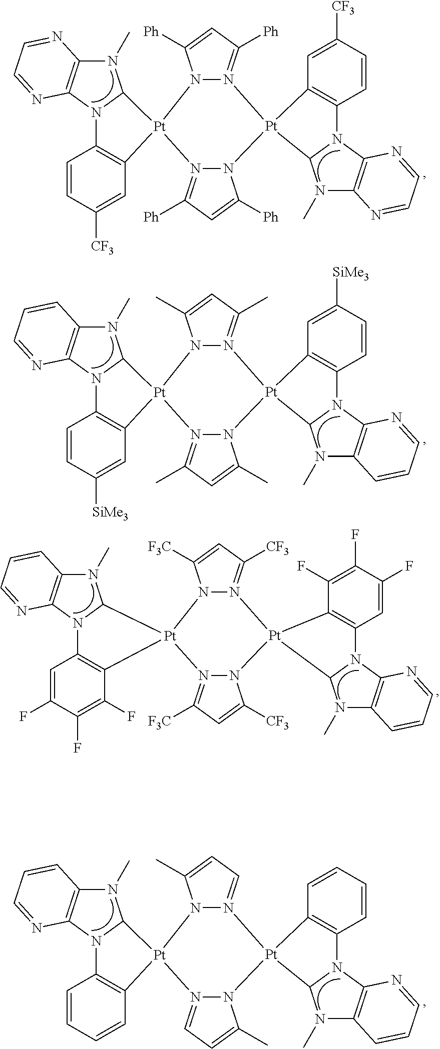

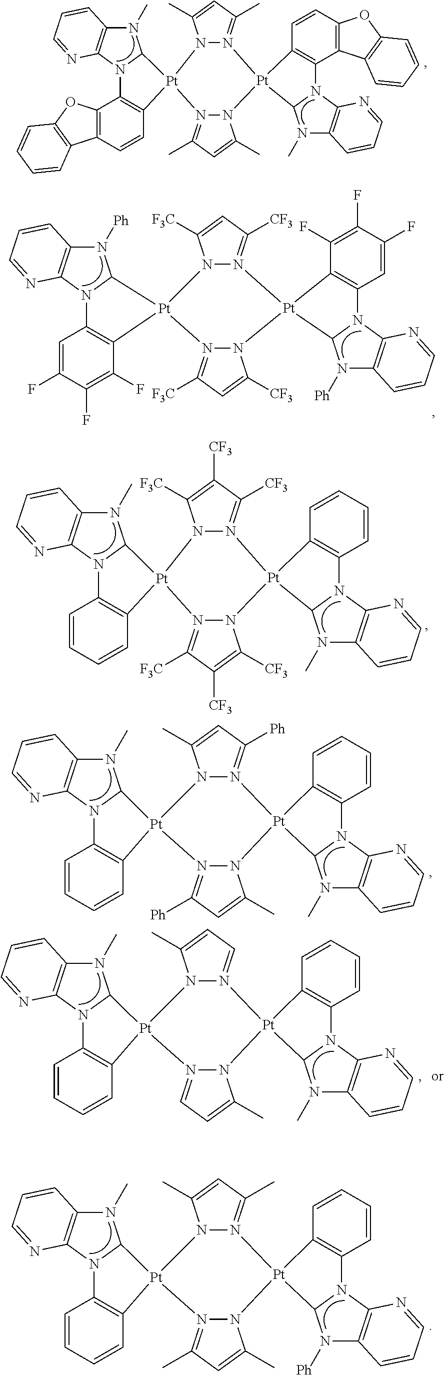

12. A dinuclear platinum(II) emitter complex, or an isomer thereof, according to formula (II): 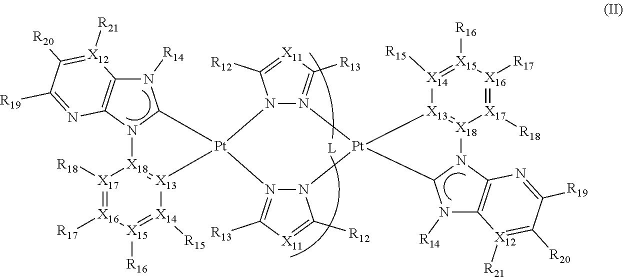
wherein R₁₂ and R₁₃ are each independently selected from the group consisting of a hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein each R₁₄ is independently selected from the group consisting of a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein each X₁₁ is a carbon and the X₁₁ positions are linked via a linker group L,
wherein each X₁₂ is independently selected from carbon or nitrogen with the proviso that R₂₁ is a free electron pair when X₁₂ is nitrogen,
wherein each X₁₃ or X₁₄ or X₁₅ or X₁₆ or X₁₇ or X₁₈ are independently selected from carbon or nitrogen with the proviso that when any of X₁₄ or X₁₅ or X₁₆ or X₁₇ are nitrogen that R₁₅, R₁₆, R₁₇, R₁₈ are a free electron pair,
wherein R₁₅, R₁₆, R₁₇, R₁₈, R₁₉, R₂₀, and R₂₁ are each independently selected from the group consisting of a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; a nitro group, and an SiMe₃ group,
wherein each of R₁₅ and R₁₆, R₁₆ and R₁₇, R₁₇ and R₁₈, R₁₉ and R₂₀, or R₂₀ and R₂₁ can optionally form a saturated, unsaturated, or aromatic, optionally substituted ring, optionally interrupted by a heteroatom, and having a total of from 5 to 18 carbon atoms and heteroatoms,
wherein the linker group L is a linker group which is a substituted or unsubstituted linear or branched alkyl radical having from 1 to 20 carbon atoms, optionally interrupted by at least one heteroatom and/or aryl group and optionally having at least one substituent group thereon; or comprises two phenol groups linked with a linear or branched alkyl radical, optionally interrupted by at least one heteroatom, and optionally having at least one substituent group thereon.

13. The dinuclear platinum(II) emitter complex of claim 12, wherein the linker group L has a formula selected from: 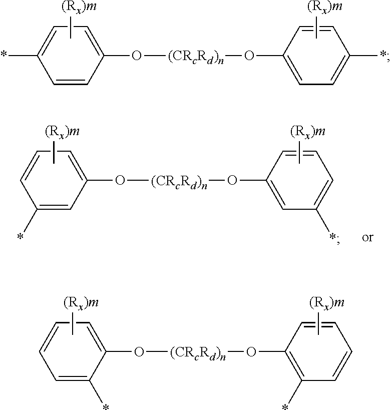
where each n can have an integer value from 3 to 20, and each R_{c} and R_{d} can independently be a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group; where each Rₓ is typically hydrogen and m is 4 but alternatively each Rₓ can represent one or more optional substituents, which may independently be present, when m is 1, 2, 3, or 4 and each Rₓ can be selected from a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group.

14. The dinuclear platinum(II) emitter complex of claim 12, wherein the linker group L has a formula selected from: 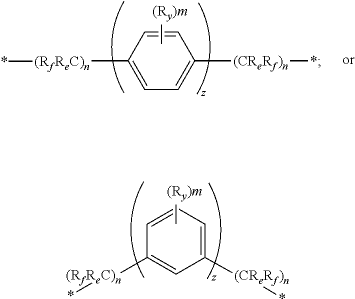
where each n and z are independently an integer value from 1 to 20, and each Rₑ and R_{f} can each independently be a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group; where Ry is typically hydrogen and m is 4 but alternatively R_{y} can represent one or more optional substituents, which may independently be present, when m is 1, 2, 3, or 4, where any remaining unsubstituted positions are hydrogen, and each R_{y} can be selected from a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group.

15. The dinuclear platinum(II) emitter complex of claim 12, wherein each R₁₂ and R₁₃ is a linear or branched alkyl radical, or a substituted or unsubstituted aryl radical; each R₁₄ is a linear or branched alkyl radical, or a substituted or unsubstituted aryl radical; each X₁₂ is selected from carbon or nitrogen with the proviso that R₂₁ is absent when X₁₂ is nitrogen; R₁₈-R₂₀ selected from hydrogen, linear or branched alkyl radical, halogen, alkoxyl radical, or Si(R_{q})₃, wherein R_{q} is a linear or branched alkyl radical, alkoxyl radical or aryl; R₁₅, R₁₆, and R₁₇ are each a halogen; and L is a linker group which is a substituted or unsubstituted linear or branched alkyl radical having from 1 to 20 carbon atoms, optionally interrupted by at least one heteroatom and/or aryl group and/or cycloalkyl and/or heteroaryl group and/or heterocycloalkyl group and optionally having at least one substituent group thereon; or a substituted or unsubstituted alkenyl radical having 2 to 20 carbon atoms, or a substituted or unsubstituted alkynyl radical having 2 to 20 carbon atoms; or comprises two phenol groups linked with a linear or branched alkyl radical, optionally interrupted by at least one heteroatom and optionally having at least one substituent group thereon.

16. The dinuclear platinum(II) emitter complex of claim 12, wherein each X₁₁ is carbon; each R₁₂ and R₁₃ is a linear or branched alkyl radical, or a substituted or unsubstituted aryl radical; each R₁₄ is a linear or branched alkyl radical, or a substituted or unsubstituted aryl radical; each X₁₂ is carbon; R₁₈-R₂₁ selected from hydrogen, linear or branched alkyl radical, halogen, alkoxyl radical, or Si(R_{q})₃, wherein R_{q} is a linear or branched alkyl radical, alkoxyl radical or aryl; R₁₅, R₁₆, and R₁₇ are each a halogen; and the linker group L is a linear or branched alkyl radical, or a substituted or unsubstituted aryl radical, or a combination thereof, optionally interrupted by at least one heteroatom.

17. The dinuclear platinum(II) emitter complex of claim 12, wherein each X₁₁ is carbon; each R₁₂ and R₁₃ is a linear or branched alkyl radical, or a substituted or unsubstituted aryl radical; each R₁₄ is a linear or branched alkyl radical, or a substituted or unsubstituted aryl radical; each X₁₂ is nitrogen; R₁₈-R₂₀ selected from hydrogen, linear or branched alkyl radical, halogen, alkoxyl radical, or Si(R_{q})₃, wherein R_{q} is a linear or branched alkyl radical, alkoxyl radical or aryl; R₁₅, R₁₆, and R₁₇ are each a halogen; and the linker group L is a linear or branched alkyl radical, or a substituted or unsubstituted aryl radical, or a combination thereof, optionally interrupted by at least one heteroatom.

18. (canceled)

19. The dinuclear platinum(II) emitter complex of claim 12 having a structure selected from:

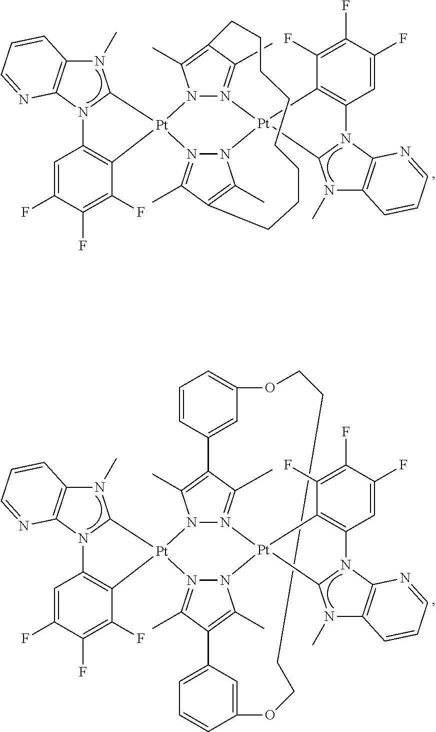

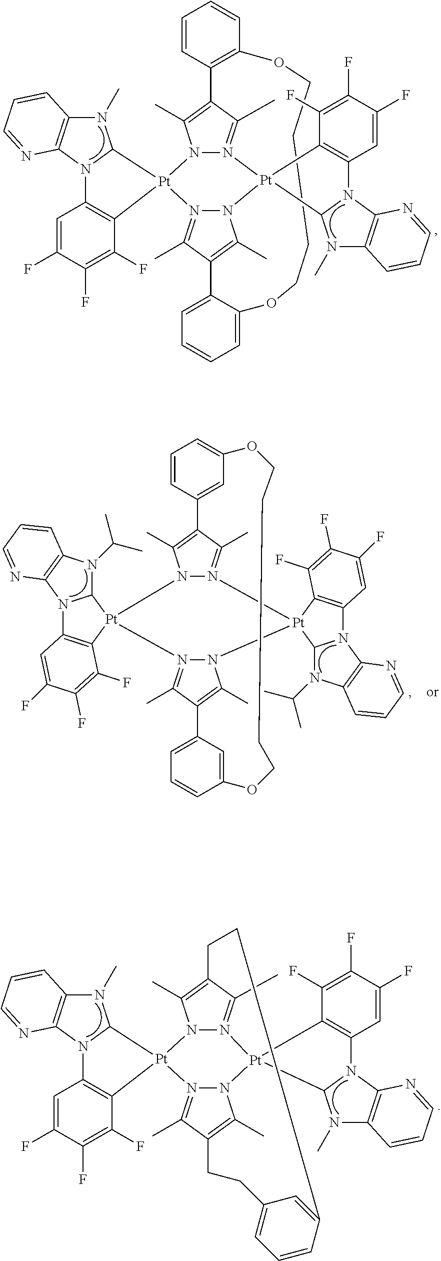

20. A method for preparing a dinuclear platinum(II) emitter complex, the method comprising:
contacting a platinum (Pt) compound with a first ligand selected from a pyrazole ligand, a triazole ligand, or a combination thereof; and a second ligand according to formula (III) 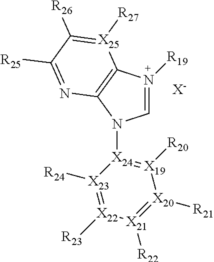
wherein R₁₉ is selected from the group consisting of a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms,
wherein X₁₉ is independently selected from carbon or nitrogen with the proviso that R₂₀ is hydrogen when X₁₉ is a carbon and R₂₀ is a free electron pair when X₁₉ is nitrogen,
wherein X₂₅ is independently selected from carbon or nitrogen with the proviso that R₂₆ is a free electron pair when X₂₅ is nitrogen,
wherein X₂₄ is carbon and each of X₁₉ or X₂₀ or X₂₁ or X₂₂ or X₂₃ are independently selected from carbon or nitrogen with the proviso that when any of X₁₉ or X₂₀ or X₂₁ or X₂₂ or X₂₃ are nitrogen that R₂₀, R₂₁, R₂₂, R₂₃, R₂₄ are a free electron pair,
wherein R₂₁, R₂₂, R₂₃, R₂₄, R₂₅, R₂₆, and R₂₇ are each independently selected from the group consisting of a hydrogen; a halogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; a substituted or unsubstituted heteroaryl radical having a total of from 5 to 18 carbon atoms and heteroatoms; an alkoxy group; an amino group; a hydroxyl group; a formyl group; an acyl group; a thio group; an ester group; a carbonyl group; a carboxylate group; an amide group; and a nitro group,
wherein each of R₂₁ and R₂₂, R₂₂ and R₂₃, R₂₃ and R₂₄, R₂₅ and R₂₆, or R₂₆ and R₂₇ can optionally form a saturated, unsaturated, or aromatic, optionally substituted ring, optionally interrupted by a heteroatom, and having a total of from 5 to 18 carbon atoms and heteroatoms, and
wherein X is a halide, BF₄⁻, PF₆⁻, CF₃SO₃⁻, SbF₆⁻, ClO₄⁻, or 1/2 SO₄²⁻.

21-22. (canceled)

23. The method of claim 20, wherein the first ligand is the pyrazole ligand having a structure according to formula (IV) 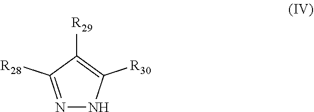
wherein R₂₈, R₂₉, and R₃₀ are each independently selected from the group consisting of a hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms.

24. (canceled)

25. The method of claim 20, wherein the first ligand is the pyrazole ligand having a structure according to formula (V) 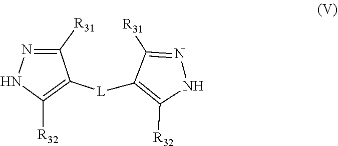
wherein in linker L is a linker group which is a substituted or unsubstituted linear or branched alkyl radical having from 1 to 20 carbon atoms, optionally interrupted by at least one heteroatom and/or aryl group and optionally having at least one substituent group thereon; or comprises two phenol groups linked with linear or branched alkyl radical, optionally interrupted by at least one heteroatom and optionally having at least one substituent group thereon; and
wherein R₃₁ and R₃₂ are each independently selected from the group consisting of a hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms.

26. (canceled)

27. The method of claim 20, wherein the first ligand is the triazole ligand having a structure according to formula (VI) 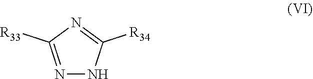
wherein R₃₃ and R₃₄ are each independently selected from the group consisting of a hydrogen; a substituted or unsubstituted linear or branched alkyl radical having from 1 to 20 carbon atoms, optionally interrupted by at least one heteroatom and optionally bearing at least one functional group; a substituted or unsubstituted cycloalkyl radical having from 3 to 20 carbon atoms; a substituted or unsubstituted aryl radical having from 6 to 30 carbon atoms; and a substituted or unsubstituted heteroaryl radical having a total of from 5 to 18 carbon atoms and heteroatoms.

28. (canceled)

29. An organic electronic component comprising a first electrode, a second electrode, and an organic layer disposed between the first electrode and the second electrode, the organic layer comprising an emission layer and at least one dinuclear platinum(II) emitter complex of claim 1;
wherein the organic electronic component is optionally an organic light-emitting diode (OLED).

30-36. (canceled)
